(19) United States
(12) Patent Application Publication
(10) Pub. No.: US 2022/0149293 A1
(43) Pub. Date: May 12, 2022

(54) ORGANIC LIGHT-EMITTING DEVICE AND ELECTRONIC APPARATUS INCLUDING THE SAME

(71) Applicant: Samsung Display Co., Ltd., Yongin-si (KR)

(72) Inventors: Seulong Kim, Yongin-si (KR); Hajin Song, Yongin-si (KR)

(21) Appl. No.: 17/454,006

(22) Filed: Nov. 8, 2021

(30) Foreign Application Priority Data
Nov. 12, 2020 (KR) 10-2020-0150993

(51) Int. Cl. H01L 51/00

(52) U.S. Cl. CPC H01L 51/0072; H01L 51/0073; H01L 51/502; H01L 51/0094; H01L 51/0058

(57) ABSTRACT

An organic light-emitting device and an electronic apparatus including the same are disclosed. The organic light-emitting device includes: a first electrode, a second electrode facing the first electrode; and an interlayer including a first emission layer and a second emission layer, which are located between the first electrode and the second electrode, wherein the first emission layer includes a first host and a first dopant, the second emission layer includes a second host and a second dopant, the first emission layer has greater hole mobility than electron mobility, the second emission layer has greater electron mobility than hole mobility, the first host has a triplet excitation energy level (T₁) value of 2.0 eV or more, and the second host has a T₁ value of 1.6 eV or more and 1.8 eV or less.

### CROSS-REFERENCE TO RELATED APPLICATION

This application claims priority to and the benefit of Korean Patent Application No. 10-2020-0150993, filed on Nov. 12, 2020, in the Korean Intellectual Property Office, the entire content of which is hereby incorporated by reference.

### BACKGROUND

### 1. Field

One or more aspects of embodiments of the present disclosure relate to an organic light-emitting device including a double-layered emission layer, and an electronic apparatus including the organic light-emitting device.

### 2. Description of Related Art

Light-emitting devices (for example, organic light emitting devices, OLEDs) are self-emission devices that may have wide viewing angles, high contrast ratios, short response times, and/or excellent or suitable characteristics in terms of luminance, driving voltage, and/or response speed, compared to devices in the related art.

In an organic light-emitting device, a first electrode is located on a substrate, and a hole transport region, an emission layer, an electron transport region, and a second electrode are sequentially formed on the first electrode. Holes provided from the first electrode may move toward the emission layer through the hole transport region, and electrons provided from the second electrode may move toward the emission layer through the electron transport region. Carriers (such as the holes and the electrons) may recombine in the emission layer to produce excitons. These excitons may transition from an excited state to the ground state to thereby generate light.

### SUMMARY

One or more aspects of embodiments of the present disclosure are directed toward an organic light-emitting device including a double-layered emission layer and having characteristics of high efficiency and/or long lifespan.

Additional aspects will be set forth in part in the description that follows and, in part, will be apparent from the description, or may be learned by practice of the presented embodiments of the disclosure.

One or more embodiments of the present disclosure provide an organic light-emitting device including a first electrode; a second electrode facing the first electrode; and an interlayer including a first emission layer and a second emission layer, which are located between the first electrode and the second electrode, wherein the first emission layer includes a first host and a first dopant; the second emission layer includes a second host and a second dopant; the first emission layer has greater hole mobility than electron mobility; the second emission layer has greater electron mobility than hole mobility; the first host has a triplet excitation energy level (T₁) value of 2.0 eV or more; and the second host has a T₁ value of 1.6 eV or more and 1.8 eV or less (e.g., 1.6 eV to 1.8 eV).

One or more embodiments of the present disclosure provide an organic light-emitting device including a first electrode; a second electrode facing the first electrode; and an interlayer between the first electrode and the second electrode, wherein the interlayer includes m emission units and m-1 charge generating units between two neighboring emission units among the m emission units; m is an integer of 2 or more; at least one emission unit among the m emission units includes a first emission layer and a second emission layer; the first emission layer includes a first host and a first dopant; the second emission layer includes a second host and a second dopant; the first emission layer has greater hole mobility than electron mobility; the second emission layer has greater electron mobility than hole mobility; the first host has a T₁ value of 2.0 eV or more; and the second host has a T₁ value of 1.6 eV or more and 1.8 eV or less.

One or more embodiments of the present disclosure provide an electronic apparatus including the organic light-emitting device.

### BRIEF DESCRIPTION OF THE DRAWINGS

The above and other aspects, features, and advantages of certain embodiments of the disclosure will be more apparent from the following description taken in conjunction with the accompanying drawing, in which:

FIGS. 1-3 are each a diagram schematically illustrating a structure of a light-emitting device according to an embodiment;

FIG. 4 is a cross-sectional view of a light-emitting apparatus according to an embodiment of the present disclosure; and

FIG. 5 is a cross-sectional view of a light-emitting apparatus according to an embodiment of the present disclosure.

### DETAILED DESCRIPTION

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described below, by referring to the drawings, to explain aspects of the present description. As utilized herein, the term “and/or” includes any and all combinations of one or more of the associated listed items. Throughout the disclosure, the expression “at least one of a, b and c” indicates only a, only b, only c, both (e.g., simultaneously) a and b, both (e.g., simultaneously) a and c, both (e.g., simultaneously) b and c, all of a, b, and c, or variations thereof.

An expression utilized in the singular encompasses the expression of the plural, unless it has a clearly different meaning in the context.

It will be further understood that the terms “includes,” “including,” “comprises,” and/or “comprising” utilized herein specify the presence of stated features or elements, but do not preclude the presence or addition of one or more other features or elements.

It will be understood that when a layer, region, or component is referred to as being “on” or “onto” another layer, region, or component, it may be directly or indirectly formed on the other layer, region, or component. For example, intervening layers, regions, or components may be present. When an element is referred to as being “directly on,” “directly onto,” another layer, region, or component, there are no intervening elements present.

The sizes of elements in the drawings may be exaggerated for convenience of explanation. In other words, because sizes and/or thicknesses of components in the drawings are arbitrarily illustrated for convenience of explanation, embodiments are not limited thereto.

As used herein, expressions such as “at least one of,” “one of,” and “selected from,” when preceding a list of elements, modify the entire list of elements and do not modify the individual elements of the list. Further, the use of “may” when describing embodiments of the present disclosure refers to “one or more embodiments of the present disclosure”.

An organic light-emitting device according to an aspect includes:

a first electrode;

a second electrode facing the first electrode; and

an interlayer including a first emission layer and a second emission layer, which are located between the first electrode and the second electrode,

wherein the first emission layer includes a first host and a first dopant,

the second emission layer includes a second host and a second dopant,

the first emission layer has greater hole mobility than electron mobility,

the second emission layer has greater electron mobility than hole mobility,

the first host has a triplet excitation energy level (T₁) value of 2.0 eV or more,

the first host utilizes phosphorescence to emit light at triplet excitation energy level (e.g., utilizes triplet state excitation energy to emit phosphorescent light), and

the second host may have a T₁ value of 1.6 eV or more and 1.8 eV or less and emits fluorescence via singlet excitation energy level (S₁) (e.g., utilizes singlet state excitation energy to emit fluorescent light).

The first emission layer and the second emission layer according to an embodiment may be to emit blue light. In an embodiment, the first emission layer and the second emission layer may have a wavelength range of about 450 nm to about 495 nm.

An organic light-emitting device according to an embodiment includes an emission layer including two different hosts and two different dopants. Accordingly, a hole-electron recombination zone may be shifted from an interface of the emission layer to the center thereof, and thus, deterioration of the device due to decomposition of an organic layer neighboring the emission layer may be prevented or reduced, and device lifespan characteristics may be improved. Also, due to inclusion of a plurality of emission layers formed by sequentially stacking a first emission layer (which includes the first host and the first dopant) and a second emission layer (which includes the second host and the second dopant), and the resulting ability to control the hole mobility and electron mobility of each emission layer, a hole-electron recombination zone may be shifted to an interface between the first emission layer and the second emission layer, and thus, deterioration of an organic layer (for example, an electron blocking layer) due to excitons may be prevented or reduced, and lifespan characteristics may be improved.

In some embodiments, in the organic light-emitting device, the first emission layer has a T₁ energy that is relatively greater than that of the second emission layer, and thus, triplet-triplet fusion (TTF) may occur at a side of the second emission layer (that is, TTF occurs at the interface between the first emission layer and the second emission layer), and a TTF zone is narrow. Accordingly, luminescence efficiency is improved.

In an embodiment, the first emission layer may be a phosphorescence emission layer. Here, the term “phosphorescence” refers to light emitted when an excited triplet state energy exciton transitions to the ground state. In an embodiment, the first emission layer may include a phosphorescent host (for example, a first host) and a phosphorescent dopant (for example, a first dopant). The first dopant may be substantially the same as described in connection with a phosphorescent dopant in the present specification.

In an embodiment, a thickness of the first emission layer may be greater than about 1 nm and less than or equal to about 20 nm. Because the first emission layer is a phosphorescence emission layer and a decay time is long, triplet energy may be distributed to (e.g., over) a sufficiently large area. Thus, even when the thickness of the first emission layer is greater than about 1 nm, a portion of the triplet energy may be transferred to the second emission layer and a time during which high phosphorescent energy stays (e.g., the lifetime of the high energy phosphorescence) in the first emission layer may be reduced, such that the lifespan of the phosphorescence emission layer may be improved, and TTF may occur with the triplet energy being transferred to the second emission layer such that high efficiency may be ensured.

In an embodiment, the second emission layer may be a fluorescence emission layer. Here, the term “fluorescence” refers to light emitted when an excited singlet state energy exciton transitions to the ground state. In an embodiment, the second emission layer may include a fluorescent host (for example, a second host) and a fluorescent dopant (for example, a second dopant). The second dopant may be substantially the same as described in connection with a fluorescent dopant and a delayed fluorescence material in the present specification.

In an embodiment, a thickness of the second emission layer may be greater than about 1 nm and less than or equal to about 20 nm. Even when the thickness of the second emission layer is greater than about 1 nm, TTF may easily proceed due to a long decay time of the first emission layer.

In an organic light-emitting device of the present disclosure according to an embodiment, phosphorescence may be emitted when an excited state triplet in the first emission layer transitions to the ground state. At the same time (e.g., in addition and/or simultaneously), a part of a triplet (e.g., a portion of the triplet state energy) may move (e.g., be transferred) to the second emission layer, an excited state singlet may be generated by a TTF mechanism in the second emission layer, and fluorescence may be emitted when the excited state singlet transitions to the ground state. Due to this mechanism, a triplet that is not utilized for phosphorescence emission in the first emission layer may be utilized in the second emission layer, and thus, device efficiency may be increased.

In an embodiment, the first emission layer and the second emission layer may be arranged to contact each other. Because the first emission layer and the second emission layer are arranged to contact each other, an area in which excitons are generated may be shifted to an interface between the first emission layer and the second emission layer. Accordingly, deterioration of the device due to leakage of the excitons to a neighboring organic layer (for example, an electron blocking layer) may be prevented or reduced.

In an embodiment, the first host may include a compound having a structure in which an azadibenzofuran group or an azadibenzothiophene group is substituted with a carbazole group and a bulky group (for example, a triphenylsilyl group, a triphenylgermanyl group, and/or the like).

In an embodiment, the first host may be or include a compound represented by Formula 1:

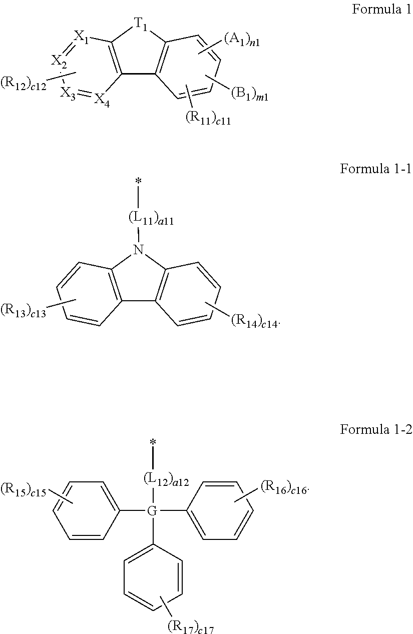

In Formulae 1, 1-1, and 1-2,

T₁ may be O or S,

X₁ to X₄ may each independently be C or N, and at least one of X₁ to X₄ may be N,

A₁ may be a group represented by Formula 1-1,

B₁ may be a group represented by Formula 1-2,

n1 may be an integer from 1 to 3, m1 may be an integer from 1 to 3, and 2≤n1+m1≤4,

G may be C, Si, or Ge,

L₁₁ and L₁₂ may each independently be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,

a11 and a12 may each independently be an integer from 1 to 5,

R₁₁ to R₁₇ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —B(Q₁)(Q₂), —P(Q₁)(Q₂), or —C(═O)(Q₁),

c11 may be an integer from 0 to 2,

c12 may be an integer from 0 to 4,

c13 and c14 may each independently be an integer from 0 to 4,

c15 to c17 may each independently be an integer from 0 to 5, and

R₁₀ₐ may be:

deuterium (-D), —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),

wherein Q₁, Q₂, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, in Formula 1, T₁ may be O, and one of X₁ and X₃ may be N.

In an embodiment, in Formulae 1, 1-1, and 1-2,

L₁₁ and L₁₂ may each independently be selected from: a single bond, a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group; and

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), and —N(Q₃₁)(Q₃₂),

wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

In an embodiment, in Formulae 1, 1-1, and 1-2,

R₁₁ to R₁₇ may each independently be: hydrogen, deuterium, —F, —Cl, —Br, —I, a hydroxyl group, a cyano group, or a nitro group;

a C₁-C₂₀ alkyl group, a C₂-C₂₀ alkenyl group, a C₂-C₂₀ alkynyl group, or a C₁-C₂₀ alkoxy group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or any combination thereof;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₂-C₂₀ alkenyl group, a C₂-C₂₀ alkynyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or any combination thereof; or

—B(Q₁)(Q₂), —P(Q₁)(Q₂), or —C(═O)(Q₁), and

Q₁, Q₂ and Q₃₁ to Q₃₃ may each independently be the same as described in the present specification,

but embodiments of the present disclosure are not limited thereto.

In an embodiment, Formula 1 may be represented by one of Formulae 1A to 1L:

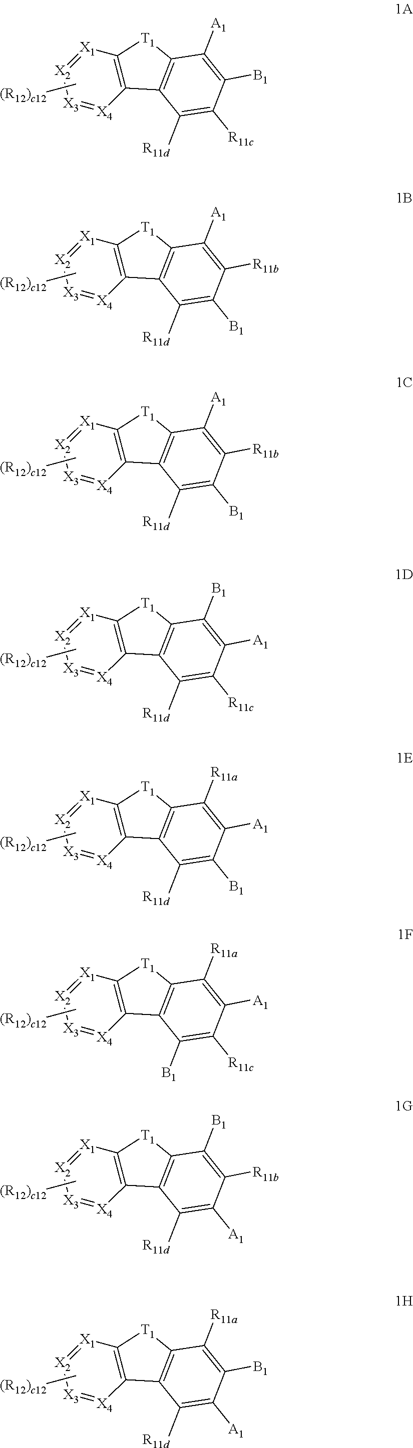

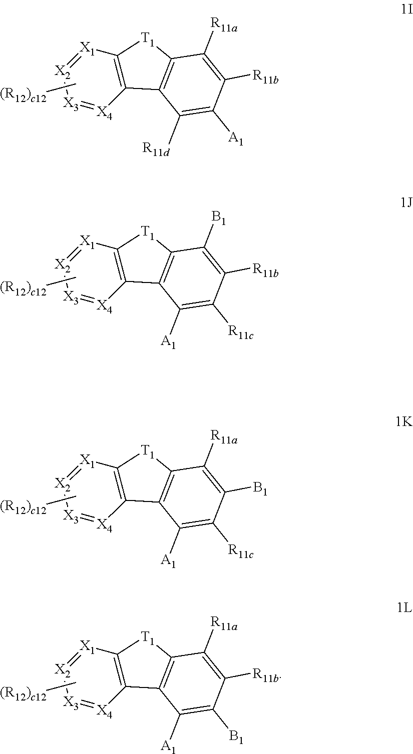

In Formulae 1A to 1L,

T₁, X₁ to X₄, R₁₂, c12, A₁, and B₁ may each independently be the same as described in the present specification, and

each of R₁₁ₐ to R_{11d} may be the same as described in connection with R₁₁ in the present specification.

In an embodiment, the first host may be selected from Compounds PH-1 and PH-2:

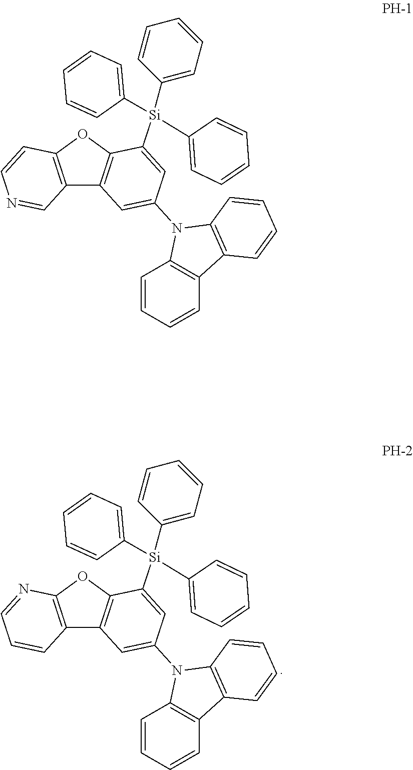 [SMILES: c1ccc([Si](c2ccccc2)(c2ccccc2)c2cc(-n3c4ccccc4c4ccccc43)cc3c2oc2ccncc23)cc1 ; c1ccc([Si](c2ccccc2)(c2ccccc2)c2cc(-n3c4ccccc4c4ccccc43)cc3c2oc2ncccc23)cc1]

In an embodiment, the second host may be or include a compound represented by Formula 2:

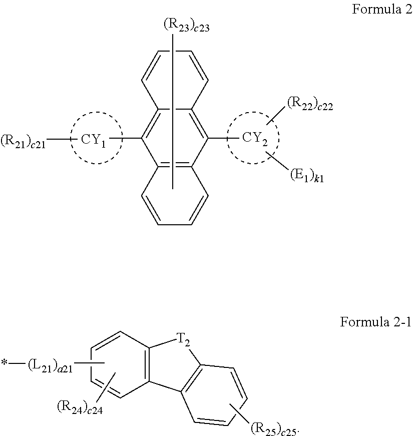

In Formulae 2 and 2-1,

ring CY₁ and ring CY₂ may each independently be a C₃-C₆₀ carbocyclic group or a C₁-C₆₀ heterocyclic group,

E₁ may be a group represented by Formula 2-1,

k₁ may be an integer from 1 to 10,

T₂ may be O or S,

L₂₁ may be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,

a21 may be an integer from 1 to 5,

R₂₁ to R₂₅ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —B(Q₁)(Q₂), —P(Q₁)(Q₂), or —C(═O)(Q₁),

c21 and c22 may each independently be an integer from 0 to 10,

c23 may be an integer from 1 to 8, and at least one of the c23 R₂₃(s) is not hydrogen,

c24 may be an integer from 1 to 3,

c25 may be an integer from 1 to 4, and

R₁₀ₐ may be:

deuterium (-D), —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),

wherein Q₁, Q₂, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, L₂₁ may each independently be selected from: a single bond, a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group; and

a phenylene group, a pentalenylene group, an indenylene group, a naphthylene group, an azulenylene group, a heptalenylene group, an indacenylene group, an acenaphthylene group, a fluorenylene group, a spiro-bifluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, and a pyridinylene group, each substituted with at least one selected from deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), and —N(Q₃₁)(Q₃₂),

wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

In an embodiment, in Formulae 2 and 2-1,

R₂₁ to R₂₅ may each independently be: hydrogen, deuterium, —F, —Cl, —Br, —I, a hydroxyl group, a cyano group, or a nitro group;

a C₁-C₂₀ alkyl group, a C₂-C₂₀ alkenyl group, a C₂-C₂₀ alkynyl group, or a C₁-C₂₀ alkoxy group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or any combination thereof;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₂-C₂₀ alkenyl group, a C₂-C₂₀ alkynyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or any combination thereof; or

—B(Q₁)(Q₂), —P(Q₁)(Q₂), or —C(═O)(Q₁), and

Q₁, Q₂ and Q₃₁ to Q₃₃ may each independently be the same as described in the present specification,

but embodiments of the present disclosure are not limited thereto.

In an embodiment, ring CY₁ and ring CY₂ may each independently be or include a benzene group, a naphthalene group, an anthracene group, a phenanthrene group, a triphenylene group, a chrysene group, or a pyrene group, but embodiments of the present disclosure are not limited thereto.

In an embodiment, ring CY₁ and ring CY₂ may each be a benzene group, and T₂ in Formula 2-1 may be O.

In an embodiment, in Formula 2, at least one of the c23 R₂₃(s) may be a C₁-C₆₀ alkyl group unsubstituted or substituted with at least one R₁₀ₐ.

In an embodiment, Formula 2 may be represented by Formula 2A:

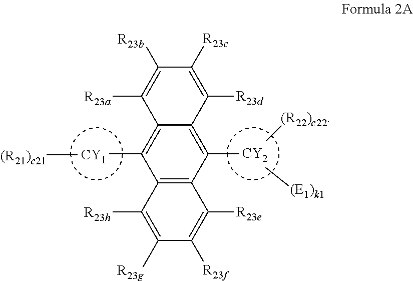

In Formula 2A,

ring CY₁, ring CY₂, R₂₁, c21, R₂₂, c22, E₁, and k1 may each independently be the same as described above,

R₂₃ₐ to R₂₃ₕ may each independently be the same as described in connection with R₂₃ in the present specification, and in some embodiments, R_{23b} may be a C₁-C₆₀ alkyl group unsubstituted or substituted with at least one R₁₀ₐ.

In an embodiment, R_{23b} may be a methyl group, an ethyl group, an n-propyl group, an isopropyl group, an n-butyl group, an isobutyl group, a sec-butyl group, or a tert-butyl group, but embodiments of the present disclosure are not limited thereto.

In an embodiment, the second host may be selected from Compounds FH-1 and FH-2:

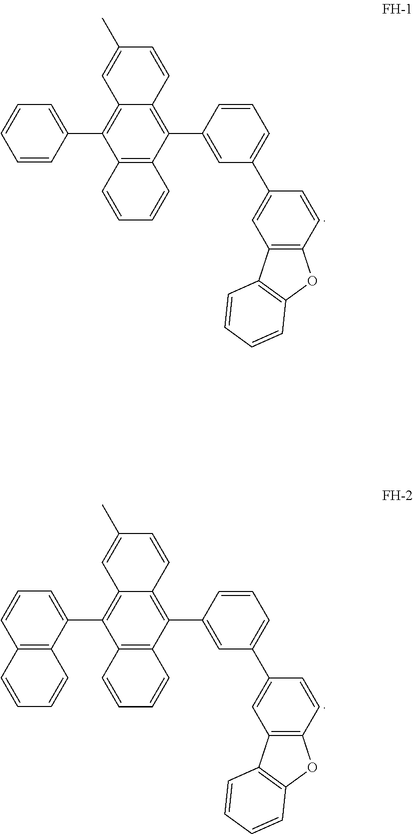 [SMILES: Cc1ccc2c(-c3cccc(-c4ccc5oc6ccccc6c5c4)c3)c3ccccc3c(-c3ccccc3)c2c1 ; Cc1ccc2c(-c3cccc(-c4ccc5oc6ccccc6c5c4)c3)c3ccccc3c(-c3cccc4ccccc34)c2c1]

In an embodiment, the first dopant may have a T₁ value of 2.0 eV or more. In an embodiment, the first dopant may be a phosphorescent dopant or a delayed fluorescence compound (or a delayed fluorescence material). The phosphorescent dopant and the delayed fluorescence material will be described below in more detail.

In an embodiment, the second dopant may have a S1 value of 2.8 eV or more. In an embodiment, the second dopant may be a fluorescent dopant. The fluorescent dopant will be described below in more detail.

In an embodiment, the first dopant may be different from the second dopant.

In an embodiment, the first electrode may be an anode; the second electrode may be a cathode; the interlayer may further include a hole transport region between the first electrode and the first emission layer, and an electron transport region between the second emission layer and the second electrode; the hole transport region may include a hole injection layer, a hole transport layer, an emission auxiliary layer, an electron blocking layer, or any combination thereof; and the electron transport region may include a hole blocking layer, an electron transport layer, an electron injection layer, or any combination thereof.

In an embodiment, the organic light-emitting device may further include a capping layer. The capping layer will be described below in more detail.

An organic light-emitting device according to another embodiment includes: a first electrode;

a second electrode facing the first electrode;

an interlayer including an emission layer between the first electrode and the second electrode,

wherein the emission layer includes a first host, a second host, a first dopant, and a second dopant, and the first dopant is different from the second dopant,

the first host includes (e.g., is) a compound represented by Formula 1, and

the second host includes (e.g., is) a compound represented by Formula 2.

Here, the first host and the second host may each independently be the same as described above. Also, the first dopant may be or include a phosphorescent dopant as described, and the second dopant may be or include a fluorescent dopant as described below, for example in connection with a delayed fluorescence material.

An organic light-emitting device according to another embodiment includes: a first electrode;

a second electrode facing the first electrode; and

an interlayer between the first electrode and the second electrode,

wherein the interlayer includes: m emission units; and

m-1 charge generating units located between two neighboring emission units among the m emission units (e.g., interlayered or interposed with the m emission units), wherein m is an integer of 2 or more,

at least one emission unit among the m emission units includes a first emission layer and a second emission layer,

the first emission layer includes a first host and a first dopant,

the second emission layer includes a second host and a second dopant,

the first emission layer has greater hole mobility than electron mobility,

the second emission layer has greater electron mobility than hole mobility,

the first host has a T₁ value of 2.0 eV or more, and

the second host has a T₁ value of 1.6 eV or more and 1.8 eV or less.

An electronic apparatus according to another embodiment includes the organic light-emitting device.

In an embodiment, the electronic apparatus further includes a thin-film transistor,

the thin-film transistor includes a source electrode and a drain electrode, and

the first electrode of the organic light-emitting device may be electrically connected to at least one of the source electrode and the drain electrode of the thin-film transistor.

In an embodiment, the electronic apparatus may further include quantum dots.

The term “interlayer” as utilized herein refers to a single layer and/or all of a plurality of layers located between a first electrode and a second electrode of an organic light-emitting device.

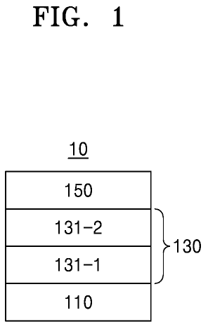

### Description of FIG. 1

FIG. 1 is a schematic cross-sectional view of a light-emitting device 10 according to an embodiment. The light-emitting device (e.g., organic light-emitting device) 10 includes a first electrode 110, an interlayer 130 including a first emission layer 131-1 and a second emission layer 131-2, and a second electrode 150.

Hereinafter, a structure of the light-emitting device 10 according to an embodiment and a method of manufacturing the light-emitting device 10 will be described in connection with FIG. 1.

### First Electrode 110

In FIG. 1, a substrate may be additionally located under the first electrode 110 and/or above the second electrode 150. The substrate may be a glass substrate and/or a plastic substrate. The substrate may be a flexible substrate. In one or more embodiments, the substrate may include a plastic with excellent or suitable heat resistance and durability (such as polyimide, polyethylene terephthalate (PET), polycarbonate, polyethylene naphthalate, polyarylate (PAR), polyetherimide, or any combination thereof).

The first electrode 110 may be formed by, for example, depositing or sputtering a material for forming the first electrode 110 on the substrate. When the first electrode 110 is an anode, a high work function material that can easily inject holes may be utilized as a material for forming the first electrode 110.

The first electrode 110 may be a reflective electrode, a semi-transmissive electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combination thereof may be utilized as a material for forming the first electrode 110.

The first electrode 110 may have a single-layered structure including (e.g., consisting of) a single layer, or a multi-layered structure including a plurality of layers. In an embodiment, the first electrode 110 may have a three-layered structure of ITO/Ag/ITO.

### Interlayer 130

The interlayer 130 is located on the first electrode 110. The interlayer 130 includes a first emission layer 130-1 and a second emission layer 130-2.

In some embodiments, the interlayer 130 may further include a hole transport region between the first electrode 110 and the first emission layer 130-1, and an electron transport region between the second emission layer 130-2 and the second electrode 150.

The interlayer 130 may further include metal-containing compounds (such as organometallic compounds), inorganic materials (such as quantum dots), and/or the like, in addition to one or more suitable organic materials.

In one or more embodiments, the interlayer 130 may include i) two or more emission units sequentially stacked between the first electrode 110 and the second electrode 150, and ii) a charge generation layer located between the two emission units. When the interlayer 130 includes the emission unit and the charge generation layer as described above, the light-emitting device 10 may be a tandem light-emitting device.

### Hole Transport Region in Interlayer 130

The hole transport region may have i) a single-layered structure including (e.g., consisting of) a single layer including (e.g., consisting of) a single material, ii) a single-layered structure including (e.g., consisting of) a single layer including a plurality of different materials, or iii) a multi-layered structure including a plurality of layers including different materials.

The hole transport region may include a hole injection layer, a hole transport layer, an emission auxiliary layer, an electron blocking layer, or any combination thereof.

For example, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein the constituting layers of each structure are stacked sequentially from the first electrode 110.

The hole transport region may include a compound represented by Formula 201, a compound represented by Formula 202, or any combination thereof:

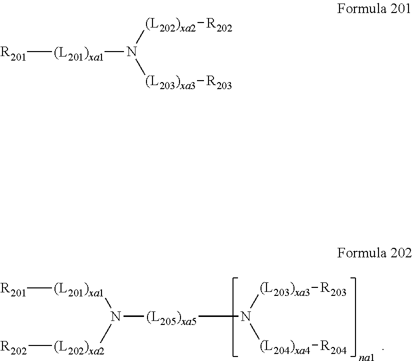

In Formulae 201 and 202,

L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

L₂₀₅ may be *—O—*′, *—S—*′, *—N(Q₂₀₁)—*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

xa1 to xa4 may each independently be an integer from 0 to 5,

xa5 may be an integer from 1 to 10,

R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ (for example, a carbazole group) (for example, see Compound HT16 and/or the like),

R₂₀₃ and R₂₀4 may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and

na1 may be an integer from 1 to 4.

In an embodiment, Formulae 201 and 202 may each include at least one of the groups represented by Formulae CY201 to CY217:

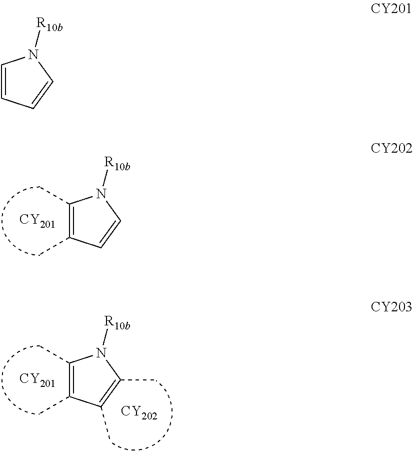

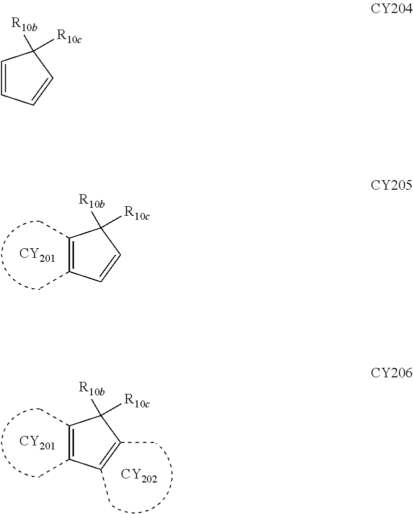

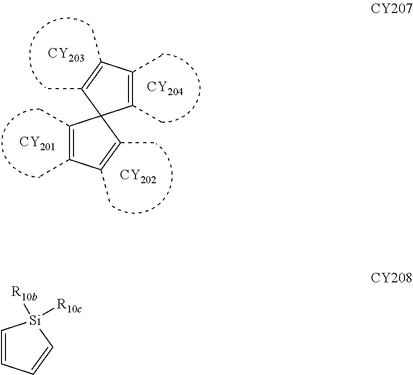

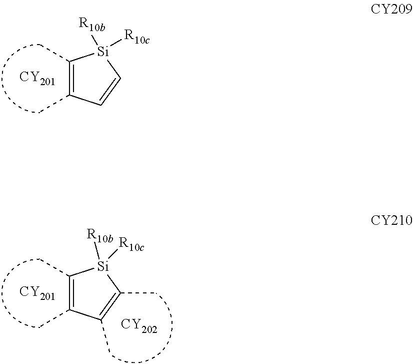

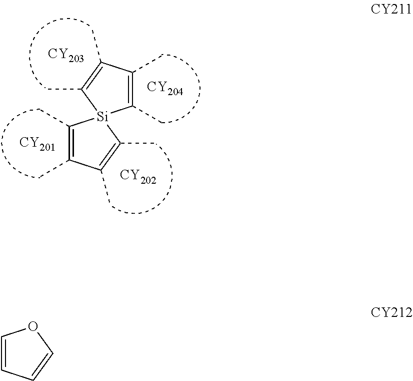

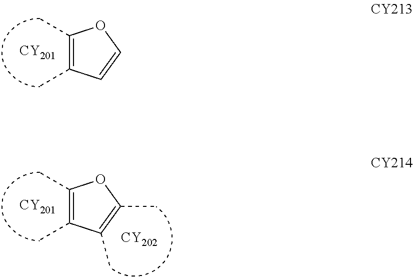

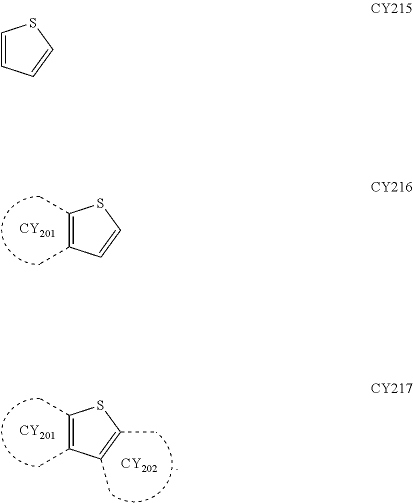

Regarding Formulae CY201 to CY217, R_{10b} and R_{10c} may each independently be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with at least one R₁₀ₐ described herein.

In an embodiment, ring CY₂₀₁ to ring CY₂₀₄ in Formulae CY201 to CY217 may each independently be a benzene group, a naphthalene group, a phenanthrene group, or an anthracene group.

In an embodiment, Formulae 201 and 202 may each include at least one of the groups represented by Formulae CY201 to CY203.

In an embodiment, Formula 201 may include at least one of the groups represented by Formulae CY201 to CY203 and at least one of the groups represented by Formulae CY204 to CY217.

In one or more embodiments, in Formula 201, xa1 may be 1, R₂₀₁ may be a group represented by one of Formulae CY201 to CY203, xa2 may be 0, and R₂₀₂ may be a group represented by one of Formulae CY204 to CY207.

In one or more embodiments, each of Formulae 201 and 202 may not include groups represented by Formulae CY201 to CY203.

In one or more embodiments, each of Formulae 201 and 202 may not include groups represented by Formulae CY201 to CY203 and may include at least one of the groups represented by Formulae CY204 to CY217.

In an embodiment, each of Formulae 201 and 202 may not include groups represented by Formulae CY201 to CY217.

In an embodiment, the hole transport region may include one of Compounds HT1 to HT44, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzene sulfonic acid (PANI/DBSA), poly(3,4-ethylene dioxythiophene)/poly(4-styrene sulfonate) (PEDOT/PSS), polyaniline/camphor sulfonic acid (PANI/CSA), and polyaniline/poly(4-styrene sulfonate) (PANI/PSS), or any combination thereof:

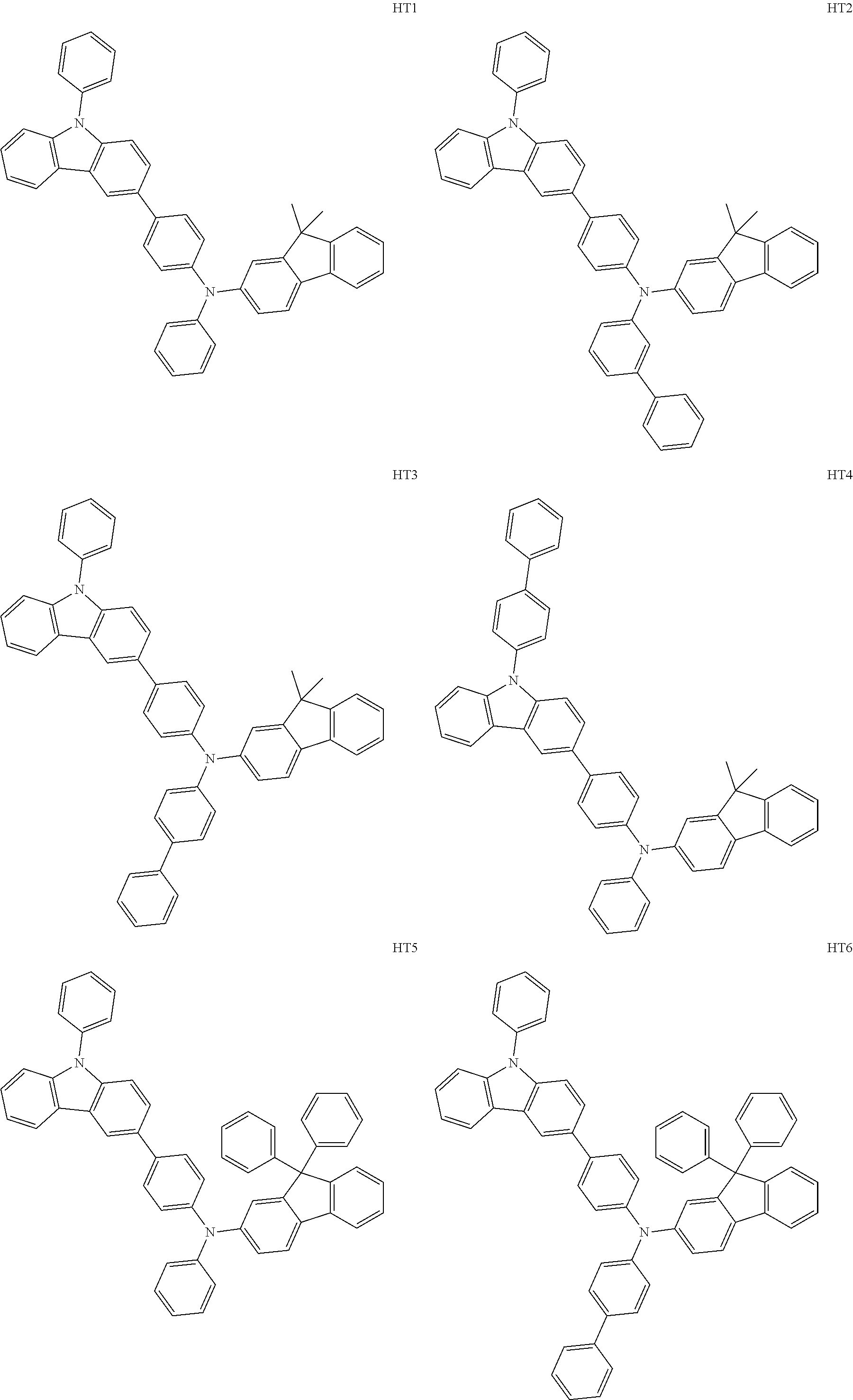

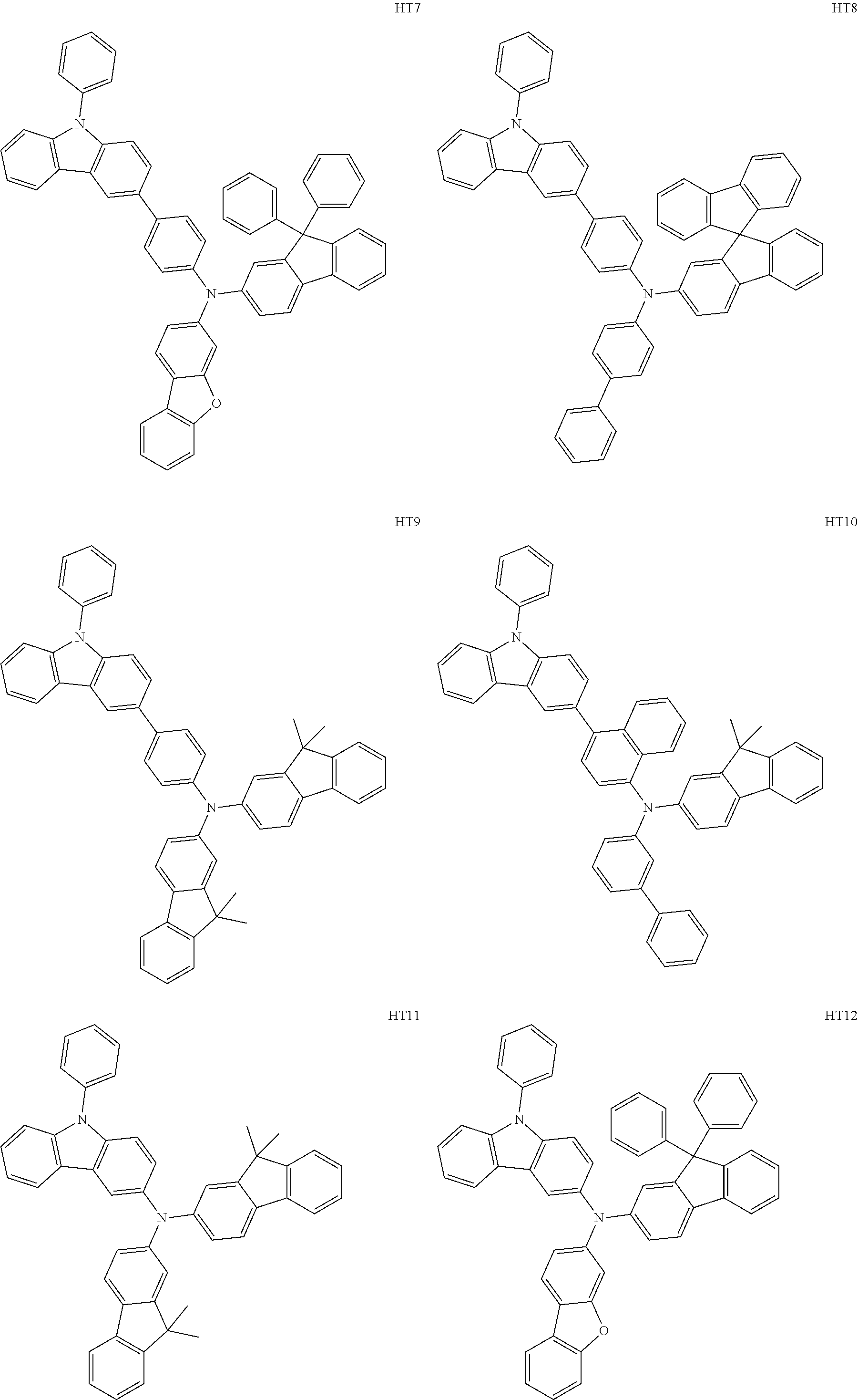

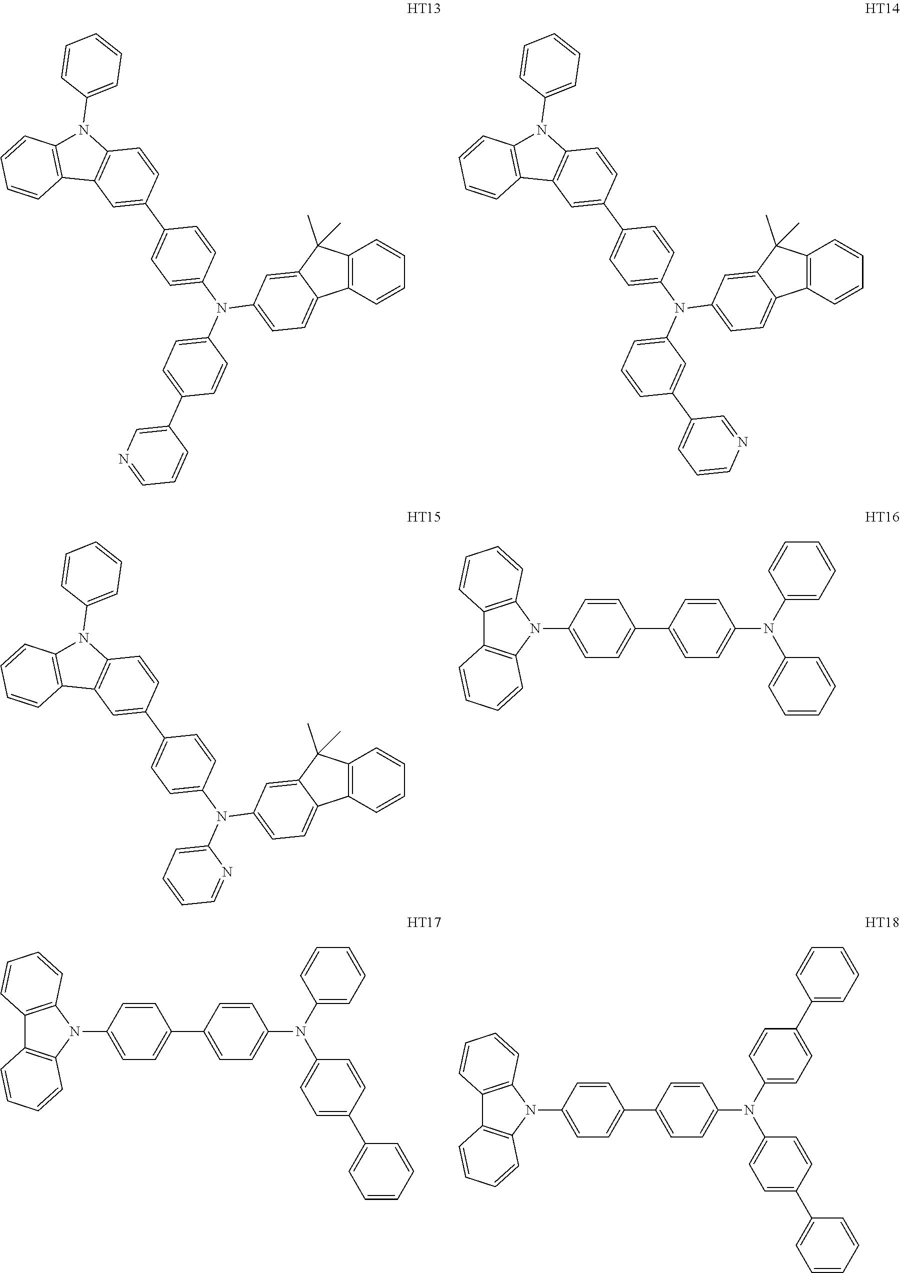 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

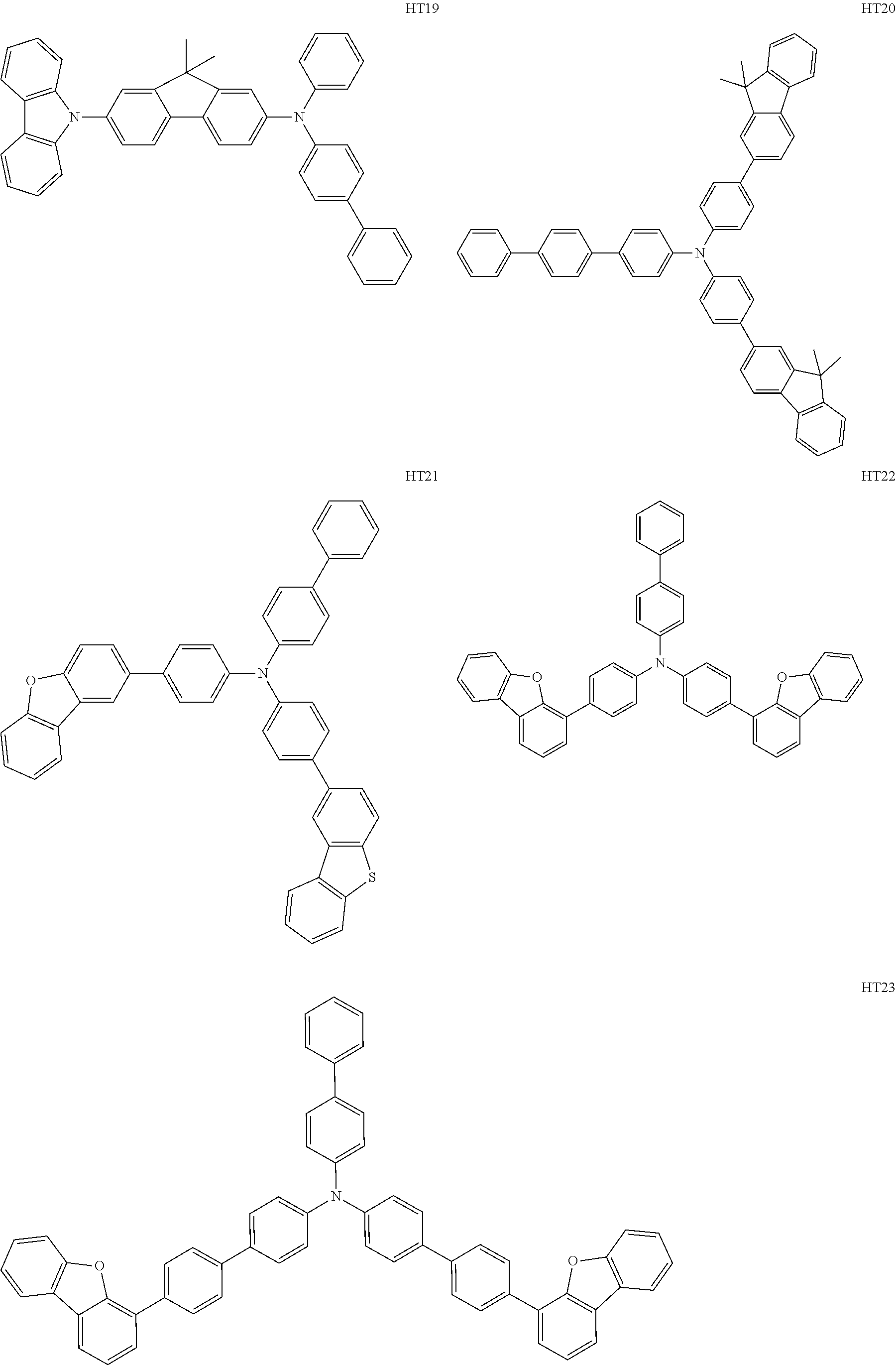 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

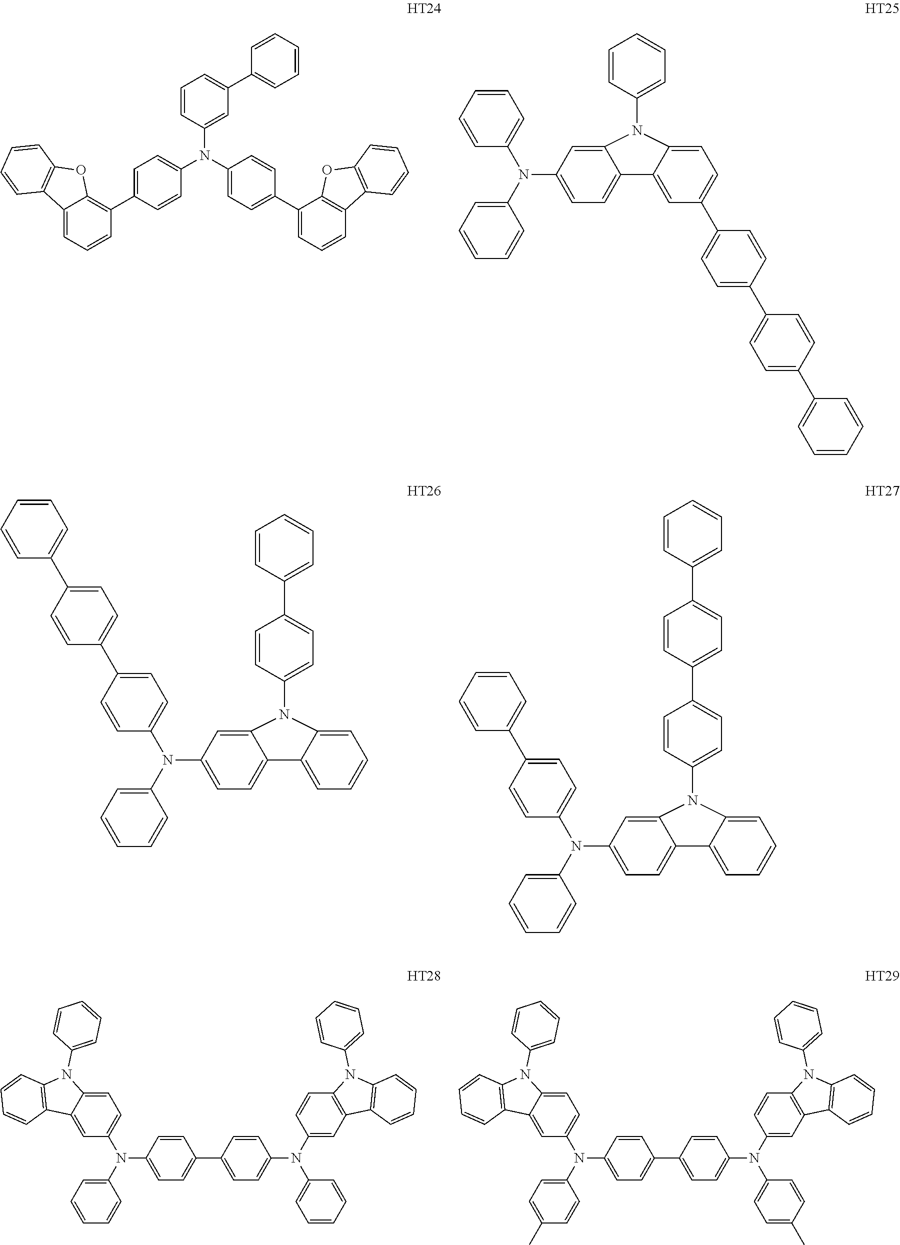

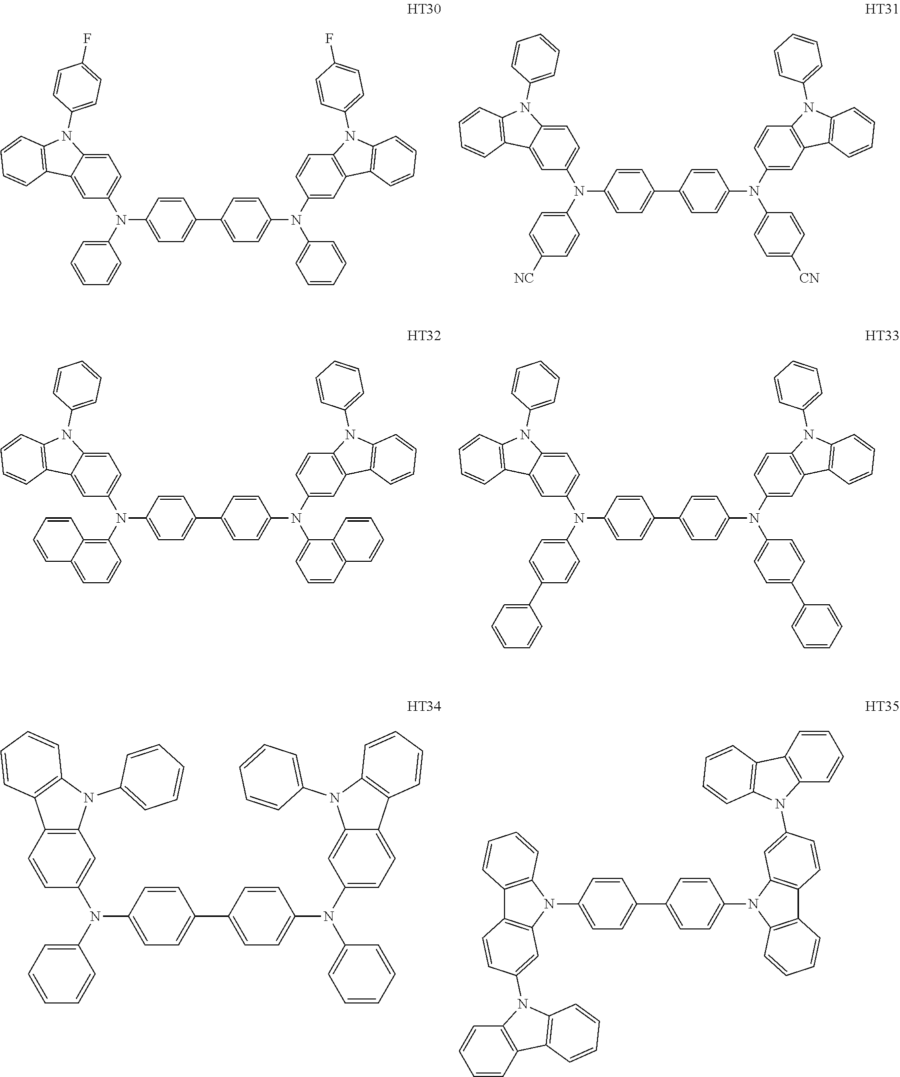

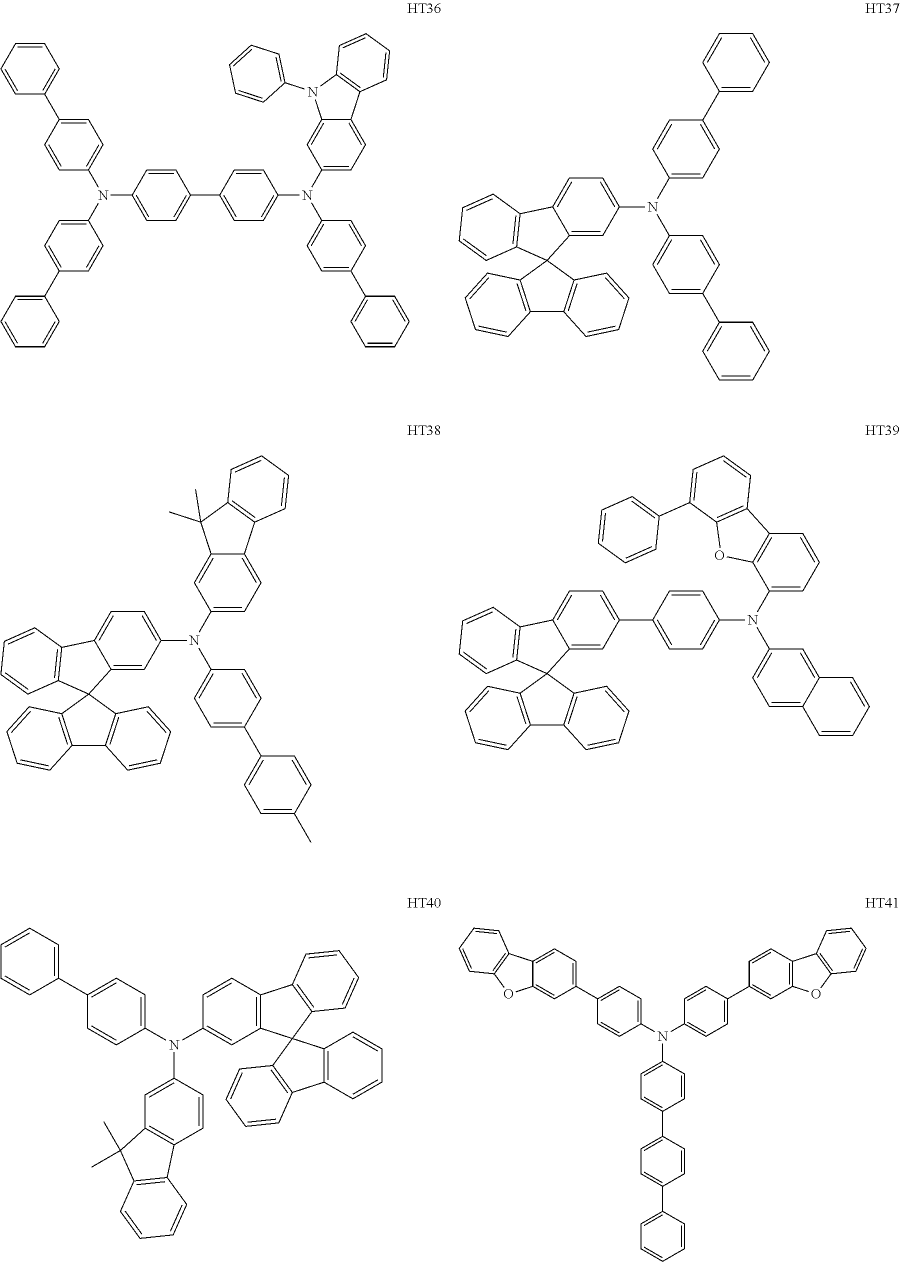

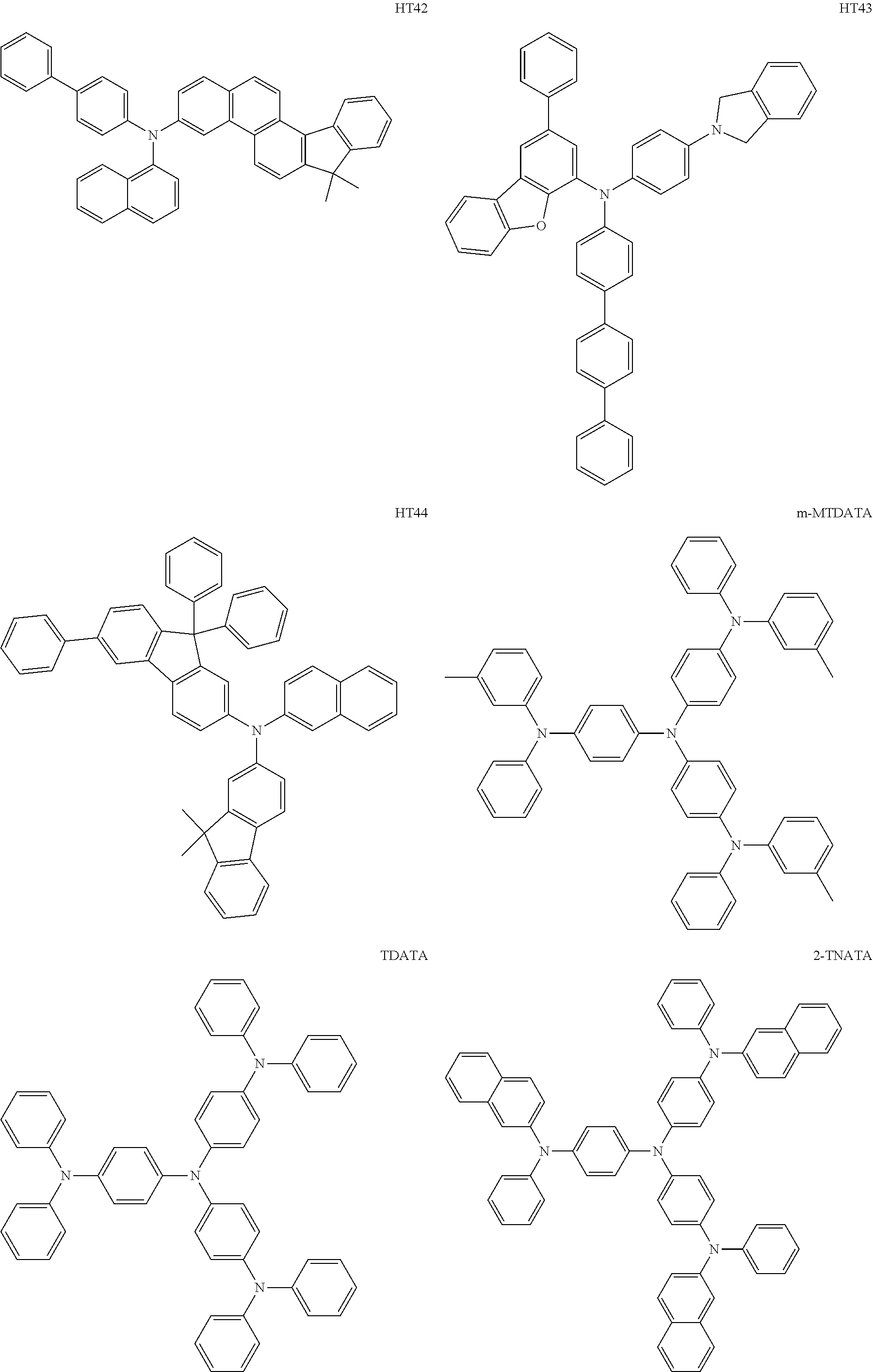

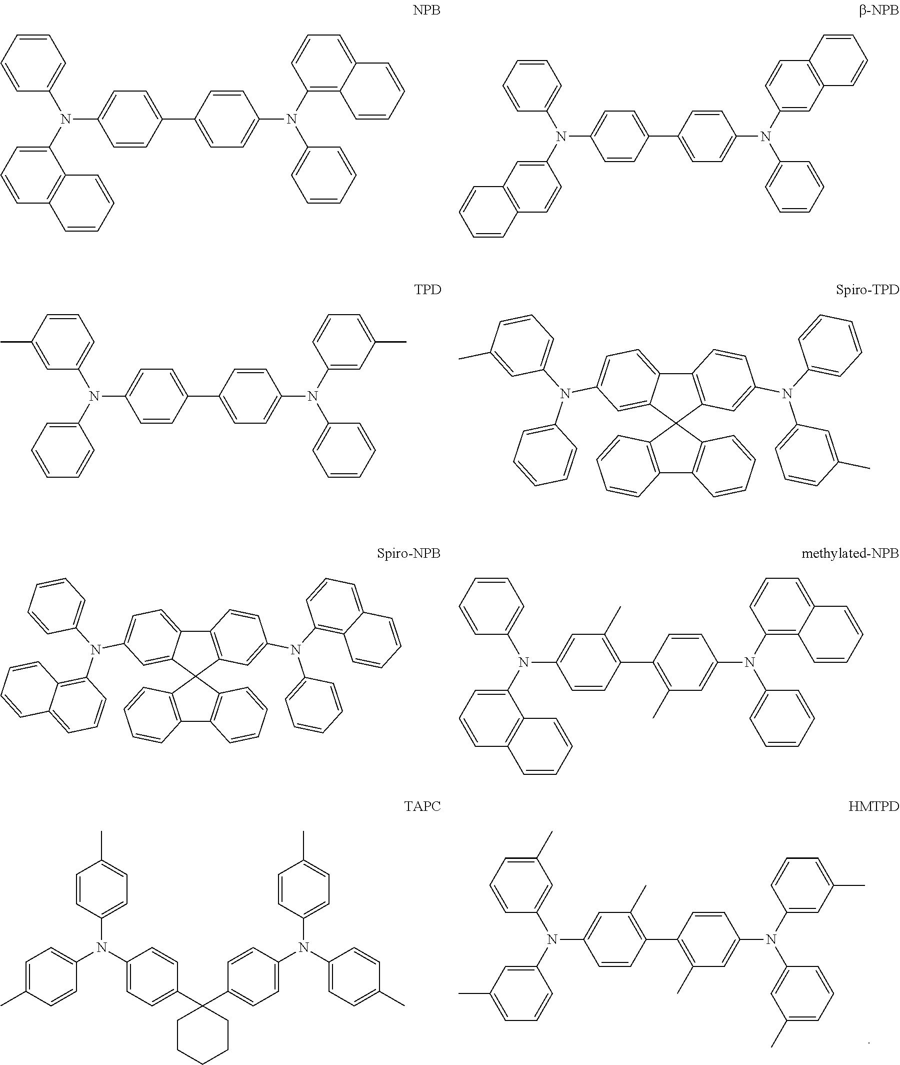

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase the light-emission efficiency of the device by compensating for an optical resonance distance of the wavelength of light emitted by an emission layer, and the electron blocking layer may block or reduce the flow of electrons from an electron transport region. The emission auxiliary layer and the electron blocking layer may include the materials as described above.

p-Dopant

The hole transport region may further include, in addition to these materials, a charge-generating material for the improvement of conductive properties. The charge-generating material may be substantially uniformly or non-uniformly dispersed in the hole transport region (for example, in the form of a single layer of a charge-generating material).

The charge-generating material may be, for example, a p-dopant.

In an embodiment, a lowest unoccupied molecular orbital (LUMO) energy level of the p-dopant may be −3.5 eV or less.

In an embodiment, the p-dopant may include a quinone derivative, a cyano group-containing compound, a compound containing an element EL1 and an element EL2, or any combination thereof.

Non-limiting examples of the quinone derivative may include TCNQ and/or F4-TCNQ.

Non-limiting examples of the cyano group-containing compound may include HAT-CN and/or a compound represented by Formula 221.

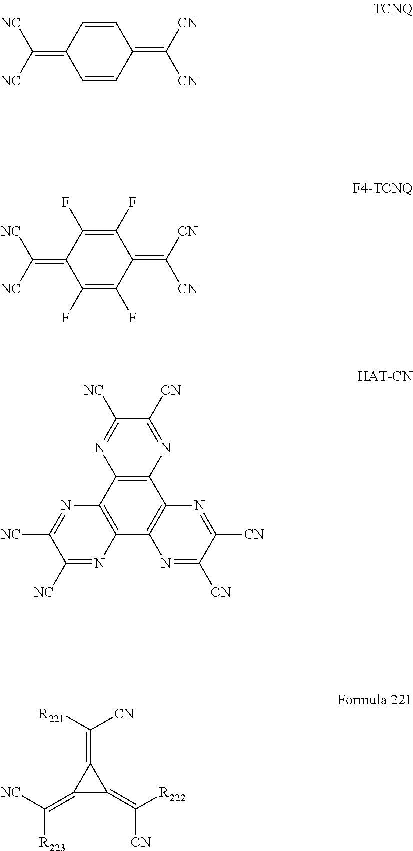

In Formula 221,

R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and

at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

Regarding the compound containing the element EL1 and the element EL2, element EL1 may be a metal, a metalloid, or a combination thereof, and element EL2 may be a non-metal, a metalloid, or a combination thereof.

Non-limiting examples of the metal may include: an alkali metal (for example, lithium (Li), sodium (Na), potassium (K), rubidium (Rb), cesium (Cs), and/or the like); an alkaline earth metal (for example, beryllium (Be), magnesium (Mg), calcium (Ca), strontium (Sr), barium (Ba), and/or the like); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper(Cu), silver (Ag), gold (Au), and/or the like); a post-transition metal (for example, zinc (Zn), indium (In), tin (Sn), and/or the like); and/or a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like).

Non-limiting examples of the metalloid may include silicon (Si), antimony (Sb), and/or tellurium (Te).

Non-limiting examples of the non-metal may include oxygen (O) and/or halogen (for example, F, Cl, Br, I, etc.).

In an embodiment, non-limiting examples of the compound containing element EL1 and element EL2 may include a metal oxide, a metal halide (for example, a metal fluoride, a metal chloride, a metal bromide, and/or a metal iodide), a metalloid halide (for example, a metalloid fluoride, a metalloid chloride, a metalloid bromide, and/or a metalloid iodide), a metal telluride, and/or any combination thereof.

Non-limiting examples of the metal oxide may include a tungsten oxide (for example, WO, W₂O₃, WO₂, WO₃, and/or W₂O₅), a vanadium oxide (for example, VO, V₂O₃, VO₂, and/or V₂O₅), a molybdenum oxide (MoO, Mo₂O₃, MoO₂, MoO₃, and/or Mo₂O₅), and/or a rhenium oxide (for example, ReO₃).

Non-limiting examples of the metal halide may include alkali metal halide, alkaline earth metal halide, transition metal halide, post-transition metal halide, and/or lanthanide metal halide.

Non-limiting examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, and/or CsI.

Non-limiting examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, and/or BaI₂.

Non-limiting examples of the transition metal halide may include a titanium halide (for example, TiF₄, TiCl₄, TiBr₄, and/or TiI₄), a zirconium halide (for example, ZrF₄, ZrCl₄, ZrBr₄, and/or ZrI₄), a hafnium halide (for example, HfF₄, HfCl₄, HfBr₄, and/or HfI₄), a vanadium halide (for example, VF₃, VCl₃, VBr₃, and/or VI₃), a niobium halide (for example, NbF₃, NbCl₃, NbBr₃, and/or NbI₃), a tantalum halide (for example, TaF₃, TaCl₃, TaBr₃, and/or TaI₃), a chromium halide (for example, CrF₃, CrO₃, CrBr₃, and/or CrI₃), a molybdenum halide (for example, MoF₃, MoCl₃, MoBr₃, and/or MoI₃), a tungsten halide (for example, WF₃, WCl₃, WBr₃, and/or WI₃), a manganese halide (for example, MnF₂, MnCl₂, MnBr₂, and/or MnI₂), a technetium halide (for example, TcF₂, TcCl₂, TcBr₂, and/or TcI₂), a rhenium halide (for example, ReF₂, ReCl₂, ReBr₂, and/or ReI₂), an iron halide (for example, FeF₂, FeCl₂, FeBr₂, and/or FeI₂), a ruthenium halide (for example, RuF₂, RuCl₂, RuBr₂, and/or RuI₂), an osmium halide (for example, OsF₂, OsCl₂, OsBr₂, and/or OsI₂), a cobalt halide (for example, CoF₂, COCl₂, CoBr₂, and/or Col₂), a rhodium halide (for example, RhF₂, RhCl₂, RhBr₂, and/or RhI₂), an iridium halide (for example, IrF₂, IrCl₂, IrBr₂, and/or IrI₂), a nickel halide (for example, NiF₂, NiCl₂, NiBr₂, and/or NiI₂), a palladium halide (for example, PdF₂, PdCl₂, PdBr₂, and/or PdI₂), a platinum halide (for example, PtF₂, PtCl₂, PtBr₂, and/or PtI₂), a copper halide (for example, CuF, CuCl, CuBr, and/or Cul), a silver halide (for example, AgF, AgCl, AgBr, and/or AgI), and/or a gold halide (for example, AuF, AuCl, AuBr, and/or AuI).

Non-limiting examples of the post-transition metal halide may include a zinc halide (for example, ZnF₂, ZnCl₂, ZnBr₂, and/or ZnI₂), an indium halide (for example, InI₃), and/or a tin halide (for example, SnI₂).

Non-limiting examples of the lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, and/or SmI₃.

Non-limiting examples of the metalloid halide may include antimony halide (for example, SbCl₅).

Non-limiting examples of the metal telluride may include an alkali metal telluride (for example, Li₂Te, Na₂Te, K₂Te, Rb₂Te, and/or Cs₂Te), an alkaline earth metal telluride (for example, BeTe, MgTe, CaTe, SrTe, and/or BaTe), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, and/or Au₂Te), a post-transition metal telluride (for example, In₂Te₃, SnTe, and/or ZnTe), and/or a lanthanide metal telluride (for example, LaTe, CeTe, PrTe, NdTe, PmTe, EuTe, GdTe, TbTe, DyTe, HoTe, ErTe, TmTe, YbTe, and/or LuTe).

### Emission Layer in Interlayer 130

When the light-emitting device 10 is a full-color light-emitting device, the emission layer may be patterned into a red emission layer, a green emission layer, and/or a blue emission layer, according to a sub-pixel. In one or more embodiments, the emission layer may have a stacked structure of two or more layers of a red emission layer, a green emission layer, and a blue emission layer, in which the two or more layers may contact each other or may be separated from each other. In one or more embodiments, the emission layer may include two or more materials of a red light-emitting material, a green light-emitting material, and a blue light-emitting material, in which the two or more materials may be mixed with each other in a single layer to emit white light.

The emission layer may include a host and a dopant. The dopant may include a phosphorescent dopant, a fluorescent dopant, or any combination thereof.

An amount of the dopant in the emission layer may be from about 0.01 to about 15 parts by weight based on 100 parts by weight of the host.

In an embodiment, the emission layer may include a delayed fluorescence material. The delayed fluorescence material may act as a host or a dopant in the emission layer.

A thickness of the emission layer may be in a range of about 100 Å to about 1,000 Å, for example, about 200 Å to about 600 Å. When the thickness of the emission layer is within these ranges, excellent or suitable light-emission characteristics may be obtained without a substantial increase in driving voltage.

### Host in Emission Layer

The first host and the second host of the emission layer may each independently be the same as described above.

### Phosphorescent Dopant

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

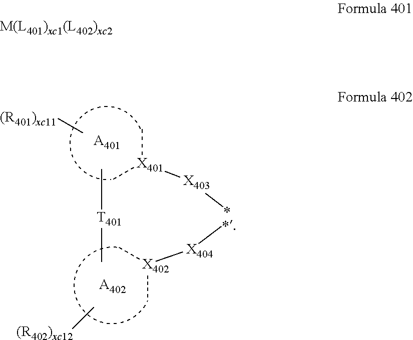

In Formulae 401 and 402,

M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), and/or thulium (Tm)),

L₄₀₁ may be a ligand represented by Formula 402, and xc1 may be 1, 2, or 3, wherein, when xc1 is 2 or more, two or more L₄₀₁ (s) may be identical to or different from each other,

L₄₀₂ may be an organic ligand, and xc2 may be 0, 1, 2, 3, or 4, wherein, when xc2 is 2 or more, two or more L₄₀₂(s) may be identical to or different from each other,

X₄₀₁ and X₄₀₂ may each independently be nitrogen or carbon,

ring A401 and ring A402 may each independently be a C₃-C₆₀ carbocyclic group or a C₁-C₆₀ heterocyclic group,

T₄₀₁ may be a single bond, *—O—*′, *—S—*′, *—C(═O)—*′, *—N(Q₄₁₁)—*′, *—C(Q₄₁₁)(Q₄₁₂)—*′, *—C(Q₄₁₁)═C(Q₄₁₂)—*′, *—C(Q₄₁₁)═*′, or *═C═*′,

X₄₀₃ and X₄₀₄ may each independently a chemical bond (for example, a covalent bond or a coordination bond), O, S, N(Q₄₁₃), B(Q₄₁₃), P(Q₄₁₃), C(Q₄₁₃)(Q₄₁₄), or Si(Q₄₁₃)(Q₄₁₄),

Q₄₁₁ to Q₄₁₄ may each independently be the same as described in connection with Q₁ in the present specification,

R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),

Q₄₀₁ to Q₄₀₃ may each independently be the same as described in connection with Q₁ in the present specification,

xc11 and xc12 may each independently be an integer from 0 to 10, and

* and *′ in Formula 402 each indicate a binding site to M in Formula 401.

In an embodiment, in Formula 402, i) X₄₀₁ may be nitrogen, and X₄₀₂ may be carbon, or ii) both X₄₀₁ and X₄₀₂ may be nitrogen (e.g., simultaneously).

In an embodiment, when xc1 in Formula 401 is 2 or more, two ring A401(s) in two or more L₄₀₁(s) may optionally be linked to each other via T₄₀₂, which is a linking group, or two ring A₄₀₂(s) in two or more L₄₀₁(s) may optionally be linked to each other via T₄₀₃, which is a linking group (see Compounds PD1 to PD4 and PD7). T₄₀₂ and T₄₀₃ may each independently be the same as described in connection with T₄₀₁.

L₄₀₂ in Formula 401 may be an organic ligand. In an embodiment, L₄₀₂ may include a halogen group, a diketone group (for example, an acetylacetonate group), a carboxylic acid group (for example, a picolinate group), —C(═O), a isonitrile group, a —CN group, a phosphorus group (for example, a phosphine group and/or a phosphite group), or any combination thereof.

The phosphorescent dopant may include, for example, one of Compounds PD1 to PD29, or any combination thereof:

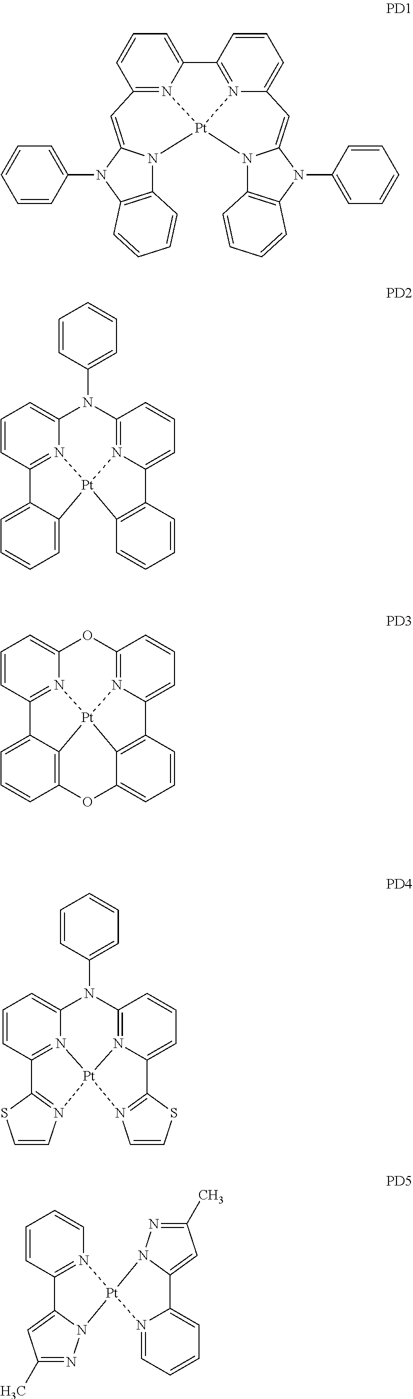

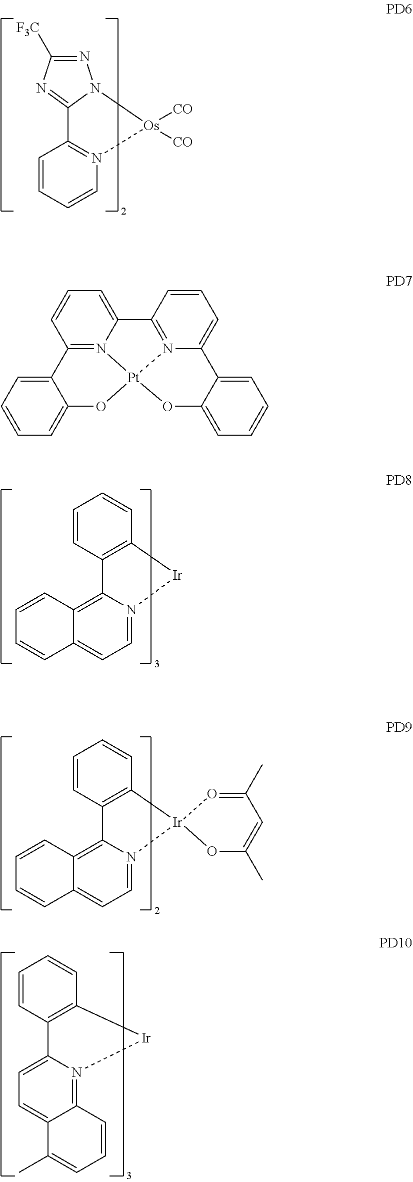

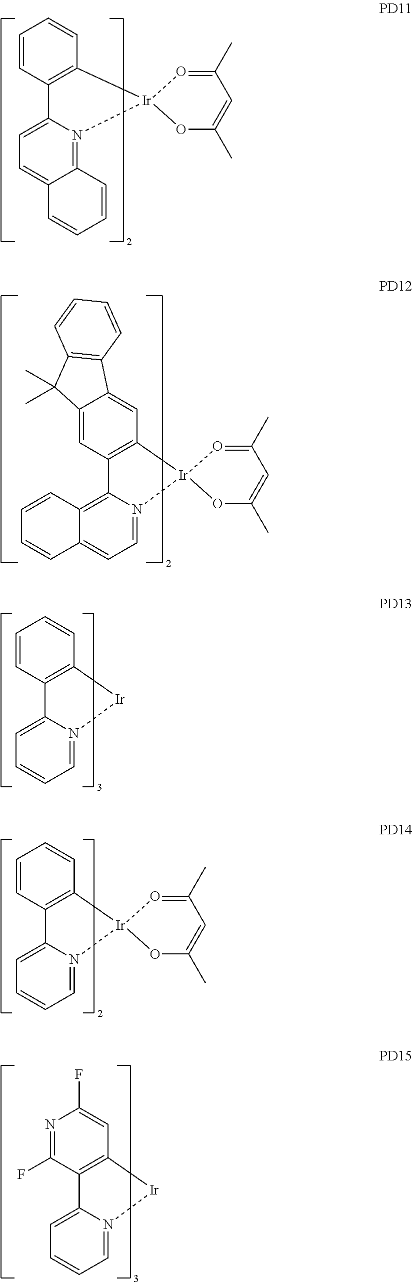

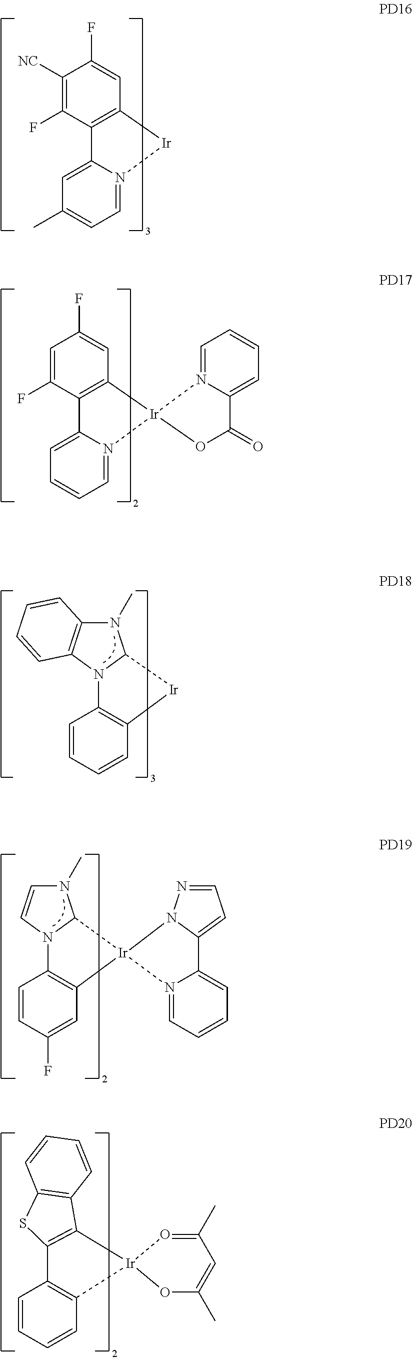

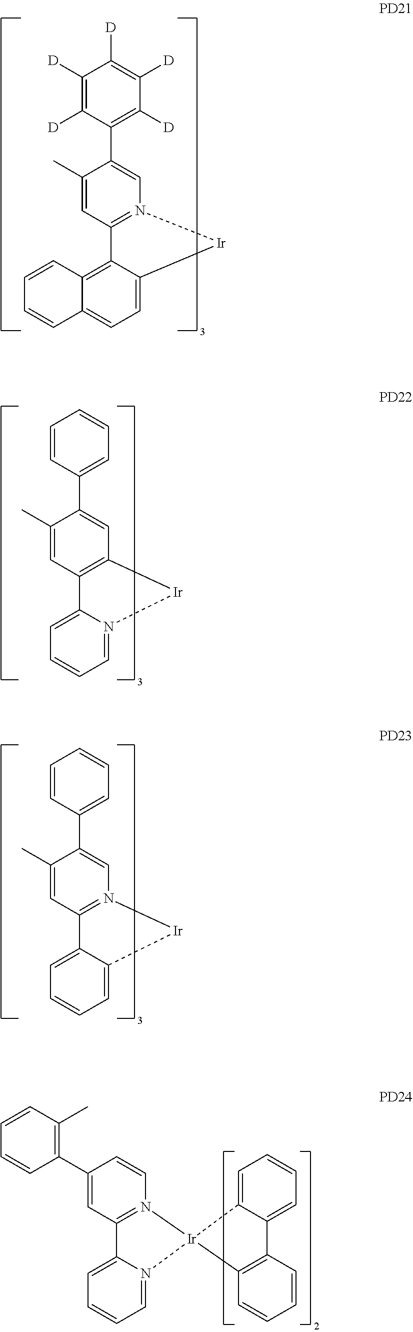

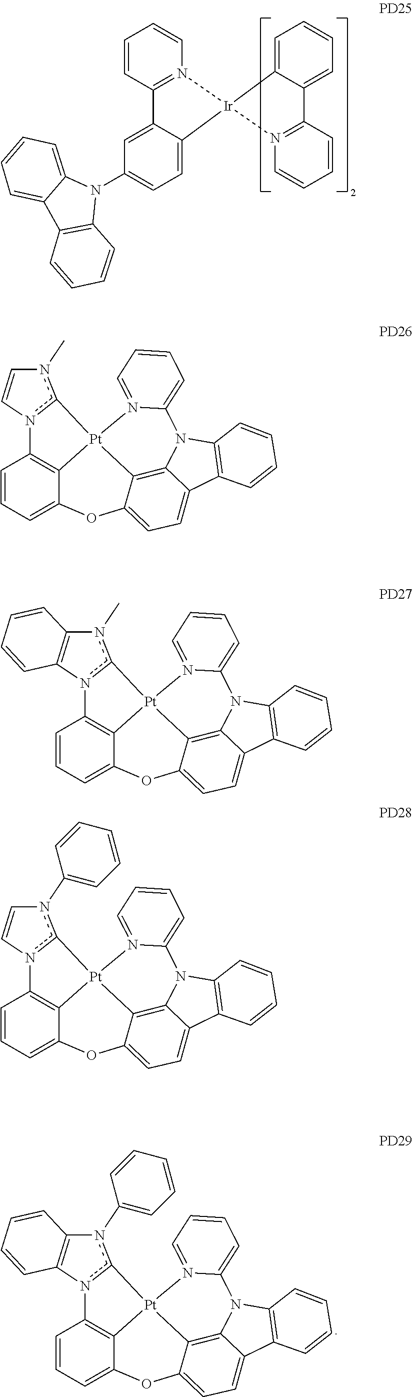

### Fluorescent Dopant

The fluorescent dopant may include an amine group-containing compound, a styryl group-containing compound, a boron-nitrogen compound, or any combination thereof.

In an embodiment, the fluorescent dopant may include a compound represented by Formula 501:

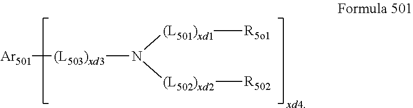

In Formula 501,

Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xd1 to xd3 may each independently be 0, 1, 2, or 3, and

xd4 may be 1, 2, 3, 4, 5, or 6.

In an embodiment, Ar₅₀₁ in Formula 501 may be a condensed cyclic group (for example, an anthracene group, a chrysene group, or a pyrene group) in which three or more monocyclic groups are condensed.

In an embodiment, xd4 in Formula 501 may be 2.

In an embodiment, the fluorescent dopant may include one of Compounds FD1 to FD44, DPVBi, and DPAVBi, or any combination thereof:

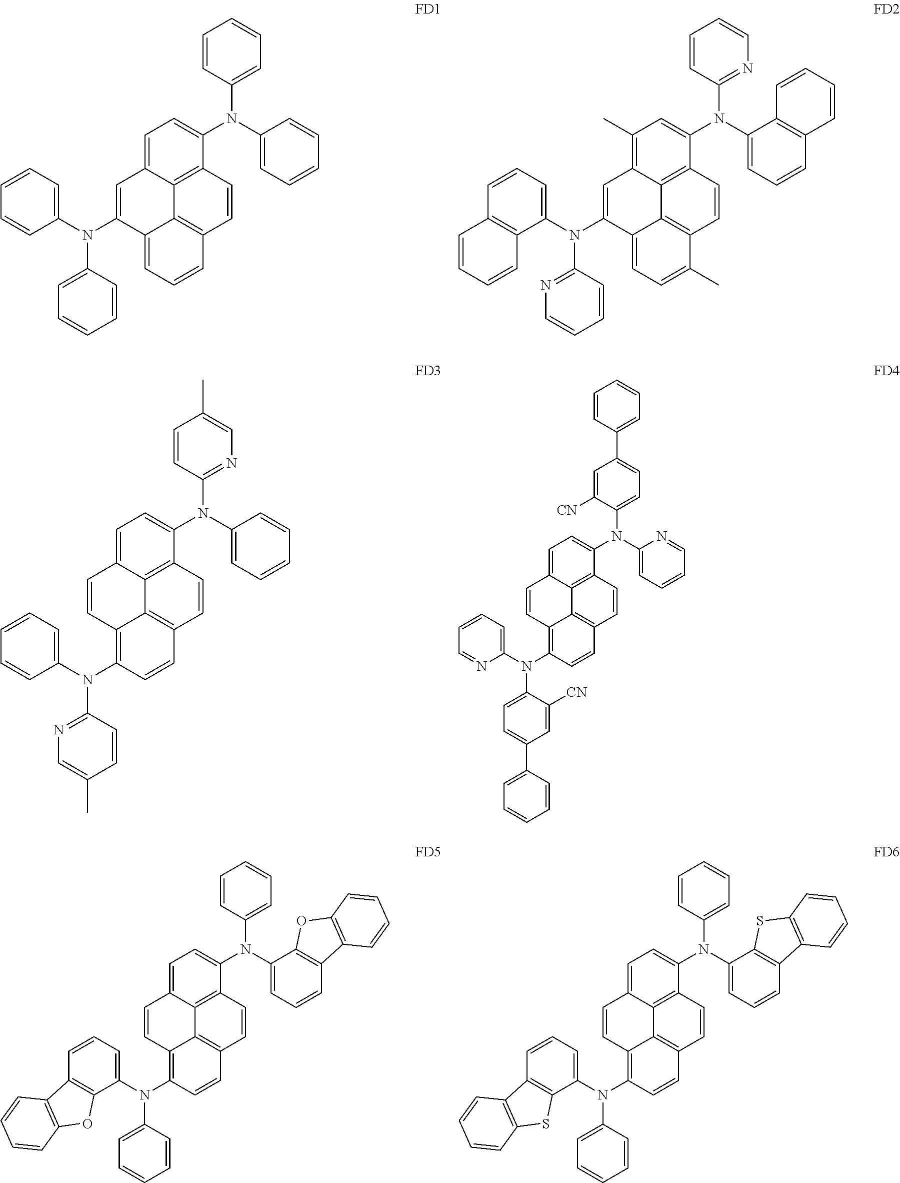

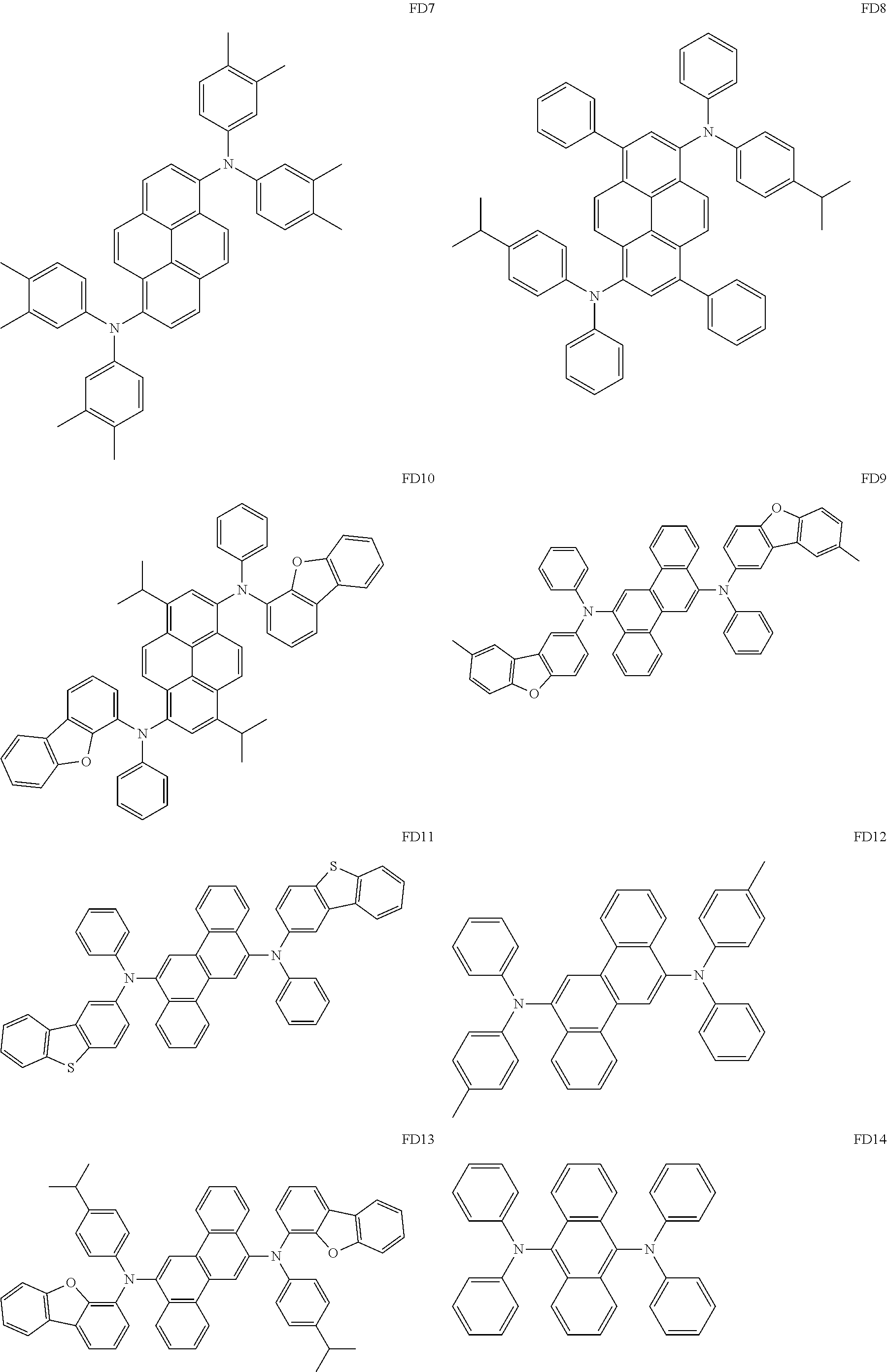

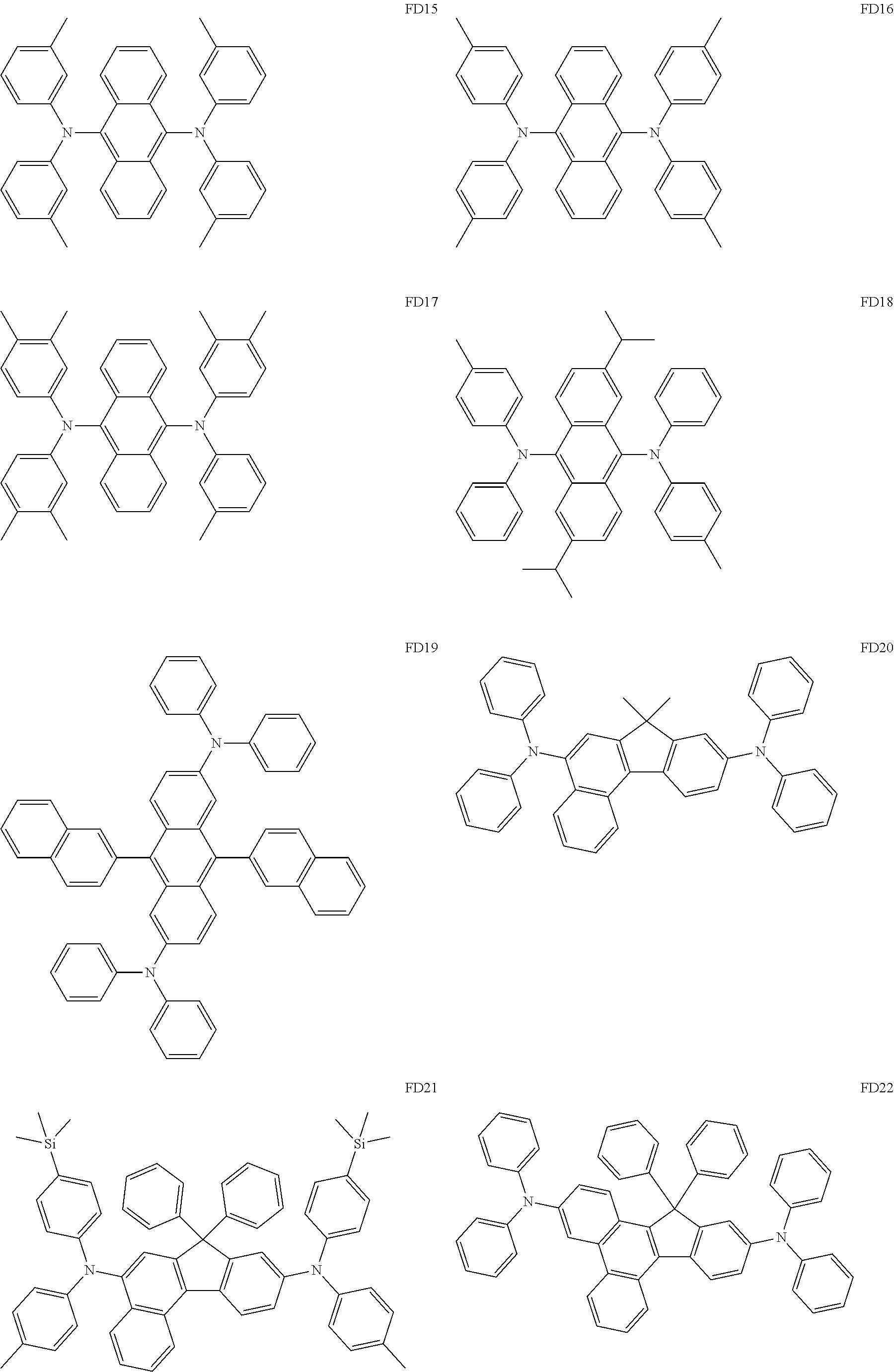

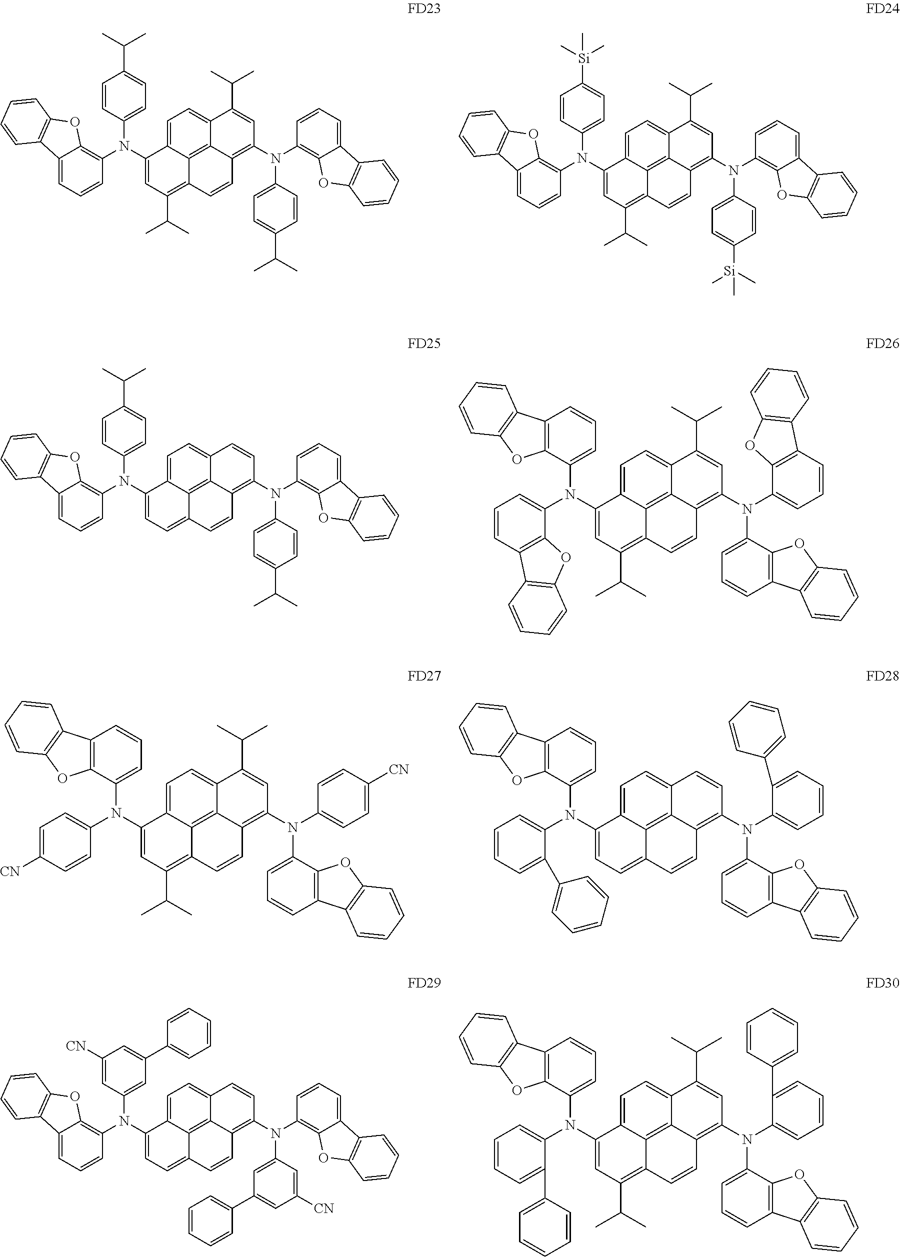

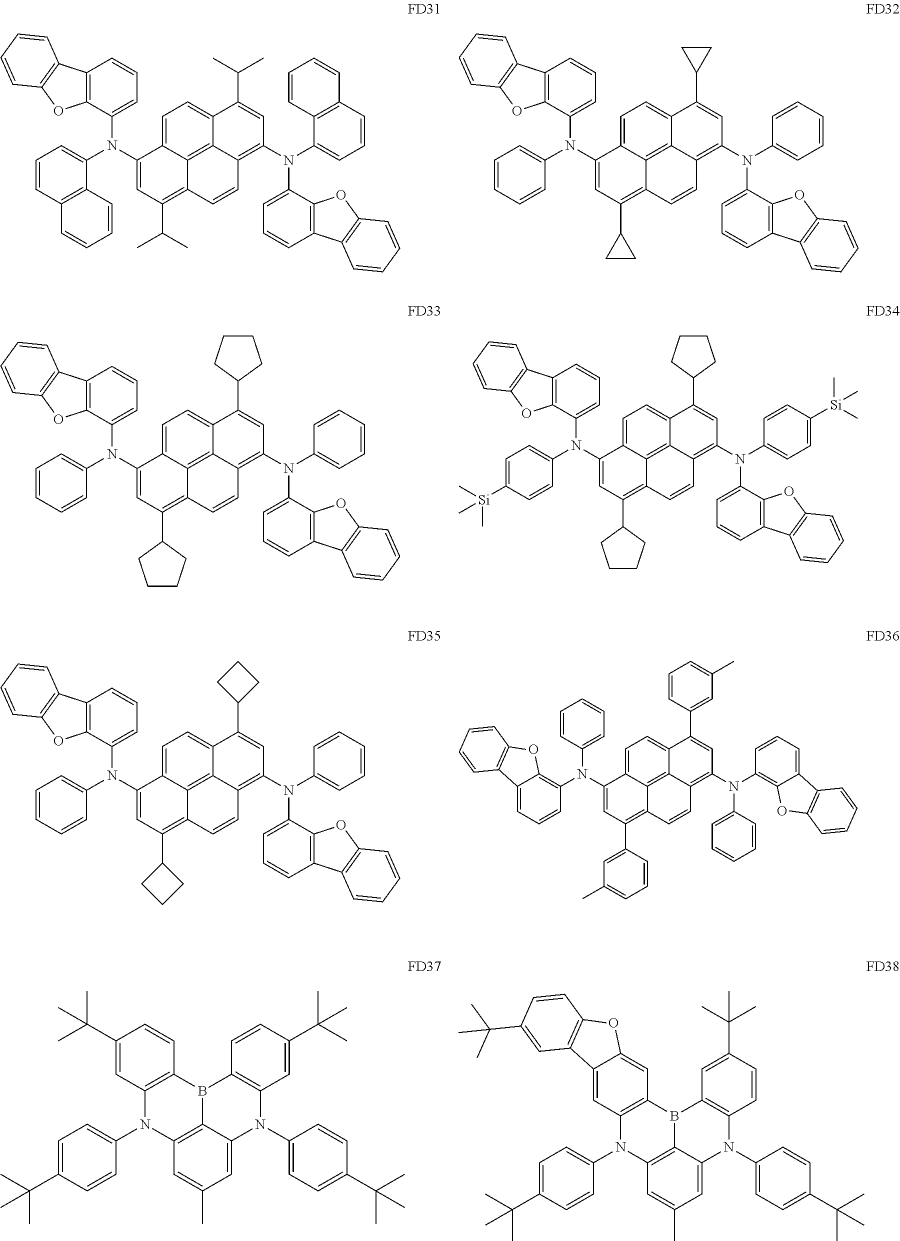

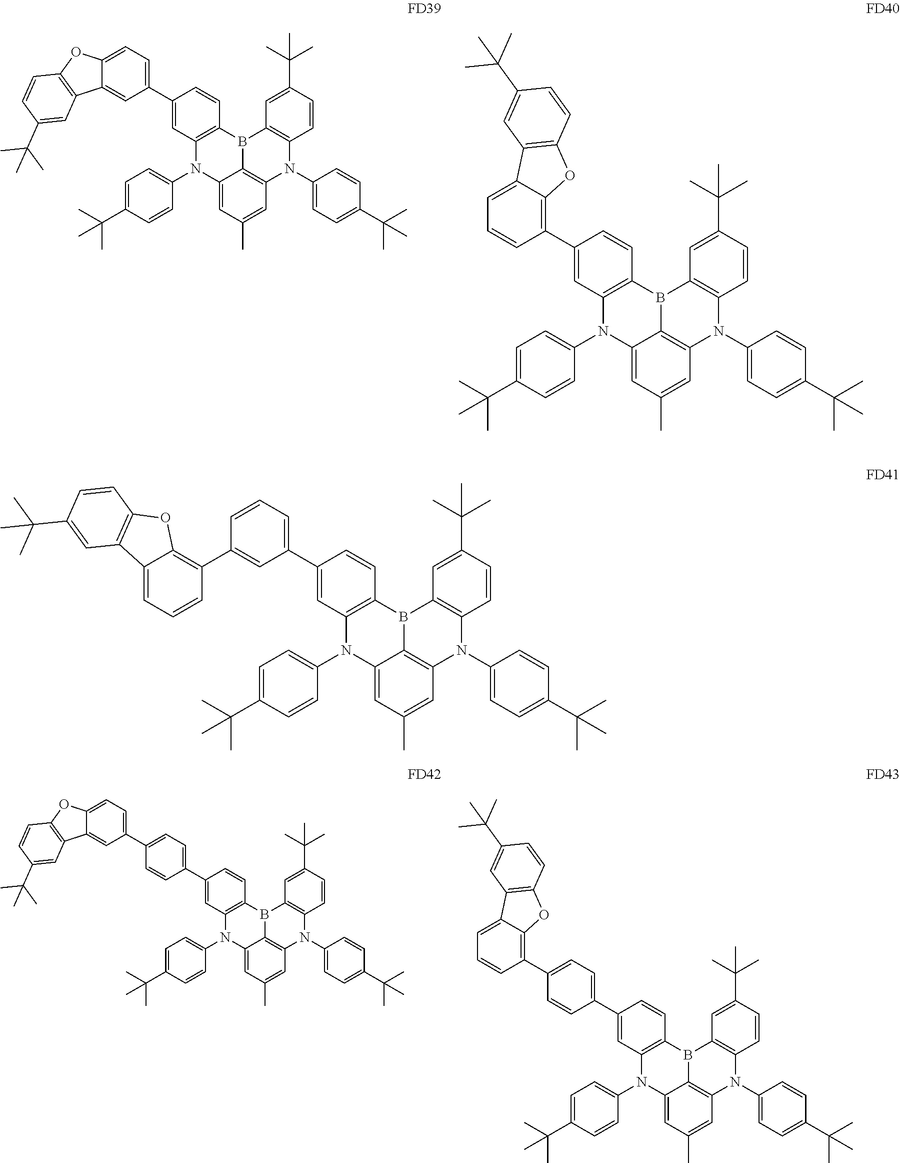

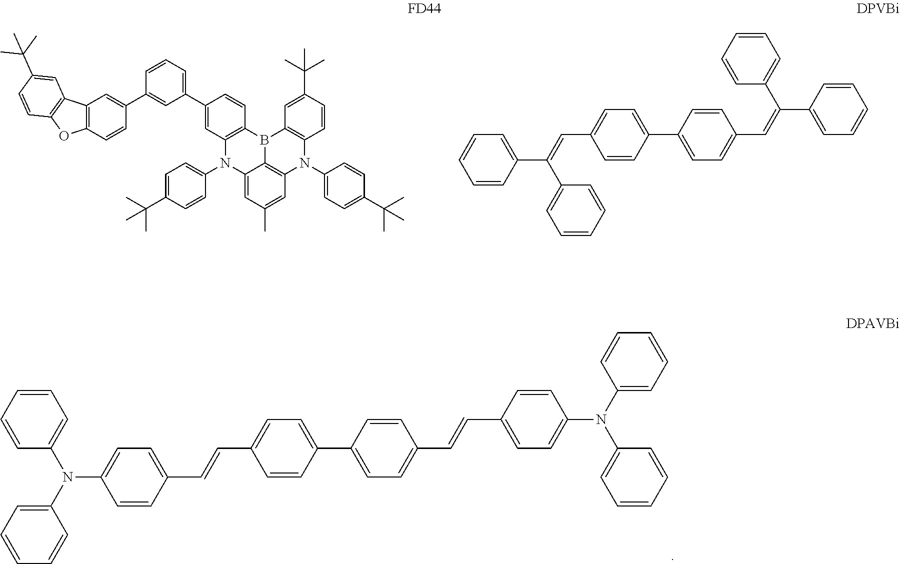

### Delayed Fluorescence Material

The emission layer may include a delayed fluorescence material.

The delayed fluorescence material utilized herein may be selected from any compound that is capable of emitting delayed fluorescent light based on a delayed fluorescent emission mechanism.

The delayed fluorescence material included in the emission layer may act as a host or a dopant depending on the type or kind of other materials included in the emission layer.

In an embodiment, the difference between the triplet energy level (eV) of the delayed fluorescence material and the singlet energy level (eV) of the delayed fluorescence material may be 0 eV or more and 0.5 eV or less. When the difference between the triplet energy level (eV) of the delayed fluorescence material and the singlet energy level (eV) of the delayed fluorescence material satisfies the above-described range, up-conversion from the triplet state to the singlet state of the delayed fluorescence materials may effectively occur, and thus, the luminescence efficiency of the light-emitting device 10 may be improved.

In an embodiment, the delayed fluorescence material may include i) a material that includes at least one electron donor (for example, a π electron-rich C₃-C₆₀ cyclic group, such as a carbazole group) and at least one electron acceptor (for example, a sulfoxide group, a cyano group, or a π-electron-deficient nitrogen-containing C₁-C₆₀ cyclic group), and/or ii) a material including a C₈-C₆₀ polycyclic group in which two or more cyclic groups share a boron (B) atom and are condensed with each other.

The delayed fluorescence material may include at least one of Compounds DF1 to DF9:

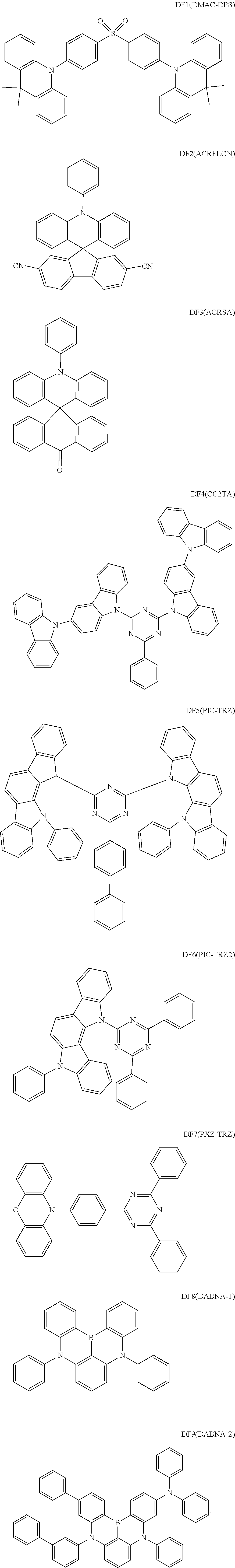

### Quantum Dot

The emission layer may include a quantum dot.

The term “quantum dot” as utilized herein refers to a crystal of a semiconductor compound, and may include any material that is capable of emitting light of one or more suitable emission wavelengths according to the size (diameter) of the crystal.

A diameter of the quantum dot may be, for example, in a range of about 1 nm to about 10 nm.

The quantum dot may be synthesized by a wet chemical process, a metal organic chemical vapor deposition process, a molecular beam epitaxy process, or a process that is similar to these processes.

The term “wet chemical process” refers to a method in which an organic solvent and a precursor material are mixed, and then, a quantum dot particle crystal is grown. When the quantum dot particle crystal grows, the organic solvent may act as a dispersant naturally coordinated on the surface of the quantum dot particle crystal, and may thereby control the growth of the quantum dot particle crystal. Accordingly, the growth of quantum dot particle crystal may be controlled or selected by utilizing a process that is easily performed at low cost compared to a vapor deposition process (such as a metal organic chemical vapor deposition (MOCVD) process and/or a molecular beam epitaxy (MBE) process).

The quantum dot may include a Group III-VI semiconductor compound, a Group II-VI semiconductor compound, a Group III-V semiconductor compound, a Group I-III-VI semiconductor compound, a Group IV-VI semiconductor compound, a Group IV element or compound, or any combination thereof.

Non-limiting examples of the Group II-VI semiconductor compound may include: a binary compound (such as CdSe, CdTe, ZnS, ZnSe, ZnTe, ZnO, HgS, HgSe, HgTe, MgSe, and/or MgS); a ternary compound (such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS); a quaternary compound (such as CdZnSeS, CdZnSeTe, CdZnSTe, CdHgSeS, CdHgSeTe, CdHgSTe, HgZnSeS, HgZnSeTe, and/or HgZnSTe); or any combination thereof.

Non-limiting examples of the Group III-V semiconductor compound may include: a binary compound (such as GaN, GaP, GaAs, GaSb, AlN, AlP, AlAs, AlSb, InN, InP, InAs, and/or InSb); a ternary compound (such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb); a quaternary compound (such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb); or any combination thereof. In an embodiment, the Group III-V semiconductor compound may further include a Group II element. Non-limiting examples of the Group III-V semiconductor compound further including a Group II element may include InZnP, InGaZnP, or InAIZnP.

Non-limiting examples of the Group III-VI semiconductor compound may include: a binary compound (such as GaS, GaSe, Ga₂Se₃, GaTe, InS, In₂S₃, InSe, In₂Se₃, and/or InTe); a ternary compound (such as InGaS₃ and/or InGaSe₃); or any combination thereof.

Non-limiting examples of the Group I-III-VI semiconductor compound may include: a ternary compound (such as AgInS, AgInS₂, CuInS, CuInS₂, CuGaO₂, AgGaO₂, and/or AgAlO₂); or any combination thereof.

Non-limiting examples of the Group IV-VI semiconductor compound may include: a binary compound (such as SnS, SnSe, SnTe, PbS, PbSe, and/or PbTe); a ternary compound (such as SnSeS, SnSeTe, SnSTe, PbSeS, PbSeTe, PbSTe, SnPbS, SnPbSe, and/or SnPbTe); a quaternary compound (such as SnPbSSe, SnPbSeTe, and/or SnPbSTe); or any combination thereof.

In an embodiment, the Group IV element or compound may include: a single element (such as Si and/or Ge); a binary compound (such as SiC and/or SiGe); or any combination thereof.

Each element included in the multi-element compound (e.g., the binary compound, the ternary compound, and/or the quaternary compound) may be present in a particle at a substantially uniform concentration (e.g., concentration distribution) or a non-uniform concentration.

In some embodiments, the quantum dot may have a single (e.g., unitary) structure having a substantially uniform concentration of each element included in the quantum dot, or may have a dual structure of a core-shell (e.g., including a core, and a shell surrounding the core). In an embodiment, a material included in the core may be different from a material included in the shell.

The shell of the quantum dot may function as a protective layer for maintaining semiconductor characteristics by preventing or reducing chemical degeneration of the core, and/or may function as a charging layer for imparting electrophoretic characteristics to the quantum dot. The shell may be a single layer or a multilayer. An interface between the core and the shell may have a concentration gradient, for example in which the concentration of elements existing in the shell decreases toward the center.

Non-limiting examples of the shell of the quantum dot may include a metal or non-metal oxide, a semiconductor compound, or any combination thereof. Non-limiting examples of the oxide of metal or non-metal may include: a binary compound (such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO); a ternary compound (such as MgAl₂O₄, CoFe₂O₄, NiFe₂O₄, and/or CoMn₂O₄); or any combination thereof. Non-limiting examples of the semiconductor compound may include, as described herein, a Group III-VI semiconductor compound, a Group II-VI semiconductor compound, a Group III-V semiconductor compound, a Group I-III-VI semiconductor compound, a Group IV-VI semiconductor compound, or any combination thereof. In an embodiment, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of an emission wavelength spectrum of the quantum dot may be about 45 nm or less, for example, about 40 nm or less, for example, about 30 nm or less. When the FWHM of the emission wavelength spectrum of the quantum dot is within this range, color purity or color gamut may be improved. In some embodiments, light emitted by such quantum dots may be omnidirectionally irradiated. Accordingly, a wide viewing angle may be increased.

In some embodiments, the quantum dot may be a spherical particle, a pyramidal particle, a multi-arm particle, a cubic nanoparticle, a nanotube particle, a nanowire particle, a nanofiber particle, or a nanoplate particle.

By adjusting the size of the quantum dot, the energy band gap may also be adjusted to thereby provide light of one or more suitable wavelengths in the quantum dot emission layer. Therefore, by utilizing quantum dots of different sizes, a light-emitting device that emits light of one or more suitable wavelengths may be implemented. In an embodiment, the size of the quantum dot may be selected to emit red, green and/or blue light. In some embodiments, the size of the quantum dot may be adjusted or selected so that light of one or more suitable colors are combined to emit white light.

### Electron Transport Region in Interlayer 130

The electron transport region may have: i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including different materials.

The electron transport region may include a buffer layer, a hole blocking layer, an electron control layer, an electron transport layer, an electron injection layer, or any combination thereof.

In an embodiment, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein, for each structure, constituting layers are sequentially stacked from an emission layer.

The electron transport region (for example, the buffer layer, the hole blocking layer, the electron control layer, and/or the electron transport layer in the electron transport region) may include a metal-free compound including at least one π-electron-deficient nitrogen-containing C₁-C₆₀ cyclic group.

In an embodiment, the electron transport region may include a compound represented by Formula 601:

[Ar₆₀₁]ₓₑ₁₁-[(L₆₀₁)ₓₑ₁-R₆₀₁]ₓₑ₂₁. Formula 601

In Formula 601,

Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

Q₆₀₁ to Q₆₀₃ may each independently be the same as described in connection with Q₁,

xe21 may be 1, 2, 3, 4, or 5, and

at least one of Ar₆₀₁, L₆₀₁, and R₆₀₁ may each independently be a π-electron-deficient nitrogen-containing C₁-C₆₀ cyclic group unsubstituted or substituted with at least one R₁₀ₐ.

In an embodiment, when xe11 in Formula 601 is 2 or more, two or more of Ar₆₀₁(s) may be linked to each other via a single bond.

In an embodiment, Ar₆₀₁ in Formula 601 may be a substituted or unsubstituted anthracene group.

In an embodiment, the electron transport region may include a compound represented by Formula 601-1:

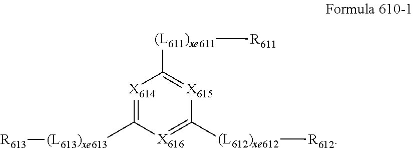

In Formula 601-1,

X₆₁₄ may be N or C(R₆₁₄), X₆₁₅ may be N or C(R₆₁₅), X₆₁₆ may be N or C(R₆₁₆), and at least one selected from X₆₁₄ to X₆₁₆ may be N,

L₆₁₁ to L₆₁₃ may each independently be understood by referring to the description presented in connection with L₆₀₁,

xe611 to xe613 may each independently be understood by referring to the description presented in connection with xe1,

R₆₁₁ to R₆₁₃ may each independently be understood by referring to the description presented in connection with R₆₀₁, and

R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, xe1 and xe611 to xe613 in Formulae 601 and 601-1 may each independently be 0, 1, or 2.

The electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, and NTAZ, or any combination thereof:

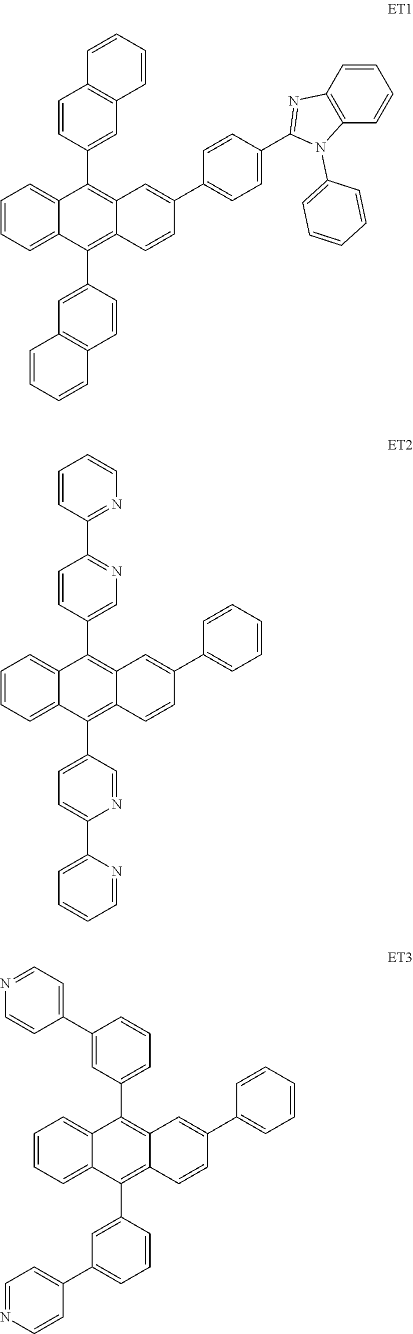 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

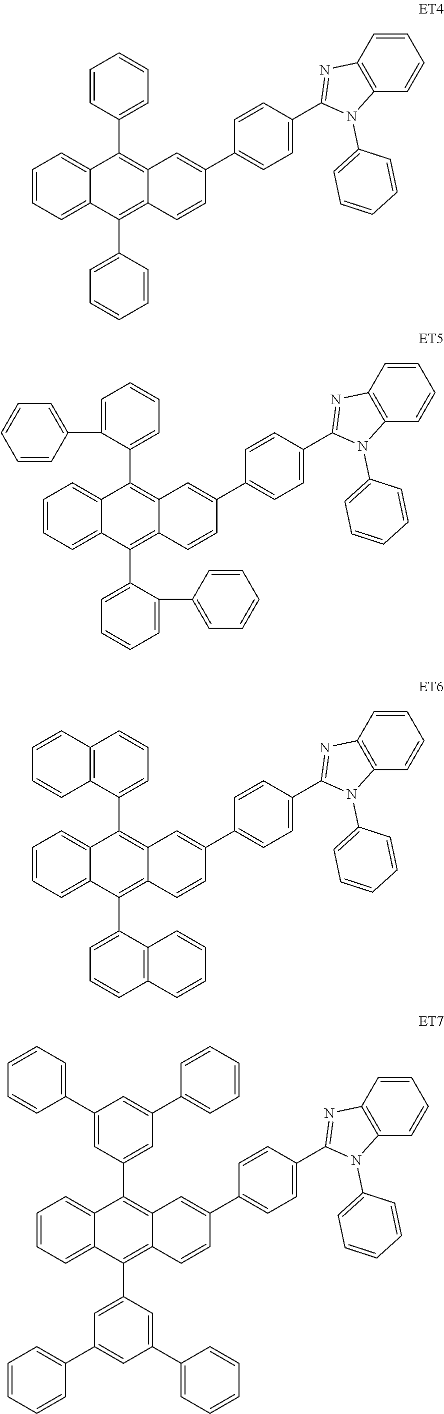 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

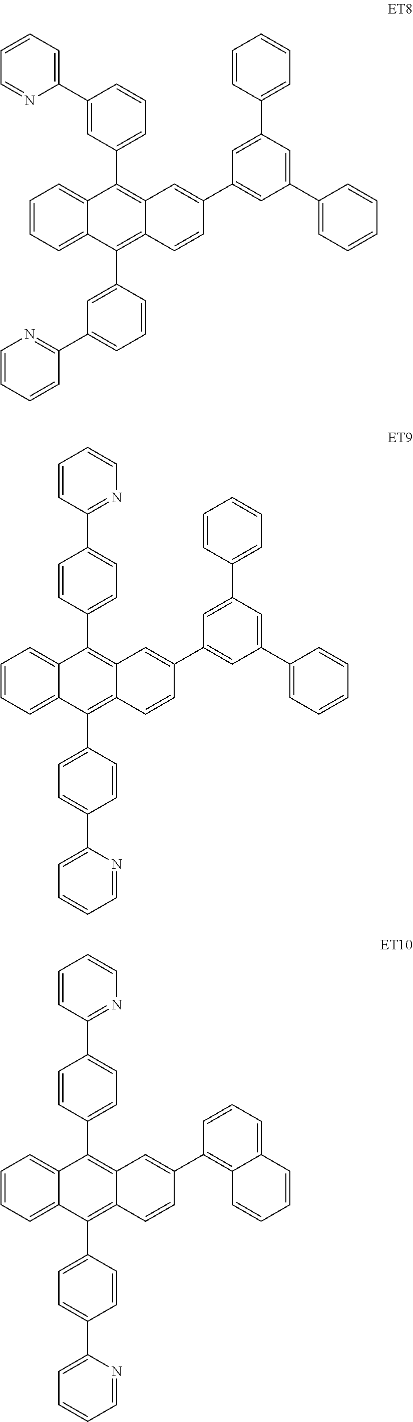

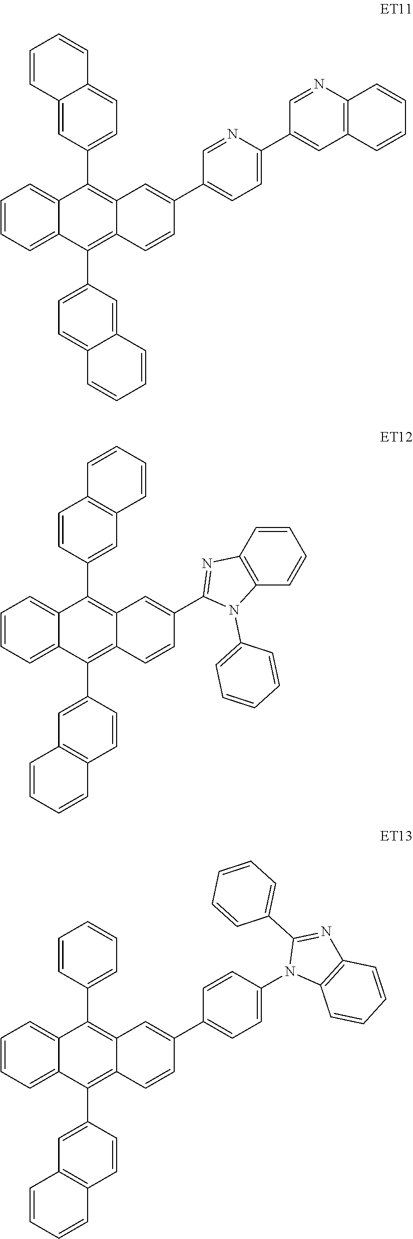

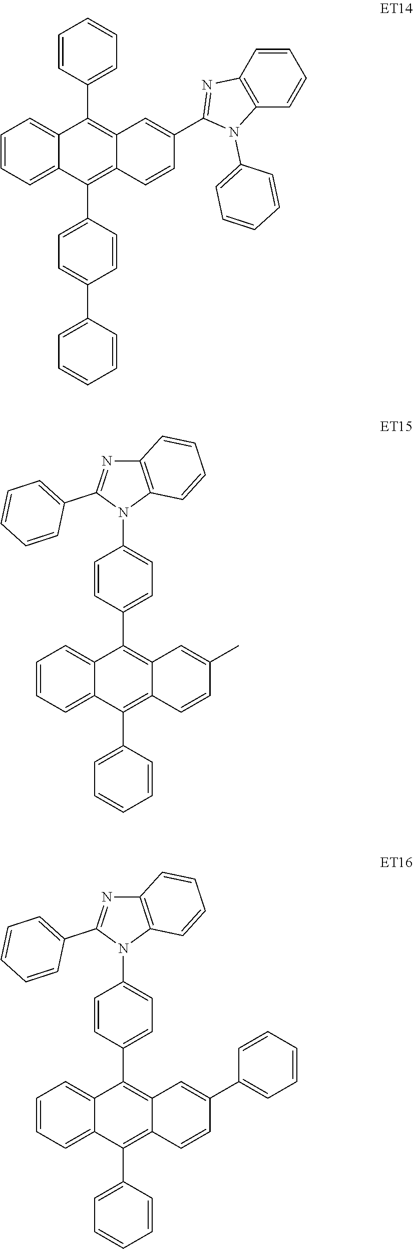 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

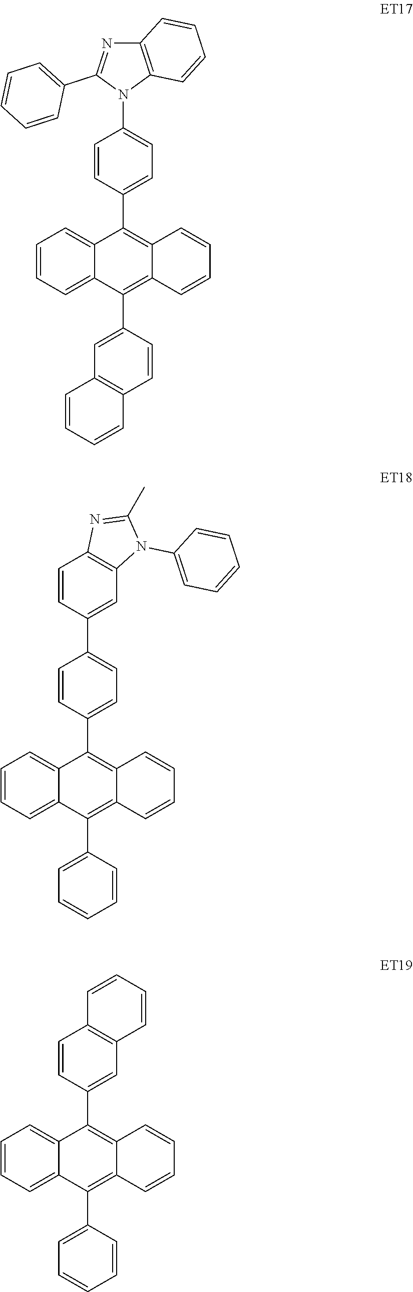

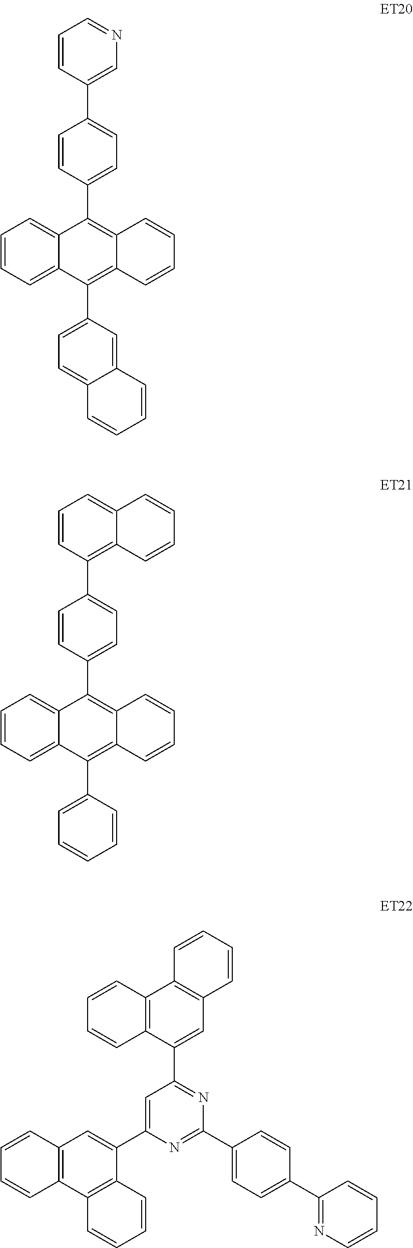

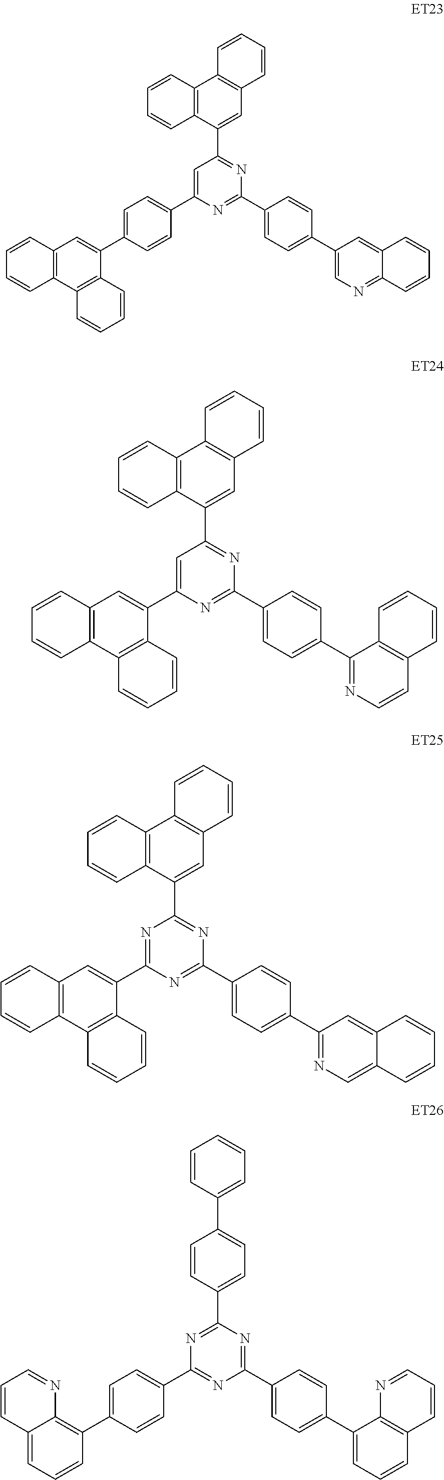 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2cc(-c3ccc(-c4nc(-c5cc6ccccc6c6ccccc56)nc(-c5cc6ccccc6c6ccccc56)n4)cc3)ncc2c1 ; c1ccc(-c2ccc(-c3nc(-c4ccc(-c5cccc6cccnc56)cc4)nc(-c4ccc(-c5cccc6cccnc56)cc4)n3)cc2)cc1]

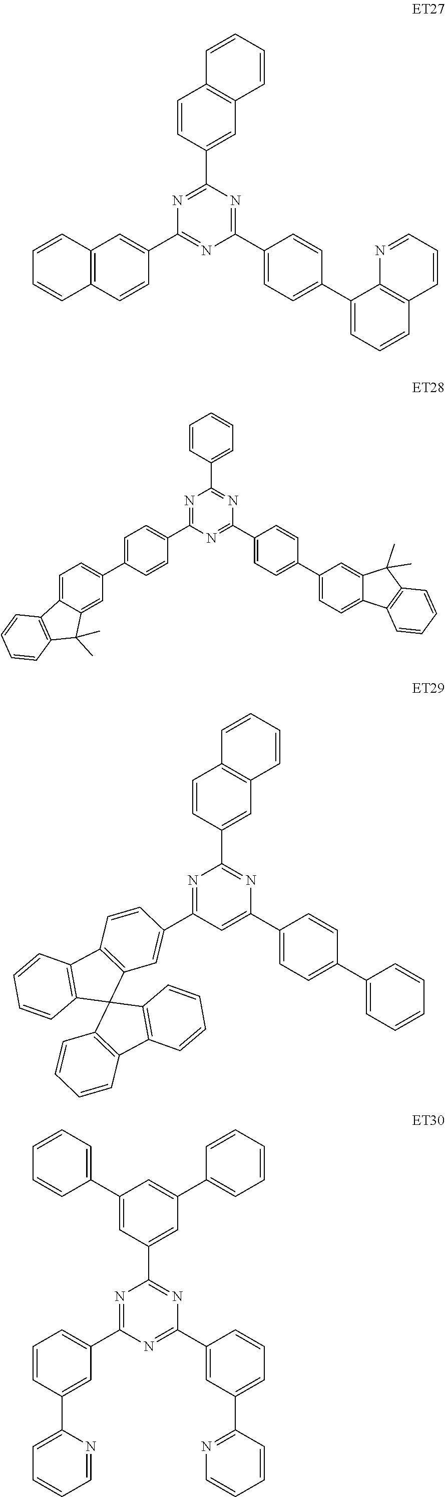

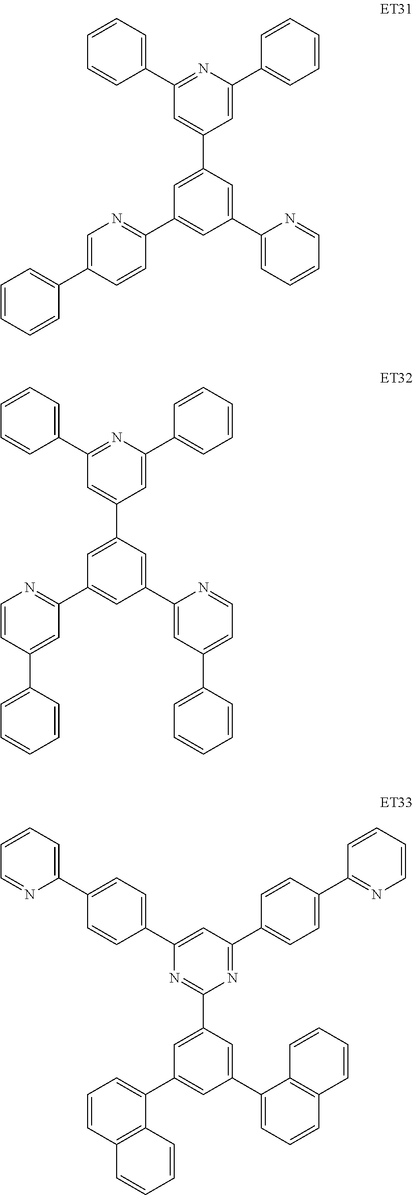 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

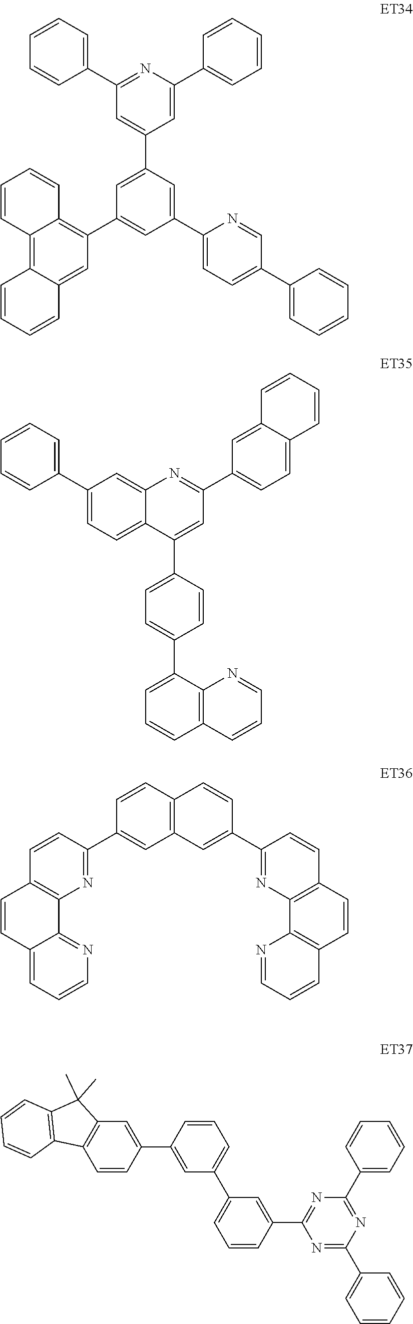 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21]

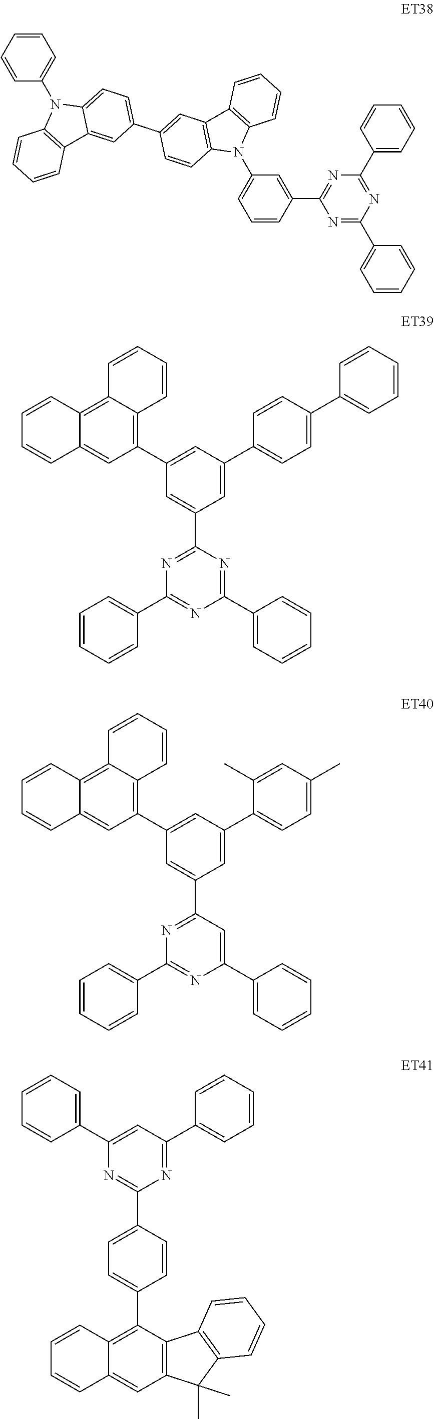 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1]

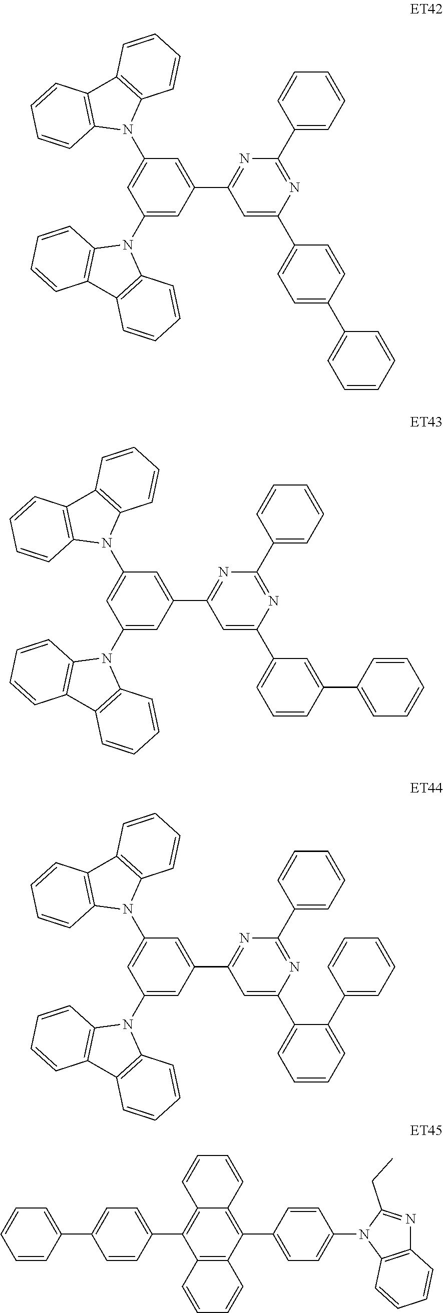 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

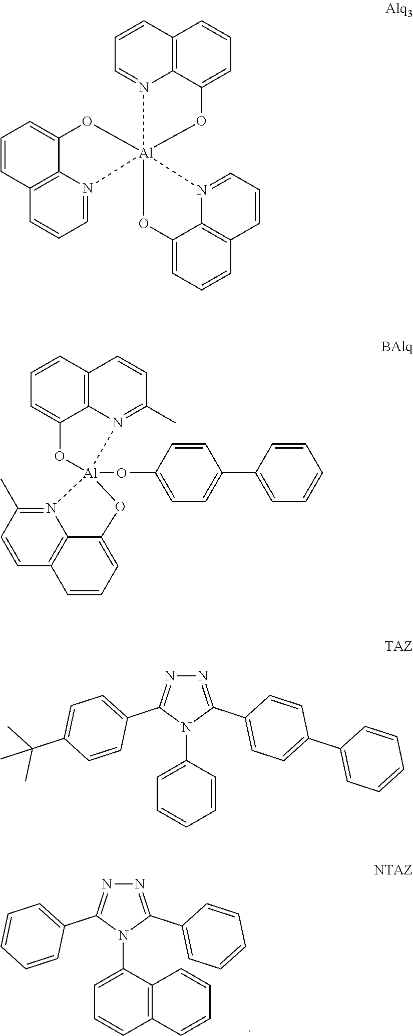

A thickness of the electron transport region may be from about 100 Å to about 5,000 Å, for example, about 160 Å to about 4,000 Å. When the electron transport region includes a buffer layer, a hole blocking layer, an electron control layer, an electron transport layer, or any combination thereof, a thickness of the buffer layer, the hole blocking layer, or the electron control layer may each independently be from about 20 Å to about 1,000 Å, for example, about 30 Å to about 300 Å, and the thickness of the electron transport layer may be from about 100 Å to about 1,000 Å, for example, about 150 Å to about 500 Å. When the thicknesses of the buffer layer, the hole blocking layer, the electron control layer, the electron transport layer, and/or the electron transport region are within these ranges, satisfactory electron transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth-metal complex, or any combination thereof. A metal ion of the alkali metal complex may be a lithium (Li) ion, a sodium (Na) ion, a potassium (K) ion, a rubidium (Rb) ion, or a cesium (Cs) ion, and a metal ion of the alkaline earth-metal complex may be a beryllium (Be) ion, a magnesium (Mg) ion, a calcium (Ca) ion, a strontium (Sr) ion, or a barium (Ba) ion. A ligand coordinated with the metal ion of the alkali metal complex or the alkaline earth-metal complex may be a hydroxy quinoline, a hydroxy isoquinoline, a hydroxy benzoquinoline, a hydroxy acridine, a hydroxy phenanthridine, a hydroxy phenyloxazole, a hydroxy phenylthiazole, a hydroxy phenyloxadiazole, a hydroxy phenylthiadiazole, a hydroxy phenylpyridine, a hydroxy phenylbenzimidazole, a hydroxy phenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) and/or ET-D2:

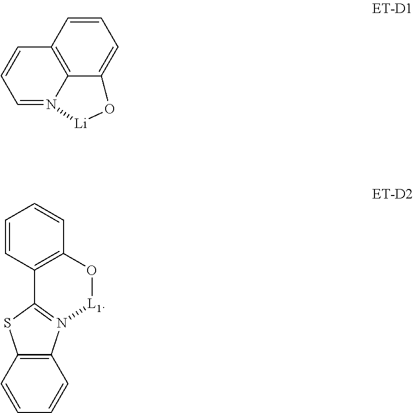

The electron transport region may include an electron injection layer to facilitate the injection of electrons from the second electrode 150. The electron injection layer may directly contact the second electrode 150.

The electron injection layer may have: i) a single-layered structure including (e.g., consisting of) a single layer including (e.g., consisting of) a single material, ii) a single-layered structure including (e.g., consisting of) a single layer including a plurality of different materials, or iii) a multi-layered structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include scandium (Sc), yttrium (Y), cerium (Ce), terbium (Tb), ytterbium (Yb), gadolinium (Gd), or any combination thereof.

The alkali metal-containing compound, the alkaline earth metal-containing compound, and the rare earth metal-containing compound may include oxides and/or halides (for example, fluorides, chlorides, bromides, and/or iodides) of the alkali metal, the alkaline earth metal, and the rare earth metal, telluride, or any combination thereof.

The alkali metal-containing compound may include alkali metal oxides (such as Li₂O, Cs₂O, and/or K₂O), and alkali metal halides (such as LiF, NaF, CsF, KF, LiI, NaI, CsI, and/or KI), or any combination thereof. The alkaline earth metal-containing compound may include alkaline earth metal oxides, (such as BaO, SrO, CaO, BaₓSr₁₋ₓO (x is a real number that satisfies the condition of 0<x<1), and/or BaₓCa₁₋ₓO (x is a real number that satisfies the condition of 0<x<1)). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include lanthanide metal telluride. Non-limiting examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and/or Lu₂Te₃.

The alkali metal complex, the alkaline earth-metal complex, and the rare earth metal complex may include i) one metal ion of the alkali metal, the alkaline earth metal, and the rare earth metal and ii) as a ligand linked to the metal ion, for example, hydroxyquinoline, hydroxy isoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

The electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof, or may further include an organic material (for example, a compound represented by Formula 601).

In an embodiment, the electron injection layer may include (e.g., consist of) i) an alkali metal-containing compound (for example, an alkali metal halide), or ii) a) an alkali metal-containing compound (for example, an alkali metal halide); and b) alkali metal, alkaline earth metal, rare earth metal, or any combination thereof. In an embodiment, the electron injection layer may be a KI:Yb co-deposited layer or a RbI:Yb co-deposited layer.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be substantially homogeneously or non-homogeneously dispersed in a matrix including the organic material.

A thickness of the electron injection layer may be in a range of about 1 Å to about 100 Å, for example, about 3 Å to about 90 Å. When the thickness of the electron injection layer is within the range described above, the electron injection layer may have satisfactory electron injection characteristics without a substantial increase in driving voltage.

### Second Electrode 150

The second electrode 150 may be located on the interlayer 130 having such a structure. The second electrode 150 may be a cathode, which is an electron injection electrode, and a metal, an alloy, an electrically conductive compound, or any combination thereof, each having a low work function, may be utilized as the material for forming the second electrode 150.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure or a multi-layered structure including two or more layers.

### Capping Layer

A first capping layer may be located outside the first electrode 110 (e.g., be on a side of the first electrode 110 facing oppositely away from the second electrode 150), and/or a second capping layer may be located outside the second electrode 150 (e.g., be on a side of the second electrode 150 facing oppositely away from the first electrode 110). For example, the light-emitting device 10 may have a structure in which the first capping layer, the first electrode 110, the interlayer 130, and the second electrode 150 are sequentially stacked in this stated order, a structure in which the first electrode 110, the interlayer 130, the second electrode 150, and the second capping layer are sequentially stacked in this stated order, or a structure in which the first capping layer, the first electrode 110, the interlayer 130, the second electrode 150, and the second capping layer are sequentially stacked in this stated order.

Light generated in the emission layer of the interlayer 130 of the light-emitting device 10 may be extracted toward the outside through the first electrode 110 (which may be a semi-transmissive electrode or a transmissive electrode) and the first capping layer, and light generated in an emission layer of the interlayer 130 of the light-emitting device 10 may be extracted toward the outside through the second electrode 150 (which is a semi-transmissive electrode or a transmissive electrode) and the second capping layer.

The first capping layer and the second capping layer may increase the external luminescence efficiency of the light-emitting device 10 according to the principle of constructive interference. Accordingly, the light extraction efficiency of the light-emitting device 10 may be increased, and the luminescence efficiency of the light-emitting device 10 may be improved.

Each of the first capping layer and the second capping layer may include a material having a refractive index of 1.5 or more (e.g., 1.6 or more) and 2.0 or less (at 589 nm).

The first capping layer and the second capping layer may each independently be an organic capping layer including an organic material, an inorganic capping layer including an inorganic material, or a composite capping layer including an organic material and an inorganic material.

The first capping layer and/or the second capping layer may each independently include a carbocyclic compound, a heterocyclic compound, an amine group-containing compound, a porphyrin derivative, a phthalocyanine derivative, a naphthalocyanine derivative, an alkali metal complex, an alkaline earth-metal complex, or any combination thereof. The carbocyclic compound, the heterocyclic compound, and the amine group-containing compound may each independently be optionally substituted with a substituent containing O, N, S, Se, Si, F, Cl, Br, I, or any combination thereof.

In an embodiment, the first capping layer and/or the second capping layer may each independently include an amine group-containing compound.

In an embodiment, the first capping layer and/or the second capping layer may each independently include a compound represented by Formula 201, a compound represented by Formula 202, or any combination thereof.

In an embodiment, the first capping layer and/or the second capping layer may each independently include one of Compounds HT28 to HT33, one of Compounds CP1 to CP6, p-NPB, or any combination thereof:

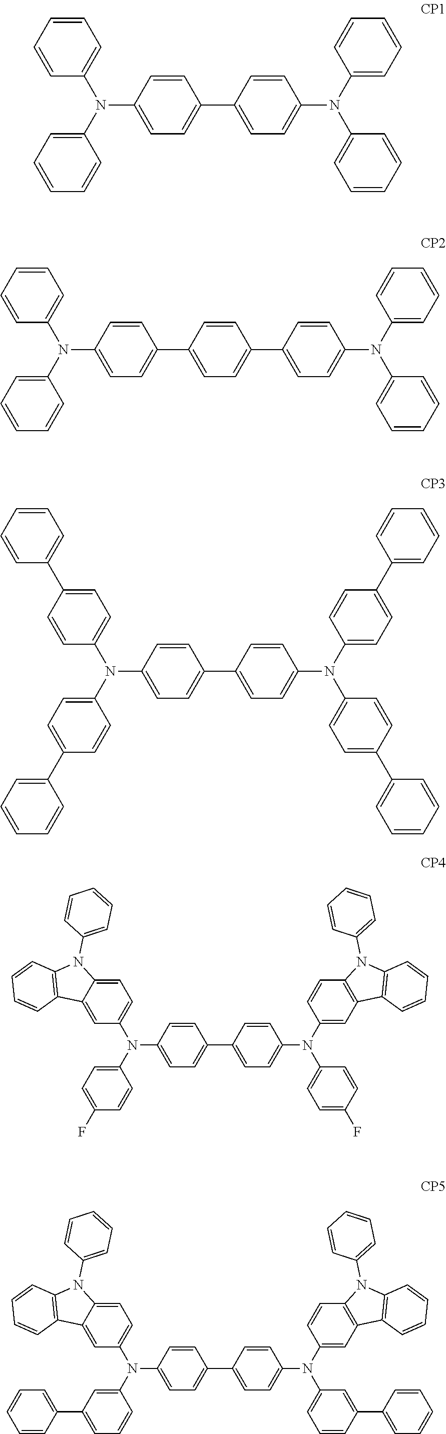 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

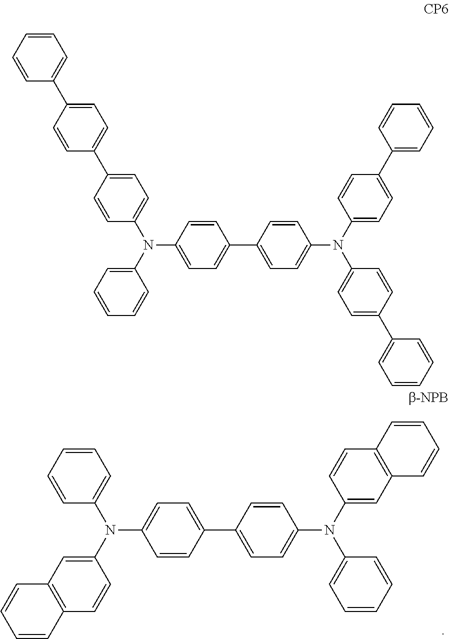

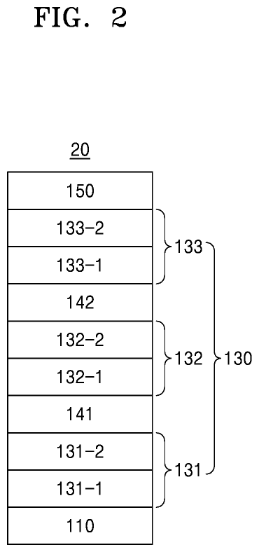

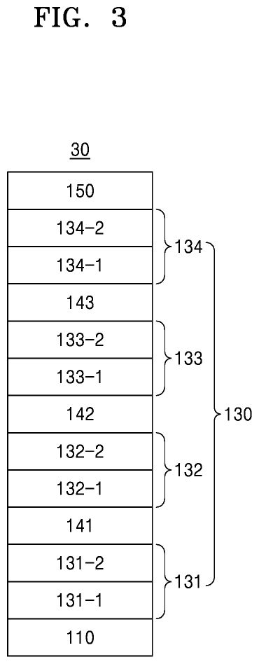

### Description of FIGS. 2 and 3

FIG. 2 is a schematic cross-sectional view of a light-emitting device (e.g., an organic light-emitting device) 20 according to an embodiment. The organic light-emitting device 20 includes: a first electrode 110; a second electrode 150 facing the first electrode 110; and an interlayer 130 between the first electrode 110 and the second electrode 150, wherein the interlayer 130 may include: a first emission unit 131 including a first emission layer 131-1 and a second emission layer 131-2; a first charge generating unit 141 located on the first emission unit 131; a second emission unit 132 including a first (third) emission layer 132-1 and a second (fourth) emission layer 132-2, which are located on the first charge generating unit 141; a second charge generating unit 142 located on the second emission unit 132; and a third emission unit 133 including a first (fifth) emission layer 133-1 and a second (sixth) emission layer 133-2, which are located on the second charge generating unit 142.

FIG. 3 is a schematic cross-sectional view of a light-emitting device (e.g., an organic light-emitting device) 30 according to an embodiment. The organic light-emitting device 30 includes: a first electrode 110; a second electrode 150 facing the first electrode 110; and an interlayer 130 between the first electrode 110 and the second electrode 150, wherein the interlayer 130 may include: a first emission unit 131 including a first emission layer 131-1 and a second emission layer 131-2; a first charge generating unit 141 located on the first emission unit 131; a second emission unit 132 including a first (third) emission layer 132-1 and a second (fourth) emission layer 132-2, which are located on the first charge generating unit 141; a second charge generating unit 142 located on the second emission unit 132; a third emission unit 133 including a first (fifth) emission layer 133-1 and a second (sixth) emission layer 133-2, which are located on the second charge generating unit 142; a third charge generating unit 143 located on the third emission unit 133; and a fourth emission unit 134 including a first (seventh) emission layer 134-1 and a second (eighth) emission layer 134-2, which are located on the third charge generating unit 143.

In some embodiments, the organic light-emitting device 20 or 30 may further include a hole transport region between the first electrode 110 and the first emission layer 131-1, and/or may further include an electron transport region between the second emission layer 131-2 and the first charge generating unit 141. The hole transport region and the electron transport region may each independently be the same as described above. Similarly, the organic light-emitting device 20 or 30 may further include a hole transport region between the first charge generating unit 141 and the first emission layer 132-1, and/or may further include an electron transport region between the second emission layer 132-2 and the second charge generating unit 142.

In some embodiments, the organic light-emitting device 20 or 30 may further include a hole transport region between the second charge generating unit 142 and the first emission layer 133-1, and/or may further include an electron transport region between the second emission layer 133-2 and the second electrode 150. Furthermore, the organic light-emitting device 30 may further include a hole transport region between the third charge generating unit 143 and the first emission layer 134-1, and/or may further include an electron transport region between the second emission layer 134-2 and the second electrode 150.

In some embodiments, the first charge generating unit 141, the second charge generating unit 142, and the third charge generating unit 143 may each include an n-type charge generation layer, a p-type charge generation layer, or a combination thereof. The n-type charge generation layer may include a material for forming an electron transport layer, an alkali metal complex, or a combination thereof, but is not limited thereto, and any suitable material having n-type semiconductor characteristics may be utilized. The p-type charge generation layer may include a material for forming a hole transport layer, a p-dopant, or a combination thereof, but is not limited thereto, and any suitable material having p-type semiconductor characteristics may be utilized.

The thicknesses of the n-type charge generation layer and the p-type charge generation layer may be within any suitable range that does not hinder the device characteristics of a light-emitting device.

### Electronic Apparatus

The light-emitting device may be included in one or more suitable electronic apparatuses. In an embodiment, an electronic apparatus including the light-emitting device may be a light-emitting apparatus, an authentication apparatus, and/or the like.

The electronic apparatus (for example, light-emitting apparatus) may further include, in addition to the light-emitting device, i) a color filter, ii) a color conversion layer, or iii) a color filter and a color conversion layer. The color filter and/or the color conversion layer may be located in at least one traveling direction of light emitted from the light-emitting device. In an embodiment, light emitted from the light-emitting device may be blue light and/or white light. The light-emitting device may be substantially the same as described above. In an embodiment, the color conversion layer may include a quantum dot. The quantum dot may be, for example, a quantum dot as described herein.

The electronic apparatus may include a first substrate. The first substrate may include a plurality of subpixel areas, the color filter may include a plurality of color filter areas respectively corresponding to the plurality of subpixel areas, and the color conversion layer may include a plurality of color conversion areas respectively corresponding to the plurality of subpixel areas.

A pixel-defining film (alternatively referred to as a “pixel-defining layer”) may be located between the plurality of subpixel areas to define each of the subpixel areas.

The color filter may further include a plurality of color filter areas and light-blocking patterns located between the plurality of color filter areas, and the color conversion layer may further include a plurality of color conversion areas and light-blocking patterns located between the plurality of color conversion areas.

The plurality of color filter areas (or the plurality of color conversion areas) may include a first area emitting first-color light, a second area emitting second-color light, and/or a third area emitting third-color light, and the first-color light, the second-color light, and/or the third-color light may have different maximum emission wavelengths. In an embodiment, the first-color light may be red light, the second-color light may be green light, and the third-color light may be blue light. In an embodiment, the plurality of color filter areas (or the plurality of color conversion areas) may include quantum dots. In an embodiment, the first area may include a red quantum dot, the second area may include a green quantum dot, and the third area may not include a (any) quantum dot. The quantum dot may be substantially the same as described in the present specification. Each of the first area, the second area, and the third area may further include a scatterer.

In an embodiment, the light-emitting device may be to emit first light, the first area may be to absorb the first light to emit first first-color light, the second area may be to absorb the first light to emit second first-color light, and the third area may be to absorb the first light to emit third first-color light. In this regard, the first first-color light, the second first-color light, and the third first-color light may have different maximum emission wavelengths. In an embodiment, the first light may be blue light, the first first-color light may be red light, the second first-color light may be green light, and the third first-color light may be blue light.

The electronic apparatus may further include a thin-film transistor in addition to the light-emitting device as described above. The thin-film transistor may include a source electrode, a drain electrode, and an activation layer, wherein any one of the source electrode and the drain electrode may be electrically connected to any one of the first electrode and the second electrode of the light-emitting device.

The thin-film transistor may further include a gate electrode, a gate insulating film, and/or the like.

The activation layer may include crystalline silicon, amorphous silicon, organic semiconductor, oxide semiconductor, and/or the like.

The electronic apparatus may further include a sealing portion for sealing the light-emitting device. The sealing portion may be located between the color filter and the light-emitting device and/or between the color conversion layer and the light-emitting device. The sealing portion allows light from the light-emitting device to be extracted to the outside, while concurrently (e.g., simultaneously) preventing or reducing ambient air and/or moisture from penetrating into the light-emitting device.

The sealing portion may be a sealing substrate including a transparent glass substrate and/or a plastic substrate. The sealing portion may be a thin film encapsulation layer including one or more organic layers and/or one or more inorganic layers. When the sealing portion is a thin film encapsulation layer, the electronic apparatus may be flexible.

On the sealing portion, in addition to the color filter and/or color conversion layer, one or more suitable functional layers may be further located according to the use of the electronic apparatus. Non-limiting examples of the functional layers may include a touch screen layer, a polarizing layer, and/or the like. The touch screen layer may be a pressure-sensitive touch screen layer, a capacitive touch screen layer, or an infrared touch screen layer. The authentication apparatus may be, for example, a biometric authentication apparatus for authenticating an individual by utilizing biometric information of a biometric body (for example, a fingertip, a pupil, and/or the like).

The authentication apparatus may further include, in addition to the light-emitting device, a biometric information collector.

The electronic apparatus may be applied to various suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various suitable measuring instruments, meters (for example, meters for a vehicle, an aircraft, and/or a vessel), projectors, and/or the like.

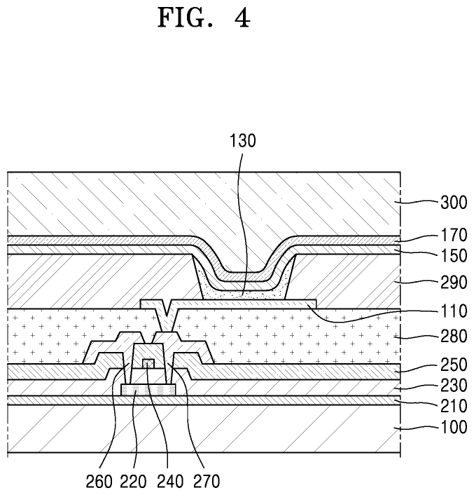

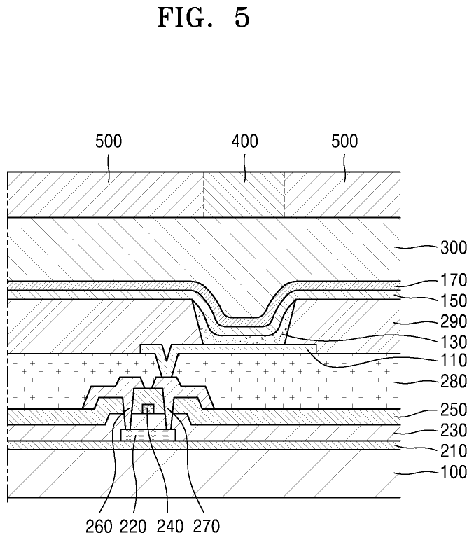

### Description of FIGS. 4 and 5

FIG. 4 is a cross-sectional view of a light-emitting apparatus according to an embodiment of the present disclosure.

The light-emitting apparatus of FIG. 4 includes a substrate 100, a thin-film transistor (TFT), a light-emitting device, and an encapsulation portion 300 that seals the light-emitting device.

The substrate 100 may be a flexible substrate, a glass substrate, and/or a metal substrate. A buffer layer 210 may be located on the substrate 100. The buffer layer 210 may prevent or reduce the penetration of impurities through the substrate 100 and may provide a flat surface on the substrate 100.

The TFT may be located on the buffer layer 210. The TFT may include an activation layer 220, a gate electrode 240, a source electrode 260, and a drain electrode 270.

The activation layer 220 may include an inorganic semiconductor (such as silicon or polysilicon), an organic semiconductor, or an oxide semiconductor, and may include a source region, a drain region, and a channel region.

A gate insulating film 230 for insulating the activation layer 220 from the gate electrode 240 may be located on the activation layer 220, and the gate electrode 240 may be located on the gate insulating film 230.

An interlayer insulating film 250 may be located on the gate electrode 240. The interlayer insulating film 250 is located between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be located on the interlayer insulating film 250. The interlayer insulating film 250 and the gate insulating film 230 may be formed to expose the source region and the drain region of the activation layer 220, and the source electrode 260 and the drain electrode 270 may be located to be in contact with the exposed portions of the source region and the drain region of the activation layer 220.

The TFT may be electrically connected to a light-emitting device to drive the light-emitting device, and may be covered by a passivation layer 280. The passivation layer 280 may include an inorganic insulating film, an organic insulating film, or a combination thereof. A light-emitting device may be provided on the passivation layer 280. The light-emitting device includes a first electrode 110, an interlayer 130, and a second electrode 150.

The first electrode 110 may be located on the passivation layer 280. The passivation layer 280 may not completely cover the drain electrode 270 and may expose a portion of the drain electrode 270, and the first electrode 110 may be connected to the exposed portion of the drain electrode 270.

A pixel-defining layer 290 including an insulating material may be located on the first electrode 110. The pixel-defining layer 290 may expose a set or predetermined region of the first electrode 110, and the interlayer 130 may be formed in the exposed region of the first electrode 110. The pixel-defining layer 290 may be a polyimide or polyacrylic-based organic film. In some embodiments, at least some layers of the interlayer 130 may extend beyond the upper portion of the pixel-defining layer 290 and may thus be located in the form of a common layer.

The second electrode 150 may be located on the interlayer 130, and a capping layer 170 may be additionally formed on the second electrode 150. The capping layer 170 may be formed to cover the second electrode 150.

The encapsulation portion 300 may be located on the capping layer 170. The encapsulation portion 300 may be located on the light-emitting device and may protect the light-emitting device from moisture and/or oxygen. The encapsulation portion 300 may include: an inorganic film including silicon nitride (SiNₓ), silicon oxide (SiOₓ), indium tin oxide, indium zinc oxide, or a combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate or polyacrylic acid), an epoxy-based resin (for example, aliphatic glycidyl ether (AGE)), or any combination thereof; or a combination of an inorganic film and an organic film.

FIG. 5 is a cross-sectional view of a light-emitting apparatus according to an embodiment of the present disclosure.

The light-emitting apparatus of FIG. 5 is similar to the light-emitting apparatus of FIG. 4, except that light-blocking patterns 500 and a functional region 400 are additionally located on the encapsulation portion 300. The functional region 400 may be i) a color filter area, ii) a color conversion area, or iii) a combination of the color filter area and the color conversion area. In an embodiment, a light-emitting device included in the light-emitting apparatus of FIG. 5 may be a tandem light-emitting device.

### Preparation Method

The layers constituting the hole transport region, the emission layer, and the layers constituting the electron transport region may be formed in a set or predetermined region by utilizing one or more suitable methods selected from vacuum deposition, spin coating, casting, Langmuir-Blodgett (LB) deposition, ink-jet printing, laser-printing, and laser-induced thermal imaging.

When the layers constituting the hole transport region, the emission layer, and the layers constituting the electron transport region are formed by vacuum deposition, the vacuum deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec, depending on the material to be included in a layer to be formed and the structure of a layer to be formed.

### DEFINITION OF TERMS

The term “C₃-C₆₀ carbocyclic group” as utilized herein refers to a cyclic group that includes (e.g., consists of) three to sixty carbon atoms only, and the term “C₁-C₆₀ heterocyclic group” as utilized herein refers to a cyclic group that has one to sixty carbon atoms and further includes, in addition to carbon, a heteroatom. The C₃-C₆₀ carbocyclic group and the C₁-C₆₀ heterocyclic group may each be a monocyclic group that includes (e.g., consists of) one ring, or a polycyclic group in which two or more rings are condensed with each other. In an embodiment, the number of ring-forming atoms of the C₁-C₆₀ heterocyclic group may be from 3 to 61.

The term “cyclic group” as utilized herein includes the C₃-C₆₀ carbocyclic group and the C₁-C₆₀ heterocyclic group.

The term “π electron-rich C₃-C₆₀ cyclic group” as utilized herein refers to a cyclic group that has three to sixty carbon atoms and does not include *—N═*′ as a ring-forming moiety, and the term “π-electron-deficient nitrogen-containing C₁-C₆₀ cyclic group” as utilized herein refers to a heterocyclic group that has one to sixty carbon atoms and includes *—N═*′ as a ring-forming moiety.

In an embodiment,

the C₃-C₆₀ carbocyclic group may be i) a group T1 (described below) or ii) a condensed cyclic group in which two or more groups T1 are condensed with each other (for example, a cyclopentadiene group, an adamantane group, a norbornane group, a benzene group, a pentalene group, a naphthalene group, an azulene group, an indacene group, acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

the C₁-C₆₀ heterocyclic group may be i) a group T2 (described below), ii) a condensed cyclic group in which two or more groups T2 are condensed with each other, or iii) a condensed cyclic group in which at least one group T2 and at least one group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothieno dibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group),

the π electron-rich C₃-C₆₀ cyclic group may be i) a group T1, ii) a condensed cyclic group in which two or more groups T1 are condensed with each other, iii) a group T3 (described below), iv) a condensed cyclic group in which two or more groups T3 are condensed with each other, or v) a condensed cyclic group in which at least one group T3 and at least one group T1 are condensed with each other (for example, a C₃-C₆₀ carbocyclic group, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, or a benzothienodibenzothiophene group),

the π-electron-deficient nitrogen-containing C₁-C₆₀ cyclic group may be i) a group T4 (described below), ii) a condensed cyclic group in which two or more groups T4 are condensed with each other, iii) a condensed cyclic group in which at least one group T4 and at least one group T1 are condensed with each other, iv) a condensed cyclic group in which at least one group T4 and at least one group T3 are condensed with each other, or v) a condensed cyclic group in which at least one group T4, at least one group T1, and at least one group T3 are condensed with each other (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group),

the group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane group (or, a bicyclo[2.2.1]heptane group), a norbornene group, a bicyclo[1.1.1]pentane group, a bicyclo[2.1.1]hexane group, a bicyclo[2.2.2]octane group, or a benzene group,

the group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group,

the group T3 may be a furan group, a thiophene group, a 1H-pyrrole group, a silole group, or a borole group, and

the group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the π-electron-deficient nitrogen-containing C₁-C₆₀ cyclic group” as utilized herein refer to a group that is condensed with a cyclic group, a monovalent group, a polyvalent group (for example, a divalent group, a trivalent group, a tetravalent group, and/or the like), according to the structure of a formula described with corresponding terms. In an embodiment, the term “benzene group” may refer to a benzo group, a phenyl group, a phenylene group, and/or the like, which may be easily understood by one of ordinary skill in the art according to a structure of a formula including the “benzene group.”

In an embodiment, non-limiting examples of the monovalent C₃-C₆₀ carbocyclic group and the monovalent C₁-C₆₀ heterocyclic group may be a C₃-C₁ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and/or a monovalent non-aromatic condensed heteropolycyclic group, and non-limiting examples of the divalent C₃-C₆₀ carbocyclic group and the divalent C₁-C₆₀ heterocyclic group may be a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and/or a divalent non-aromatic condensed heteropolycyclic group.

The term “C₁-C₆₀ alkyl group” as utilized herein refers to a linear or branched aliphatic saturated hydrocarbon monovalent group having 1 to 60 carbon atoms, and non-limiting examples thereof may be a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and/or a tert-decyl group. The term “C₁-C₆₀ alkylene group” as utilized herein refers to a divalent group having substantially the same structure as the C₁-C₆₀ alkyl group.

The term “C₂-C₆₀ alkenyl group” as utilized herein refers to a monovalent hydrocarbon group having at least one carbon-carbon double bond in the middle or at the terminus of a C₂-C₆₀ alkyl group, and non-limiting examples thereof include an ethenyl group, a propenyl group, and/or a butenyl group. The term “C₂-C₆₀ alkenylene group” as utilized herein refers to a divalent group having substantially the same structure as the C₂-C₆₀ alkenyl group.

The term “C₂-C₆₀ alkynyl group” as utilized herein refers to a monovalent hydrocarbon group having at least one carbon-carbon triple bond in the middle or at the terminus of a C₂-C₆₀ alkyl group, and non-limiting examples thereof include an ethynyl group and/or a propynyl group. The term “C₂-C₆₀ alkynylene group” as utilized herein refers to a divalent group having substantially the same structure as the C₂-C₆₀ alkynyl group.

The term “C₁-C₆₀ alkoxy group” as utilized herein refers to a monovalent group represented by —OA₁₀₁ (wherein A₁₀₁ is a C₁-C₆₀ alkyl group), and non-limiting examples thereof include a methoxy group, an ethoxy group, and/or an isopropyloxy group.

The term “C₃-C₁₀ cycloalkyl group” as utilized herein refers to a monovalent saturated hydrocarbon cyclic group having 3 to 10 carbon atoms, and non-limiting examples thereof may be a cyclopropyl group, a cyclobutyl group, a cyclopentyl group, a cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and/or a bicyclo[2.2.2]octyl group. The term “C₃-C₁ cycloalkylene group” as utilized herein refers to a divalent group having substantially the same structure as the C₃-C₁₀ cycloalkyl group.

The term “C₁-C₁₀ heterocycloalkyl group” as utilized herein refers to a monovalent cyclic group that further includes, in addition to 1 to 10 carbon atoms, at least one heteroatom as a ring-forming atom, and non-limiting examples thereof may be a 1,2,3,4-oxatriazolidinyl group, a tetrahydrofuranyl group, and/or a tetrahydrothiophenyl group. The term “C₁-C₁₀ heterocycloalkylene group” as utilized herein refers to a divalent group having substantially the same structure as the C₁-C₁₀ heterocycloalkyl group.

The term “C₃-C₁₀ cycloalkenyl group” as utilized herein refers to a monovalent monocyclic group that has 3 to 10 carbon atoms, at least one carbon-carbon double bond in the ring thereof, and no aromaticity, and non-limiting examples thereof include a cyclopentenyl group, a cyclohexenyl group, and/or a cycloheptenyl group. The term “C₃-C₁₀ cycloalkenylene group” as utilized herein refers to a divalent group having substantially the same structure as the C₃-C₁₀ cycloalkenyl group.

The term “C₁-C₁₀ heterocycloalkenyl group” as utilized herein refers to a monovalent cyclic group that has, in addition to 1 to 10 carbon atoms, at least one heteroatom as a ring-forming atom, and at least one double bond in the cyclic structure thereof. Non-limiting examples of the C₁-C₁₀ heterocycloalkenyl group include a 4,5-dihydro-1,2,3,4-oxatriazolyl group, a 2,3-dihydrofuranyl group, and/or a 2,3-dihydrothiophenyl group. The term “C₁-C₁₀ heterocycloalkenylene group” as utilized herein refers to a divalent group having substantially the same structure as the C₁-C₁₀ heterocycloalkenyl group.

The term “C₆-C₆₀ aryl group” as utilized herein refers to a monovalent group having a carbocyclic aromatic system having 6 to 60 carbon atoms, and the term “C₆-C₆₀ arylene group” as utilized herein refers to a divalent group having a carbocyclic aromatic system having 6 to 60 carbon atoms. Non-limiting examples of the C₆-C₆₀ aryl group may be a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and/or an ovalenyl group. When the C₆-C₆₀ aryl group and the C₆-C₆₀ arylene group each include two or more rings, the two or more rings may be fused to each other.

The term “C₁-C₆₀ heteroaryl group” as utilized herein refers to a monovalent group having a heterocyclic aromatic system that has, in addition to a carbon atom, at least one heteroatom as a ring-forming atom, and 1 to 60 carbon atoms. The term “C₁-C₆₀ heteroarylene group” as utilized herein refers to a divalent group having a heterocyclic aromatic system that has, in addition to a carbon atom, at least one heteroatom as a ring-forming atom, and 1 to 60 carbon atoms. Non-limiting examples of the C₁-C₆₀ heteroaryl group may be a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and/or a naphthyridinyl group. When the C₁-C₆₀ heteroaryl group and the C₁-C₆₀ heteroarylene group each include two or more rings, the two or more rings may be condensed with each other.

The term “monovalent non-aromatic condensed polycyclic group” as utilized herein refers to a monovalent group having two or more rings condensed with each other, only carbon atoms (for example, having 8 to 60 carbon atoms) as ring-forming atoms, and non-aromaticity in its entire molecular structure (e.g., is not completely aromatic through the entirety of the molecule, or the molecule as a whole does not correspond to a completely conjugated aromatic system). Non-limiting examples of the monovalent non-aromatic condensed polycyclic group may be an indenyl group, a fluorenyl group, a spiro-bifluorenyl group, a benzofluorenyl group, an indenophenanthrenyl group, and/or an indenoanthracenyl group. The term “divalent non-aromatic condensed polycyclic group” as utilized herein refers to a divalent group having substantially the same structure as the monovalent non-aromatic condensed polycyclic group.

The term “monovalent non-aromatic condensed heteropolycyclic group” as utilized herein refers to a monovalent group having two or more rings condensed to each other, at least one heteroatom other than carbon atoms (for example, having 1 to 60 carbon atoms), as a ring-forming atom, and non-aromaticity in its entire molecular structure (e.g., is not completely aromatic through the entirety of the molecule, or the molecule as a whole does not correspond to a completely conjugated aromatic system). Non-limiting examples of the monovalent non-aromatic condensed heteropolycyclic group include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and/or a benzothienodibenzothiophenyl group. The term “divalent non-aromatic condensed heteropolycyclic group” as utilized herein refers to a divalent group having substantially the same structure as the monovalent non-aromatic condensed heteropolycyclic group.

The term “C₆-C₆₀ aryloxy group” as utilized herein refers to —OA₁₀₂ (wherein A₁₀₂ is a C₆-C₆₀ aryl group), and the term “C₆-C₆₀ arylthio group” as utilized herein refers to —SA₁₀₃ (wherein A₁₀₃ is a C₆-C₆₀ aryl group).

The term “R₁₀ₐ” as utilized herein may be:

deuterium (-D), —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁, Q₂, Q₁₁ to Q₁₃, Q₂₁ to Q₂₃ and Q₃₁ to Q₃₃ utilized herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as utilized herein refers to any atom other than a carbon atom. Non-limiting examples of the heteroatom may be O, S, N, P, Si, B, Ge, Se, and/or any combination thereof.

The term “Ph” as utilized herein refers to a phenyl group, the term “Me” as utilized herein refers to a methyl group, the term “Et” as utilized herein refers to an ethyl group, the term “tert-Bu” or “Bu^{t}” as utilized herein refers to a tert-butyl group, and the term “OMe” as utilized herein refers to a methoxy group.

The term “biphenyl group” as utilized herein refers to “a phenyl group substituted with a phenyl group.” In other words, the “biphenyl group” may be a substituted phenyl group having a C₆-C₆₀ aryl group as a substituent.

The term “terphenyl group” as utilized herein refers to “a phenyl group substituted with a biphenyl group”. In other words, the “terphenyl group” may be a substituted phenyl group having, as a substituent, a C₆-C₆₀ aryl group substituted with a C₆-C₆₀ aryl group.

* and *′ as utilized herein, unless defined otherwise, each refer to a binding site to a neighboring atom in a corresponding formula.

Hereinafter, a compound according to embodiments and a light-emitting device according to embodiments will be described in more detail with reference to Synthesis Examples and Examples. The wording “B was utilized instead of A” utilized in describing Synthesis Examples indicated that an identical molar equivalent of B was utilized in place of the same molar equivalent of A.

### EXAMPLES

### Synthesis Example 1: Preparation of Compound PH-1

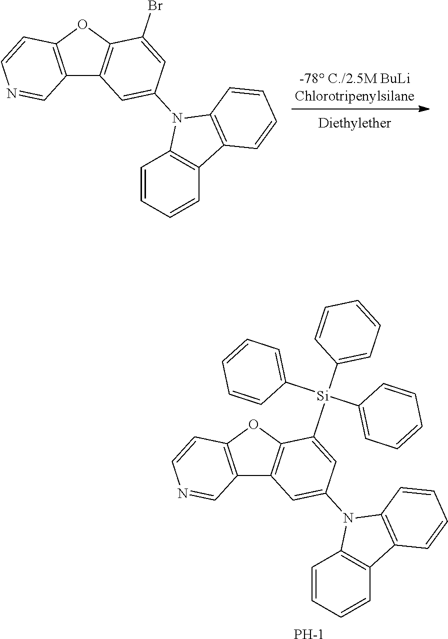

7-bromo-5-(9H-carbazole-9-yl)benzofuro[3,2-c]pyridine (5 g, 0.0121 mol) and 100 mL of diethyl ether were added into 500 mL of a round-bottom flask in the nitrogen atmosphere, and 5.32 mL (0.0133 mol) of 2.5 M butyl lithium was slowly injected thereinto at −78° C. Afterwards, the mixture was stirred for an hour, 3.92 g (0.0133 mol) of chlorotriphenylsilane was slowly injected thereinto at −78° C., which was then slowly raised to room temperature, and then stirred for 8 hours. The reaction was terminated with water, extracted with diethyl ether, and dried over anhydrous magnesium sulfate, and the resultant was subjected to column chromatography utilizing a solvent containing methylene chloride and hexane in the volume ratio of 1:10, thereby completing the preparation of Compound PH-1 (3.73 g, 52%).

¹H-NMR (CDCl₃): 9.51 (1H, s), 8.70 (1H, d), 8.55 (1H, d), 8.20 (1H, d), 7.90 (1H, d), 7.86 (1H, d), 7.70 (1H, s), 7.38-7.20 (19H, m), 7.91 (2H, m), M/S: 592.20

### Synthesis Example 2: Preparation of Compound PH-2

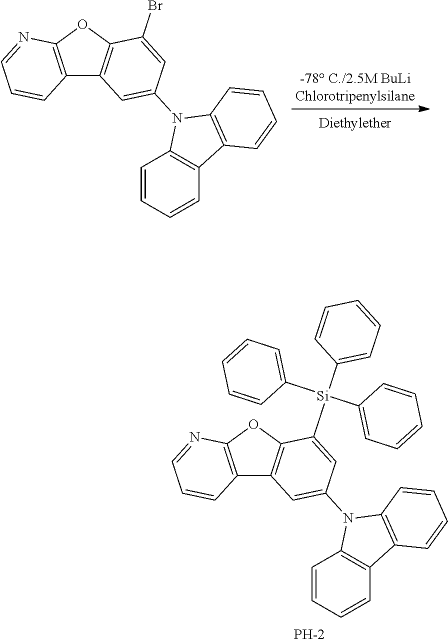

7-bromo-5-(9H-carbazole-9-yl)benzofuro[2,3-b]pyridine (5 g, 0.0121 mol) and 100 mL of diethyl ether were added into 500 mL of a round-bottom flask in the nitrogen atmosphere, and 5.32 mL (0.0133 mol) of 2.5 M butyl lithium was slowly injected thereinto at −78° C. Afterwards, the mixture was stirred for an hour, 3.92 g (0.0133 mol) of chlorotriphenylsilane was slowly injected thereinto at −78° C., which was then slowly raised to room temperature, and then stirred for 8 hours. The reaction was terminated with water, extracted with diethyl ether, and dried over anhydrous magnesium sulfate, and the resultant was subjected to column chromatography utilizing a solvent containing methylene chloride and hexane in the volume ratio of 1:10, thereby completing the preparation of Compound PH-2 (3.44 g, 48%).

¹H-NMR (CDCl₃): 8.50 (2H, m), 8.39 (1H, d), 8.19 (1H, d), 7.92 (1H, d), 7.71 (1H, s), 7.56-7.49 (2H, m), 7.45-7.30 (18H, m), 7.91 (2H, m), M/S: 592.20

### Synthesis Example 3: Preparation of Compound FH-1

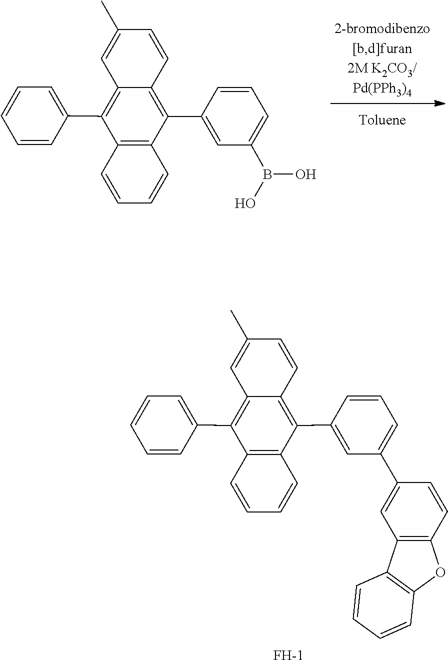

(3-(3-methyl-10-phenylanthracene-9-yl)phenyl)boronic acid (5 g, 0.01288 mol) and 2-bromodibenzo[b,d]furan (4.73 g, 0.01417 mol) were completely dissolved in 200 mL of toluene in 500 mL of a round-bottom flask in the nitrogen atmosphere, a 2 M aqueous potassium carbonate solution (100 mL) was added thereto, and tetrakis-(triphenylphosphine) palladium (0.47 g, 0.0004 mmol) was added thereto and then refluxed for 8 hours. The reaction was terminated with water, extracted with methyl chloride, and dried over anhydrous magnesium sulfate, and the resultant was subjected to column chromatography utilizing a solvent containing methylene chloride and hexane in the volume ratio of 1:10, thereby completing the preparation of Compound FH-1 (5.39 g, 82%).

¹H-NMR (CDCl₃): 8.23 (2H, m), 7.96-7.54 (15H, m), 7.39-7.27 (6H, m), 2.63 (3H, s), M/S: 510.20

### Synthesis Example 4: Preparation of Compound FH-2

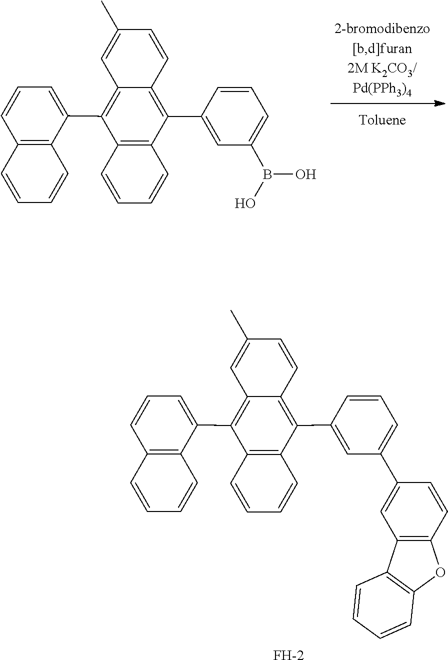

(3-(3-methyl-10-(naphthalene-1-yl)anthracene-9-yl)phenyl)boronic acid (5 g, 0.01141 mol) and 2-bromodibenzo[b,d]furan (6.41 g, 0.0125 mol) were completely dissolved in 200 mL of toluene in 500 mL of a round-bottom flask in the nitrogen atmosphere, a 2 M aqueous potassium carbonate solution (100 mL) was added thereto, and tetrakis-(triphenylphosphine) palladium (0.47 g, 0.0004 mmol) was added thereto and then refluxed for 8 hours. The reaction was terminated with water, extracted with methyl chloride, and dried over anhydrous magnesium sulfate, and the resultant was subjected to column chromatography utilizing a solvent containing methylene chloride and hexane in the volume ratio of 1:10, thereby completing the preparation of Compound FH-2 (5.44 g, 85%).

¹H-NMR (CDCl₃): 8.95 (1H, d), 8.50 (1H, d), 8.23-8.20 (3H, m), 8.09 (1H, m), 7.98-7.54 (13H, m), 7.39-7.31 (6H, m), 2.63 (3H, s), M/S: 560.21

### Measurement of T₁ Energy Level

An absolute PL quantum yield spectrometer (Quantaurus-QY) was utilized to measure the T₁ energy level of Compounds PH-1, PH-2, FH-1, and FH-2 from PL data measured at −78° C. The results are shown in Table 1.

TABLE 1

| Compound | T₁ (eV) |
|---|---|
| PH-1 | 3.05 |
| PH-2 | 3.02 |
| FH-1 | 1.75 |
| FH-2 | 1.77 |

### Example 1

An ITO (70 Å)/Ag (1000 Å)/ITO (70 Å) (anode) glass substrate was cut to a size of 50 mm×50 mm×0.5 mm, sonicated with isopropyl alcohol and pure water each for 5 minutes, and then cleaned by irradiation of ultraviolet rays and exposure of ozone thereto for 30 minutes. Then, the glass substrate was provided to a vacuum deposition apparatus.

HAT-CN was vacuum-deposited on the glass substrate to form a hole injection layer having a thickness of 100 Å. Next, NPB as a hole transport compound was vacuum-deposited thereon to form a hole transport layer having a thickness of 1,200 Å.

Compound mCBP was vacuum-deposited on the hole transport layer to form an electron blocking layer having a thickness of 50 Å.

PH-1 as a first host and FCNIrPic as a first dopant were co-deposited on the electron blocking layer at a weight ratio of 95:5 to form a first emission layer having a thickness of 100 Å, and FH-1 as a second host and a fluorescent dopant as a second dopant were co-deposited on the first emission layer at a weight ratio of 99:1 to form a second emission layer having a thickness of 100 Å.

Next, T2T was vacuum-deposited thereon to form a hole blocking layer having a thickness of 50 Å, and TPM-TAZ and LiQ were vacuum-deposited thereon at a weight ratio of 1:1 to form an electron transport layer having a thickness of 300 Å.

Yb was vacuum-deposited on the electron transport layer to a thickness of 10 Å and then AgMg was vacuum-deposited thereon to a thickness of 100 Å, to thereby form a cathode, and CPL was deposited thereon to form a capping layer having a thickness of 700 Å, thereby completing the manufacture of an organic light-emitting device.

### Examples 2 to 12 and Comparative Examples 1 to 5

Additional organic light-emitting devices were manufactured in substantially the same manner as in Example 1, except that a first host and a second host, which are shown in Table 2, were utilized, and thicknesses of a first emission layer and a second emission layer were adjusted.

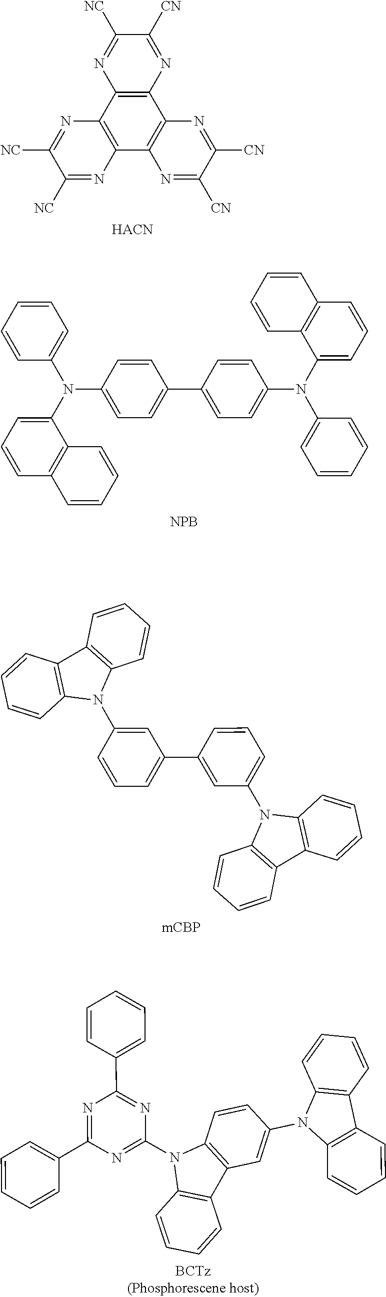

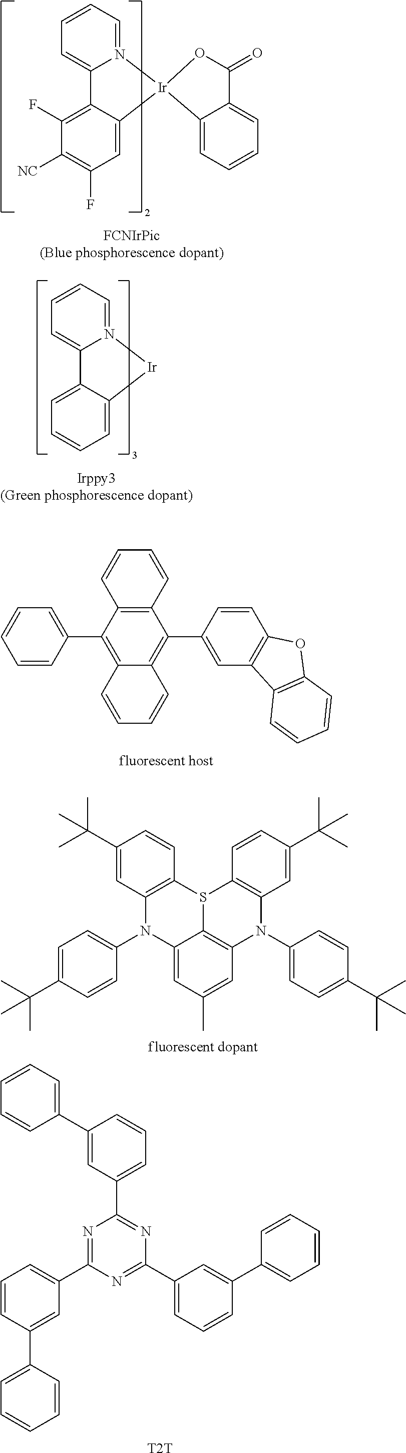

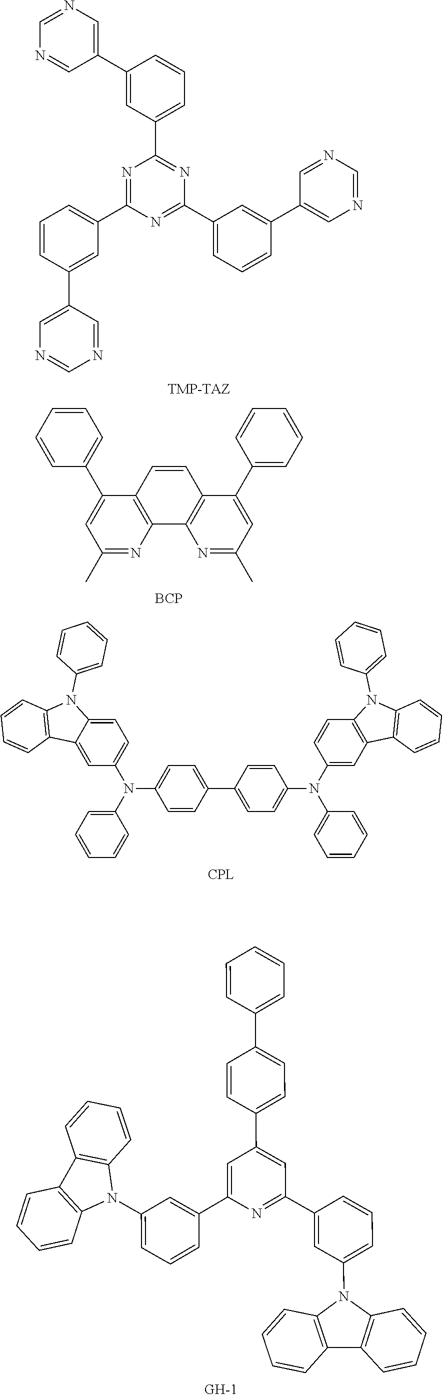

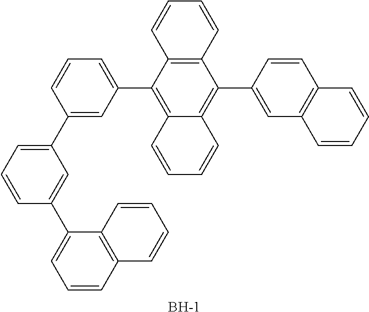

### Evaluation Example 1: Device Evaluation

Driving voltage, efficiency, and lifespan at a current density of 10 mA/cm² were measured, and the results thereof are shown in Table 2.

The driving voltage and current density of each of the organic light-emitting devices were measured utilizing a source meter (Keithley Instrument, 2400 series), and the efficiency thereof was measured utilizing a measurement device C9920-2-12 (Hamamatsu Photonics Inc.).

TABLE 2

| | First host | Second host | Driving voltage | Efficiency | Lifespan | Luminance |
|---|---|---|---|---|---|---|
| Type | Thickness (Å) | | (V) | (Cd/A) | (T97) | (nit) |
| Example 1 | PH-1 | FH-1 | 4.0 | 15 | 115 | 1000 |
| | 100 | 100 | | | | |
| Example 2 | PH-1 | FH-1 | 3.8 | 10 | 128 | 1000 |
| | 50 | 150 | | | | |
| Example 3 | PH-1 | FH-1 | 4.2 | 17 | 85 | 1000 |
| | 150 | 50 | | | | |
| Example 4 | PH-2 | FH-1 | 3.9 | 17 | 105 | 1000 |
| | 100 | 100 | | | | |
| Example 5 | PH-2 | FH-1 | 3.7 | 18 | 110 | 1000 |
| | 50 | 150 | | | | |
| Example 6 | PH-2 | FH-1 | 4.1 | 13 | 58 | 1000 |
| | 150 | 50 | | | | |
| Example 7 | PH-1 | FH-2 | 4.0 | 14 | 110 | 1000 |
| | 100 | 100 | | | | |
| Example 8 | PH-1 | FH-2 | 3.9 | 19 | 130 | 1000 |
| | 50 | 150 | | | | |
| Example 9 | PH-1 | FH-2 | 4.3 | 13 | 85 | 1000 |
| | 150 | 50 | | | | |
| Example 10 | PH-2 | FH-2 | 3.9 | 16 | 125 | 1000 |
| | 100 | 100 | | | | |
| Example 11 | PH-2 | FH-2 | 3.8 | 17 | 134 | 1000 |
| | 50 | 150 | | | | |
| Example 12 | PH-2 | FH-2 | 4.2 | 10 | 102 | 1000 |
| | 150 | 50 | | | | |
| Comparative | PH-1 | — | 4.2 | 23 | 0.5 | 1000 |
| Example 1 | 200 | — | | | | |
| Comparative | PH-2 | — | 4.2 | 25 | 0.5 | 1000 |
| Example 2 | 200 | — | | | | |
| Comparative | — | FH-1 | 3.7 | 8 | 140 | 1000 |
| Example 3 | — | 200 | | | | |
| Comparative | — | FH-2 | 3.7 | 9 | 150 | 1000 |
| Example 4 | — | 200 | | | | |
| Comparative | GH-1 | BH-1 | 5.5 | 28 | 150 | 1000 |
| Example 5 | 100 | 100 | | | | |

It is confirmed that the organic light-emitting devices of Examples 1 to 12 each have excellent or suitable lifespan characteristics compared to the organic light-emitting devices of Comparative Examples 1 and 2, which each include only a phosphorescence emission layer, and also each have excellent or suitable efficiency compared to the organic light-emitting devices of Comparative Examples 3 and 4, which each include only a fluorescence emission layer. In addition, it is confirmed that the organic light-emitting devices of Examples 1 to 12 each have a low driving voltage compared to the organic light-emitting device of Comparative Example 5.

### Example 13

An ITO (150 Å)/Ag (1,000 Å)/ITO (150 Å) (anode) glass substrate (a product of Corning Inc.) was cut to a size of 50 mm×50 mm×0.7 mm, sonicated with isopropyl alcohol and pure water each for 5 minutes, and cleaned by irradiation of ultraviolet rays and ozone exposure for 15 minutes. Then the glass substrate was provided to a vacuum deposition apparatus.

HAT-CN was vacuum deposited on the ITO/Ag/ITO anode of the glass substrate to form a hole injection layer having a thickness of 100 Å, NPB was vacuum deposited on the hole injection layer to form a hole transport layer having a thickness of 200 Å, mCBP was vacuum deposited on the hole transport layer to form an electron blocking layer having a thickness of 50 Å, PH-1 (first host) and FCNIrPic (first dopant) were co-deposited on the electron blocking layer at a weight ratio of 95:5 to form a first emission layer having a thickness of 100 Å, FH-1 (second host) and a fluorescent dopant (second dopant) were co-deposited on the first emission layer at a weight ratio of 99:1 to form a second emission layer having a thickness of 100 Å, T2T was vacuum deposited on the second emission layer to form a hole blocking layer having a thickness of 50 Å, and TPM-TAZ and LiQ were co-deposited on the hole blocking layer at a weight ratio of 1:1 to form an electron transport layer having a thickness of 250 Å, thereby completing the formation of a first emission unit.

BCP and Li were co-deposited on the first emission unit at a weight ratio of 98.5:1.5 to form an n-type charge generation layer having a thickness of 50 Å, and HAT-CN was vacuum deposited on the n-type charge generation layer to form a p-type charge generation layer having a thickness of 100 Å, thereby completing the formation of a first charge generating unit.

NPB was vacuum deposited on the first charge generating unit to form a hole transport layer having a thickness of 100 Å, mCBP was vacuum deposited on the hole transport layer to form an electron blocking layer having a thickness of 50 Å, BCTz and Ir(PPy)₃ were co-deposited on the electron blocking layer at a weight ratio of 94:6 to form an emission layer having a thickness of 250 Å, T2T was vacuum deposited on the emission layer to form a hole blocking layer having a thickness of 50 Å, and TPM-TAZ and LiQ were co-deposited on the hole blocking layer at a weight ratio of 1:1 to form an electron transport layer having a thickness of 100 Å, thereby completing the formation of a second emission unit.

CBP and Li were co-deposited on the second emission unit at a weight ratio of 98.5:1.5 to form an n-type charge generation layer having a thickness of 50 Å, and HAT-CN was vacuum deposited on the n-type charge generation layer to form a p-type charge generation layer having a thickness of 100 Å, thereby completing the formation of a second charge generating unit.

NPB was vacuum deposited on the second charge generating unit to form a hole transport layer having a thickness of 100 Å, mCBP was vacuum deposited on the hole transport layer to form an electron blocking layer having a thickness of 50 Å, PH-1 (first host) and FCNIrPic (first dopant) were co-deposited on the electron blocking layer at a weight ratio of 95:5 to form a first emission layer having a thickness of 100 Å, FH-1 (second host) and a fluorescent dopant (second dopant) were co-deposited on the first emission layer at a weight ratio of 99:1 to form a second emission layer having a thickness of 100 Å, T2T was vacuum deposited on the second emission layer to form a hole blocking layer having a thickness of 50 Å, and TPM-TAZ and LiQ were co-deposited on the hole blocking layer at a weight ratio of 1:1 to form an electron transport layer having a thickness of 350 Å, thereby completing the formation of a third emission unit.

Yb was vacuum deposited on the third emission unit to a thickness of 10 Å and then Ag and Mg were co-deposited thereon at a weight ratio of 9:1 to a thickness of 120 Å, to thereby form a cathode, and CPL was vacuum deposited on the cathode to form a capping layer having a thickness of 600 Å, thereby completing the manufacture of a tandem organic light-emitting device.

### Examples 14 to 16 and Comparative Examples 6 to 9

Additional tandem organic light-emitting devices were manufactured in substantially the same manner as in Example 13, except that a different first host and second host were utilized, as shown in Table 3.

### Evaluation Example 2: Device Evaluation

T Driving voltage, efficiency, and lifespan at a current density of 10 mA/cm² were measured, and then results thereof are shown in Table 3.

The driving voltage and current density of each of the tandem organic light-emitting devices were measured utilizing a source meter (Keithley Instrument, 2400 series), and the efficiency thereof was measured utilizing a measurement device C9920-2-12 (Hamamatsu Photonics Inc.).

TABLE 3

| | First host | Second host | Driving voltage | Efficiency | Lifespan | Luminance |
|---|---|---|---|---|---|---|
| Type | Thickness (Å) | | (V) | (Cd/A) | (T97) | (nit) |
| Example 13 | PH-1 | FH-1 | 11.2 | 25 | 280 | 1000 |
| | 100 | 100 | | | | |
| Example 14 | PH-2 | FH-1 | 11.2 | 26 | 300 | 1000 |
| | 100 | 100 | | | | |
| Example 15 | PH-1 | FH-2 | 11.2 | 25 | 290 | 1000 |
| | 100 | 100 | | | | |
| Example 16 | PH-2 | FH-2 | 11.2 | 25 | 290 | 1000 |
| | 100 | 100 | | | | |
| Comparative | PH-1 | — | 12.3 | 29 | 5 | 1000 |
| Example 6 | 200 | — | | | | |
| Comparative | PH-2 | — | 12.2 | 30 | 15 | 1000 |
| Example 7 | 200 | — | | | | |
| Comparative | — | FH-1 | 11.2 | 20 | 300 | 1000 |
| Example 8 | — | 200 | | | | |
| Comparative | — | FH-2 | 11.1 | 21 | 320 | 1000 |
| Example 9 | — | 200 | | | | |

It is confirmed that the tandem organic light-emitting devices of Examples 13 to 16 each have excellent or suitable lifespan characteristics compared to the tandem organic light-emitting devices of Comparative Examples 6 and 7, which each include only a phosphorescence emission layer, and also each have excellent or suitable efficiency compared to the tandem organic light-emitting devices of Comparative Examples 8 and 9, which each include only a fluorescence emission layer.

### Example 17

An ITO (150 Å)/Ag (1,000 Å)/ITO (150 Å) (anode) glass substrate (a product of Corning Inc.) was cut to a size of 50 mm×50 mm×0.7 mm, sonicated with isopropyl alcohol and pure water each for 5 minutes, and cleaned by irradiation of ultraviolet rays and ozone exposure thereto for 15 minutes. Then the glass substrate was provided to a vacuum deposition apparatus.

HAT-CN was vacuum deposited on the ITO/Ag/ITO anode of the glass substrate to form a hole injection layer having a thickness of 100 Å, NPB was vacuum deposited on the hole injection layer to form a hole transport layer having a thickness of 200 Å, mCBP was vacuum deposited on the hole transport layer to form an electron blocking layer having a thickness of 50 Å, PH-1 (first host) and FCNIrPic (first dopant) were co-deposited on the electron blocking layer at a weight ratio of 95:5 to form a first emission layer having a thickness of 100 Å, FH-1 (second host) and a fluorescent dopant (second dopant) were co-deposited on the first emission layer at a weight ratio of 99:1 to form a second emission layer having a thickness of 100 Å, T2T was vacuum deposited on the second emission layer to form a hole blocking layer having a thickness of 50 Å, and TPM-TAZ and LiQ were co-deposited on the hole blocking layer at a weight ratio of 1:1 to form an electron transport layer having a thickness of 250 Å, thereby completing the formation of a first emission unit.

CBP and Li were co-deposited on the first emission unit at a weight ratio of 98.5:1.5 to form an n-type charge generation layer having a thickness of 50 Å, and HAT-CN was vacuum deposited on the n-type charge generation layer to form a p-type charge generation layer having a thickness of 100 Å, thereby completing the formation of a first charge generating unit.

NPB was vacuum deposited on the first charge generating unit to form a hole transport layer having a thickness of 250 Å, mCBP was vacuum deposited on the hole transport layer to form an electron blocking layer having a thickness of 50 Å, PH-1 (first host) and FCNIrPic (first dopant) were co-deposited on the electron blocking layer at a weight ratio of 95:5 to form a first emission layer having a thickness of 100 Å, FH-1 (second host) and a fluorescent dopant (second dopant) were co-deposited on the first emission layer at a weight ratio of 99:1 to form a second emission layer having a thickness of 100 Å, T2T was vacuum deposited on the second emission layer to form a hole blocking layer having a thickness of 50 Å, and TPM-TAZ and LiQ were co-deposited on the hole blocking layer at a weight ratio of 1:1 to form an electron transport layer having a thickness of 250 Å, thereby completing the formation of a second emission unit.

CBP and Li were co-deposited on the second emission unit at a weight ratio of 98.5:1.5 to form an n-type charge generation layer having a thickness of 50 Å, and HAT-CN was vacuum deposited on the n-type charge generation layer to form a p-type charge generation layer having a thickness of 100 Å, thereby completing the formation of a second charge generating unit.

NPB was vacuum deposited on the second charge generating unit to form a hole transport layer having a thickness of 100 Å, mCBP was vacuum deposited on the hole transport layer to form an electron blocking layer having a thickness of 50 Å, BCTz and Ir(PPy)₃ were co-deposited on the electron blocking layer at a weight ratio of 94:6 to form an emission layer having a thickness of 250 Å, T2T was vacuum deposited on the emission layer to form a hole blocking layer having a thickness of 50 Å, and TPM-TAZ and LiQ were co-deposited on the hole blocking layer at a weight ratio of 1:1 to form an electron transport layer having a thickness of 350 Å, thereby completing the formation of a third emission unit.

Yb was vacuum deposited on the third emission unit to a thickness of 10 Å and then Ag and Mg were co-deposited thereon at a weight ratio of 9:1 to a thickness of 120 Å to thereby form a cathode, and CPL was vacuum deposited on the cathode to form a capping layer having a thickness of 600 Å, thereby completing the manufacture of a tandem organic light-emitting device.

### Examples 18 to 20 and Comparative Examples 10 to 13

Additional tandem organic light-emitting devices were manufactured in substantially the same manner as in Example 17, except that a different first host and second host were utilized, as shown in Table 4.

### Evaluation Example 3: Device Evaluation

Driving voltage, efficiency, and lifespan at a current density of 10 mA/cm² were measured, and the results thereof are shown in Table 4.

The driving voltage and current density of each of the tandem organic light-emitting devices were measured utilizing a source meter (Keithley Instrument, 2400 series), and the efficiency thereof was measured utilizing a measurement device C9920-2-12 (Hamamatsu Photonics Inc.).

TABLE 4

| | First host | Second host | Driving voltage | Efficiency | Lifespan | Luminance |
|---|---|---|---|---|---|---|
| Type | Thickness (Å) | | (V) | (Cd/A) | (T97) | (nit) |
| Example 17 | PH-1 | FH-1 | 11.3 | 28 | 380 | 1000 |
| | 100 | 100 | | | | |
| Example 18 | PH-2 | FH-1 | 11.3 | 29 | 320 | 1000 |
| | 100 | 100 | | | | |
| Example 19 | PH-1 | FH-2 | 11.3 | 26 | 300 | 1000 |
| | 100 | 100 | | | | |
| Example 20 | PH-2 | FH-2 | 11.3 | 30 | 325 | 1000 |
| | 100 | 100 | | | | |
| Comparative | PH-1 | — | 12.3 | 34 | 53 | 1000 |
| Example 10 | 200 | — | | | | |
| Comparative | PH-2 | — | 12.4 | 35 | 55 | 1000 |
| Example 11 | 200 | — | | | | |
| Comparative | — | FH-1 | 11.3 | 22 | 310 | 1000 |
| Example 12 | — | 200 | | | | |
| Comparative | — | FH-2 | 11.3 | 23 | 320 | 1000 |
| Example 13 | — | 200 | | | | |

It is confirmed that the tandem organic light-emitting devices of Examples 17 to 20 each have excellent or suitable lifespan characteristics compared to the tandem organic light-emitting devices of Comparative Examples 10 and 11, which each include only phosphorescence emission layer, and also each have excellent or suitable efficiency compared to the tandem organic light-emitting devices of Comparative Examples 12 and 13, which each include only a fluorescence emission layer.

### Example 21

An ITO (150 Å)/Ag (1,000 Å)/ITO (150 Å) (anode) glass substrate (a product of Corning Inc.) was cut to a size of 50 mm×50 mm×0.7 mm, sonicated with isopropyl alcohol and pure water each for 5 minutes, and cleaned by irradiation of ultraviolet rays and exposure of ozone thereto for 15 minutes. Then the glass substrate was provided to a vacuum deposition apparatus.

HAT-CN was vacuum deposited on the ITO/Ag/ITO anode of the glass substrate to form a hole injection layer having a thickness of 100 Å, NPB was vacuum deposited on the hole injection layer to form a hole transport layer having a thickness of 200 Å, mCBP was vacuum deposited on the hole transport layer to form an electron blocking layer having a thickness of 50 Å, PH-1 (first host) and FCNIrPic (first dopant) were co-deposited on the electron blocking layer at a weight ratio of 95:5 to form a first emission layer having a thickness of 100 Å, FH-1 (second host) and a fluorescent dopant (second dopant) were co-deposited on the first emission layer at a weight ratio of 99:1 to form a second emission layer having a thickness of 100 Å, T2T was vacuum deposited on the second emission layer to form a hole blocking layer having a thickness of 50 Å, and TPM-TAZ and LiQ were co-deposited on the hole blocking layer at a weight ratio of 1:1 to form an electron transport layer having a thickness of 250 Å, thereby completing the formation of a first emission unit.

CBP and Li were co-deposited on the first emission unit at a weight ratio of 98.5:1.5 to form an n-type charge generation layer having a thickness of 50 Å, and HAT-CN was vacuum deposited on the n-type charge generation layer to form a p-type charge generation layer having a thickness of 100 Å, thereby completing the formation of a first charge generating unit.

NPB was vacuum deposited on the first charge generating unit to form a hole transport layer having a thickness of 250 Å, mCBP was vacuum deposited on the hole transport layer to form an electron blocking layer having a thickness of 50 Å, PH-1 (first host) and FCNIrPic (first dopant) were co-deposited on the electron blocking layer at a weight ratio of 95:5 to form a first emission layer having a thickness of 100 Å, FH-1 (second host) and a fluorescent dopant (second dopant) were co-deposited on the first emission layer at a weight ratio of 99:1 to form a second emission layer having a thickness of 100 Å, T2T was vacuum deposited on the second emission layer to form a hole blocking layer having a thickness of 50 Å, and TPM-TAZ and LiQ were co-deposited on the hole blocking layer at a weight ratio of 1:1 to form an electron transport layer having a thickness of 250 Å, thereby completing the formation of a second emission unit.

CBP and Li were co-deposited on the second emission unit at a weight ratio of 98.5:1.5 to form an n-type charge generation layer having a thickness of 50 Å, and HAT-CN was vacuum deposited on the n-type charge generation layer to form a p-type charge generation layer having a thickness of 100 Å, thereby completing the formation of a second charge generating unit.

NPB was vacuum deposited on the second charge generating unit to form a hole transport layer having a thickness of 100 Å, mCBP was vacuum deposited on the hole transport layer to form an electron blocking layer having a thickness of 50 Å, BCTz and Ir(PPy)₃ were co-deposited on the electron blocking layer at a weight ratio of 94:6 to form an emission layer having a thickness of 250 Å, T2T was vacuum deposited on the emission layer to form a hole blocking layer having a thickness of 50 Å, and TPM-TAZ and LiQ were co-deposited on the hole blocking layer at a weight ratio of 1:1 to form an electron transport layer having a thickness of 100 Å, thereby completing the formation of a third emission unit.

CBP and Li were co-deposited on the third emission unit at a weight ratio of 98.5:1.5 to form an n-type charge generation layer having a thickness of 50 Å, and HAT-CN was vacuum deposited on the n-type charge generation layer to form a p-type charge generation layer having a thickness of 100 Å, thereby completing the formation of a third charge generating unit.

NPB was vacuum deposited on the third charge generating unit to form a hole transport layer having a thickness of 100 Å, mCBP was vacuum deposited on the hole transport layer to form an electron blocking layer having a thickness of 50 Å, PH-1 (first host) and FCNIrPic (first dopant) were co-deposited on the electron blocking layer at a weight ratio of 95:5 to form a first emission layer having a thickness of 100 Å, FH-1 (second host) and a fluorescent dopant (second dopant) were co-deposited on the first emission layer at a weight ratio of 99:1 to form a second emission layer having a thickness of 100 Å, T2T was vacuum deposited on the second emission layer to form a hole blocking layer having a thickness of 50 Å, and TPM-TAZ and LiQ were co-deposited on the hole blocking layer at a weight ratio of 1:1 to form an electron transport layer having a thickness of 350 Å, thereby completing the formation of a fourth emission unit.

Yb was vacuum deposited on the fourth emission unit to a thickness of 10 Å and then Ag and Mg were co-deposited thereon at a weight ratio of 9:1 to a thickness of 120 Å, to thereby form a cathode, and CPL was vacuum deposited on the cathode to form a capping layer having a thickness of 600 Å, thereby completing the manufacture of a tandem organic light-emitting device.

### Examples 22 to 24 and Comparative Examples 14 to 17

Additional tandem organic light-emitting devices were manufactured in substantially the same manner as in Example 21, except that a different first host and second host were utilized, as shown in Table 5.

### Evaluation Example 4: Device Evaluation

Driving voltage, efficiency, and lifespan at a current density of 10 mA/cm² were measured, and the results thereof are shown in Table 5.

The driving voltage and current density of each of the tandem organic light-emitting devices were measured utilizing a source meter (Keithley Instrument, 2400 series), and the efficiency thereof was measured utilizing a measurement device C9920-2-12 (Hamamatsu Photonics Inc.).

TABLE 5

| | First host | Second host | Driving voltage | Efficiency | Lifespan | Luminance |
|---|---|---|---|---|---|---|
| Type | Thickness (Å) | | (V) | (Cd/A) | (T97) | (nit) |
| Example 21 | PH-1 | FH-1 | 12.8 | 48 | 380 | 1000 |
| | 100 | 100 | | | | |
| Example 22 | PH-2 | FH-1 | 12.8 | 50 | 420 | 1000 |
| | 100 | 100 | | | | |
| Example 23 | PH-1 | FH-2 | 12.8 | 60 | 400 | 1000 |
| | 100 | 100 | | | | |
| Example 24 | PH-2 | FH-2 | 12.8 | 65 | 410 | 1000 |
| | 100 | 100 | | | | |
| Comparative | PH-1 | — | 13.5 | 72 | 54 | 1000 |
| Example 14 | 200 | — | | | | |
| Comparative | PH-2 | — | 13.8 | 74 | 53 | 1000 |
| Example 15 | 200 | — | | | | |
| Comparative | — | FH-1 | 12.8 | 45 | 400 | 1000 |
| Example 16 | — | 200 | | | | |
| Comparative | — | FH-2 | 12.8 | 46 | 410 | 1000 |
| Example 17 | — | 200 | | | | |

It is confirmed that the tandem organic light-emitting devices of Examples 21 to 24 each have excellent or suitable lifespan characteristics compared to the tandem organic light-emitting devices of Comparative Examples 14 and 15, which each include only phosphorescence emission layer, and also each have excellent or suitable efficiency compared to the tandem organic light-emitting devices of Comparative Examples 16 and 17, which each include only a fluorescence emission layer.

### Example 25

An ITO (150 Å)/Ag (1,000 Å)/ITO (150 Å) (anode) glass substrate (a product of Corning Inc.) was cut to a size of 50 mm×50 mm×0.7 mm, sonicated with isopropyl alcohol and pure water each for 5 minutes, and cleaned by irradiation of ultraviolet rays and ozone exposure for 15 minutes. Then the glass substrate was provided to a vacuum deposition apparatus.

HAT-CN was vacuum deposited on the ITO/Ag/ITO anode of the glass substrate to form a hole injection layer having a thickness of 100 Å, NPB was vacuum deposited on the hole injection layer to form a hole transport layer having a thickness of 200 Å, mCBP was vacuum deposited on the hole transport layer to form an electron blocking layer having a thickness of 50 Å, PH-1 (first host) and FCNIrPic (first dopant) were co-deposited on the electron blocking layer at a weight ratio of 95:5 to form a first emission layer having a thickness of 100 Å, FH-1 (second host) and a fluorescent dopant (second dopant) were co-deposited on the first emission layer at a weight ratio of 99:1 to form a second emission layer having a thickness of 100 Å, T2T was vacuum deposited on the second emission layer to form a hole blocking layer having a thickness of 50 Å, and TPM-TAZ and LiQ were co-deposited on the hole blocking layer at a weight ratio of 1:1 to form an electron transport layer having a thickness of 250 Å, thereby completing the formation of a first emission unit.

CBP and Li were co-deposited on the first emission unit at a weight ratio of 98.5:1.5 to form an n-type charge generation layer having a thickness of 50 Å, and HAT-CN was vacuum deposited on the n-type charge generation layer to form a p-type charge generation layer having a thickness of 100 Å, thereby completing the formation of a first charge generating unit.

NPB was vacuum deposited on the first charge generating unit to form a hole transport layer having a thickness of 500 Å, mCBP was vacuum deposited on the hole transport layer to form an electron blocking layer having a thickness of 50 Å, PH-1 (first host) and FCNIrPic (first dopant) were co-deposited on the electron blocking layer at a weight ratio of 95:5 to form a first emission layer having a thickness of 100 Å, FH-1 (second host) and a fluorescent dopant (second dopant) were co-deposited on the first emission layer at a weight ratio of 99:1 to form a second emission layer having a thickness of 100 Å, T2T was vacuum deposited on the second emission layer to form a hole blocking layer having a thickness of 50 Å, and TPM-TAZ and LiQ were co-deposited on the hole blocking layer at a weight ratio of 1:1 to form an electron transport layer having a thickness of 250 Å, thereby completing the formation of a second emission unit.

CBP and Li were co-deposited on the second emission unit at a weight ratio of 98.5:1.5 to form an n-type charge generation layer having a thickness of 50 Å, and HAT-CN was vacuum deposited on the n-type charge generation layer to form a p-type charge generation layer having a thickness of 100 Å, thereby completing the formation of a second charge generating unit.

NPB was vacuum deposited on the second charge generating unit to form a hole transport layer having a thickness of 600 Å, mCBP was vacuum deposited on the hole transport layer to form an electron blocking layer having a thickness of 50 Å, PH-1 (first host) and FCNIrPic (first dopant) were co-deposited on the electron blocking layer at a weight ratio of 95:5 to form a first emission layer having a thickness of 100 Å, FH-1 (second host) and a fluorescent dopant (second dopant) were co-deposited on the first emission layer at a weight ratio of 99:1 to form a second emission layer having a thickness of 100 Å, T2T was vacuum deposited on the second emission layer to form a hole blocking layer having a thickness of 50 Å, and TPM-TAZ and LiQ were co-deposited on the hole blocking layer at a weight ratio of 1:1 to form an electron transport layer having a thickness of 250 Å, thereby completing the formation of a third emission unit.

CBP and Li were co-deposited on the third emission unit at a weight ratio of 98.5:1.5 to form an n-type charge generation layer having a thickness of 50 Å, and HAT-CN was vacuum deposited on the n-type charge generation layer to form a p-type charge generation layer having a thickness of 100 Å, thereby completing the formation of a third charge generating unit.

NPB was vacuum deposited on the third charge generating unit to form a hole transport layer having a thickness of 200 Å, mCBP was vacuum deposited on the hole transport layer to form an electron blocking layer having a thickness of 50 Å, BCTz and Ir(PPy)₃ were co-deposited on the electron blocking layer at a weight ratio of 94:6 to form an emission layer having a thickness of 250 Å, T2T was vacuum deposited on the emission layer to form a hole blocking layer having a thickness of 50 Å, and TPM-TAZ and LiQ were co-deposited on the hole blocking layer at a weight ratio of 1:1 to form an electron transport layer having a thickness of 570 Å, thereby completing the formation of a fourth emission unit.

Yb was vacuum deposited on the fourth emission unit to a thickness of 10 Å and then Ag and Mg were co-deposited thereon at a weight ratio of 9:1 to a thickness of 120 Å, to thereby form a cathode, and CPL was vacuum deposited on the cathode to form a capping layer having a thickness of 600 Å, thereby completing the manufacture of a tandem organic light-emitting device.

### Examples 26 to 28 and Comparative Examples 18 to 21

Additional tandem organic light-emitting devices were manufactured in substantially the same manner as in Example 25, except that a different first host and second host were utilized, as shown in Table 6.

### Evaluation Example 5: Device Evaluation

Driving voltage, efficiency, and lifespan at a current density of 10 mA/cm² were measured, and then results thereof are shown in Table 6.

The driving voltage and current density of each of the tandem organic light-emitting devices were measured utilizing a source meter (Keithley Instrument, 2400 series), and the efficiency thereof was measured utilizing a measurement device C9920-2-12 (Hamamatsu Photonics Inc.).

TABLE 6

| | First host | Second host | Driving voltage | Efficiency | Lifespan | Luminance |
|---|---|---|---|---|---|---|
| Type | Thickness (Å) | | (V) | (Cd/A) | (T97) | (nit) |
| Example 25 | PH-1 | FH-1 | 12.9 | 55 | 390 | 1000 |
| | 100 | 100 | | | | |
| Example 26 | PH-2 | FH-1 | 12.9 | 58 | 430 | 1000 |
| | 100 | 100 | | | | |
| Example 27 | PH-1 | FH-2 | 12.9 | 65 | 405 | 1000 |
| | 100 | 100 | | | | |
| Example 28 | PH-2 | FH-2 | 12.9 | 70 | 420 | 1000 |
| | 100 | 100 | | | | |
| Comparative | PH-1 | — | 13.8 | 85 | 45 | 1000 |
| Example 18 | 200 | — | | | | |
| Comparative | PH-2 | — | 13.7 | 87 | 48 | 1000 |
| Example 19 | 200 | — | | | | |
| Comparative | — | FH-1 | 12.9 | 50 | 410 | 1000 |
| Example 20 | — | 200 | | | | |
| Comparative | — | FH-2 | 12.9 | 52 | 420 | 1000 |
| Example 21 | — | 200 | | | | |

It is confirmed that the tandem organic light-emitting devices of Examples 25 to 28 each have excellent or suitable lifespan characteristics compared to the tandem organic light-emitting devices of Comparative Examples 18 and 19, which each include only a phosphorescence emission layer, and also each have excellent or suitable efficiency compared to the tandem organic light-emitting devices of Comparative Examples 20 and 21, which each include only a fluorescence emission layer.

An organic light-emitting device according to an embodiment includes both (e.g., simultaneously) a phosphorescence emission layer and a fluorescence emission layer, each satisfying a specific parameter, and may thus have high efficiency and long lifespan characteristics.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that various suitable changes in form and details may be made therein without departing from the spirit and scope as defined by the claims and equivalents thereof.

What is claimed is:

1. An organic light-emitting device comprising:
a first electrode;
a second electrode facing the first electrode; and
an interlayer between the first electrode and the second electrode,
wherein the interlayer comprises an emission unit comprising a first emission layer and a second emission layer,
the first emission layer comprises a first host and a first dopant,
the second emission layer comprises a second host and a second dopant,
the first emission layer has greater hole mobility than electron mobility,
the second emission layer has greater electron mobility than hole mobility,
the first host has a triplet excitation energy level (T₁) value of 2.0 eV or more, and
the second host has a T₁ value of 1.6 eV or more and 1.8 eV or less.

2. The organic light-emitting device of claim 1, wherein the first dopant has a T₁ value of 2.0 eV or more.

3. The organic light-emitting device of claim 1, wherein thicknesses of the first emission layer and the second emission layer are each independently greater than 1 nm and less than or equal to 20 nm.

4. The organic light-emitting device of claim 1, wherein the second dopant has a singlet excitation energy level (S₁) value of 2.8 eV or more.

5. The organic light-emitting device of claim 1, wherein the first emission layer and the second emission layer contact each other.

6. The organic light-emitting device of claim 1, wherein the first dopant is different from the second dopant.

7. The organic light-emitting device of claim 1, wherein the first electrode is an anode,
the second electrode is a cathode,
the interlayer further comprises a hole transport region between the first electrode and the first emission layer and an electron transport region between the second emission layer and the second electrode,
the hole transport region comprises a hole injection layer, a hole transport layer, an emission auxiliary layer, an electron blocking layer, or any combination thereof, and
the electron transport region comprises a buffer layer, a hole blocking layer, an electron control layer, an electron transport layer, an electron injection layer, or any combination thereof.

8. The organic light-emitting device of claim 1, wherein the first host comprises a compound represented by Formula 1: 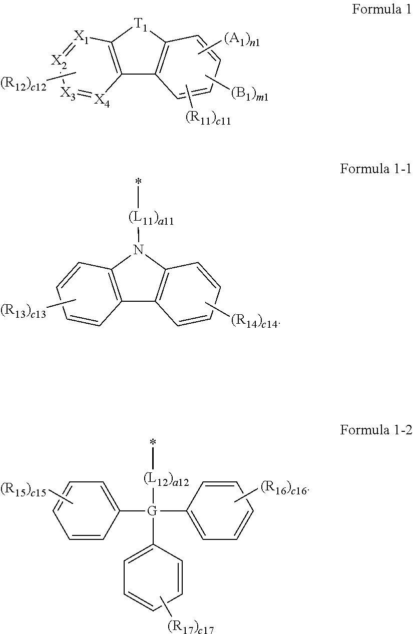
wherein, in Formulae 1, 1-1, and 1-2,
T₁ is O or S,
X₁ to X₄ are each independently C or N, and at least one of X₁ to X₄ is N,
A₁ is a group represented by Formula 1-1,
B₁ is a group represented by Formula 1-2,
n1 is an integer from 1 to 3, m1 is an integer from 1 to 3, and 2≤n1+m1≤4,
G is C, Si, or Ge,
L₁₁ and L₁₂ are each independently a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
a11 and a12 are each independently an integer from 1 to 5,
R₁₁ to R₁₇ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —B(Q₁)(Q₂), —P(Q₁)(Q₂), or —C(═O)(Q₁),
c11 is an integer from 0 to 2,
c12 is an integer from 0 to 4,
c13 and c14 are each independently an integer from 0 to 4,
c15 to c17 are each independently an integer from 0 to 5, and
R₁₀ₐ is:
deuterium (-D), —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
wherein Q₁, Q₂, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

9. The organic light-emitting device of claim 8, wherein Formula 1 is represented by one of Formulae 1A to 1L: 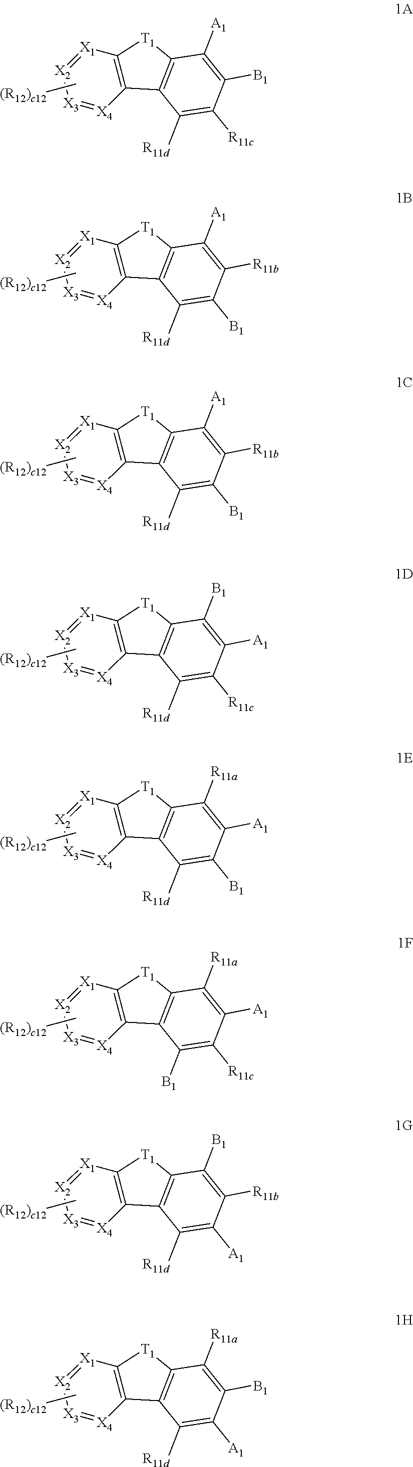 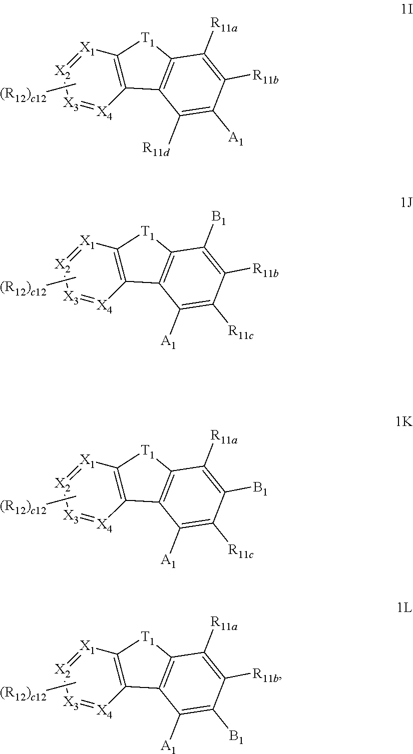
wherein, in Formulae 1A to 1L,
T₁, X₁ to X₄, R₁₂, c12, A₁, and B₁ are the same as defined in claim 8, and
R₁₁ₐ to R_{11d} are each the same as described in connection with R₁₁.

10. The organic light-emitting device of claim 1, wherein the first host is selected from Compounds PH-1 and PH-2,

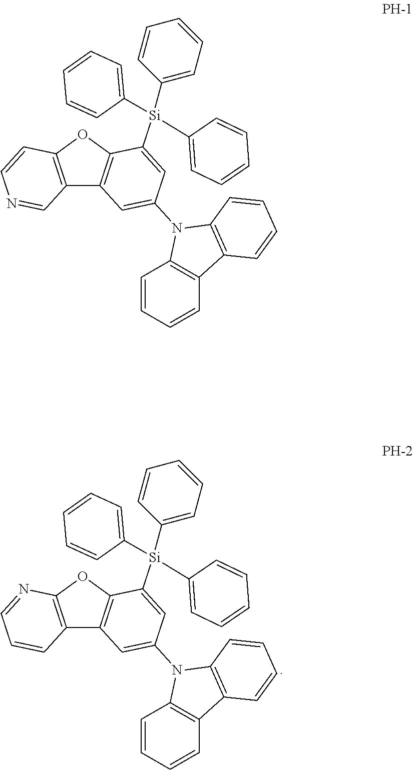 [SMILES: c1ccc([Si](c2ccccc2)(c2ccccc2)c2cc(-n3c4ccccc4c4ccccc43)cc3c2oc2ccncc23)cc1 ; c1ccc([Si](c2ccccc2)(c2ccccc2)c2cc(-n3c4ccccc4c4ccccc43)cc3c2oc2ncccc23)cc1]

11. The organic light-emitting device of claim 1, wherein the second host comprises a compound represented by Formula 2: 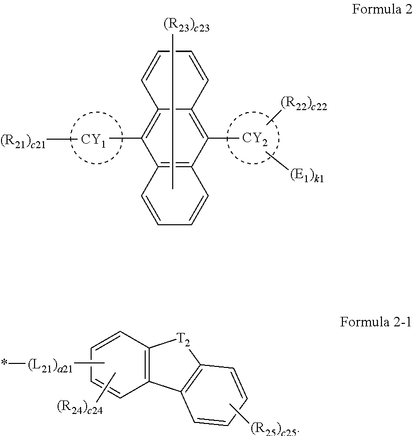
wherein, in Formulae 2 and 2-1,
ring CY₁ and ring CY₂ are each independently a C₃-C₆₀ carbocyclic group or a C₁-C₆₀ heterocyclic group,
E₁ is a group represented by Formula 2-1,
k₁ is an integer from 1 to 10,
T₂ is O or S,
L₂₁ is a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
a21 is an integer from 1 to 5,
R₂₁ to R₂₅ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —B(Q₁)(Q₂), —P(Q₁)(Q₂), or —C(═O)(Q₁),
c21 and c22 are each independently an integer from 0 to 10,
c23 is an integer from 1 to 8, and at least one of the c23 R₂₃(s) is not hydrogen,
c24 is an integer from 1 to 3,
c25 is an integer from 1 to 4, and
R₁₀ₐ is:
deuterium (-D), —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
wherein Q₁, Q₂, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

12. The organic light-emitting device of claim 11, wherein ring CY₁ and ring CY₂ each independently include a benzene group, a naphthalene group, an anthracene group, a phenanthrene group, a triphenylene group, a chrysene group, or a pyrene group.

13. The organic light-emitting device of claim 11, wherein ring CY₁ and ring CY₂ are each a benzene group, and
T₂ in Formula 2-1 is O.

14. The organic light-emitting device of claim 1, wherein the second host is selected from Compounds FH-1 and FH-2,

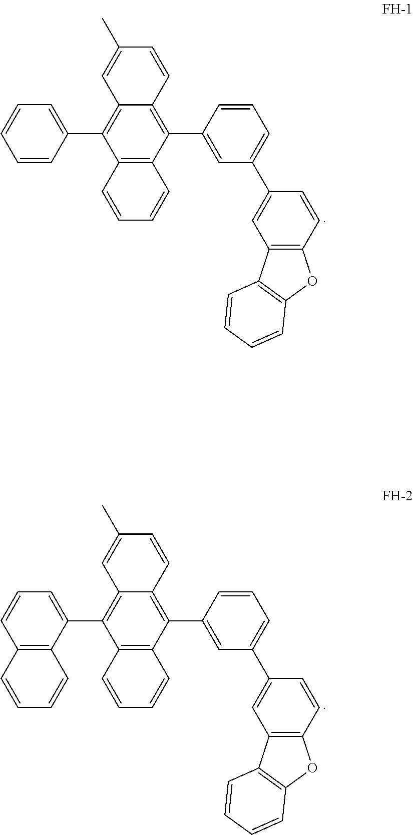 [SMILES: Cc1ccc2c(-c3cccc(-c4ccc5oc6ccccc6c5c4)c3)c3ccccc3c(-c3ccccc3)c2c1 ; Cc1ccc2c(-c3cccc(-c4ccc5oc6ccccc6c5c4)c3)c3ccccc3c(-c3cccc4ccccc34)c2c1]

15. The organic light-emitting device of claim 1, wherein the organic light-emitting device further comprises a capping layer, and
the capping layer is located outside the first electrode and/or outside the second electrode.

16. The organic light-emitting device of claim 15, wherein the capping layer has a refractive index of 1.5 or more and 2.0 or less with light of a wavelength of 589 nm.

17. An organic light-emitting device comprising:
a first electrode;
a second electrode facing the first electrode; and
an interlayer including an emission layer between the first electrode and the second electrode,
wherein the emission layer comprises a first host, a second host, a first dopant, and a second dopant, and the first dopant is different from the second dopant,
the first host comprises a compound represented by Formula 1, and
the second host comprises a compound represented by Formula 2: 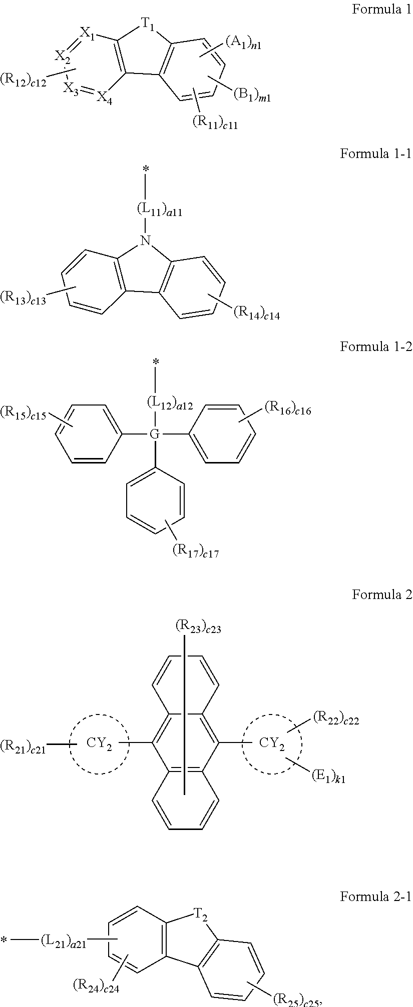
wherein, in Formulae 1, 1-1, 1-2, 2, and 2-1,
T₁ is O or S,
X₁ to X₄ are each independently C or N, and at least one of X₁ to X₄ is N,
A₁ is a group represented by Formula 1-1,
B₁ is a group represented by Formula 1-2,
n1 is an integer from 1 to 3, m1 is an integer from 1 to 3, and 2≤n1+m1≤4,
G is C, Si, or Ge,
L₁₁ and L₁₂ are each independently a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
a11 and a12 are each independently an integer from 1 to 5,
R₁₁ to R₁₇ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —B(Q₁)(Q₂), —P(Q₁)(Q₂), or —C(═O)(Q₁),
c11 is an integer from 0 to 2,
c12 is an integer from 0 to 4,
c13 and c14 are each independently an integer from 0 to 4,
c15 to c17 are each independently an integer from 0 to 5, and
ring CY₁ and ring CY₂ are each independently a C₃-C₆₀ carbocyclic group or a C₁-C₆₀ heterocyclic group,
E₁ is a group represented by Formula 2-1,
k₁ is an integer from 1 to 10,
T₂ is O or S,
L₂₁ is a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,
a21 is an integer from 1 to 5,
R₂₁ to R₂₅ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —B(Q₁)(Q₂), —P(Q₁)(Q₂), or —C(═O)(Q₁),
c21 and c22 are each independently an integer from 0 to 10,
c23 is an integer from 1 to 8, and at least one of the c23 R₂₃(s) is not hydrogen,
c24 is an integer from 1 to 3,
c25 is an integer from 1 to 4, and
R₁₀ₐ is:
deuterium (-D), —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
wherein Q₁, Q₂, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

18. An organic light-emitting device comprising:
a first electrode;
a second electrode facing the first electrode; and
an interlayer between the first electrode and the second electrode,
wherein the interlayer comprises:
m emission units; and
m-1 charge generating units located between two neighboring emission units among the m emission units,
wherein m is an integer of 2 or more,
at least one emission unit among the m emission units comprises a first emission layer and a second emission layer,
the first emission layer comprises a first host and a first dopant,
the second emission layer comprises a second host and a second dopant,
the first emission layer has greater hole mobility than electron mobility,
the second emission layer has greater electron mobility than hole mobility,
the first host has a T₁ value of 2.0 eV or more, and
the second host has a T₁ value of 1.6 eV or more and 1.8 eV or less.

19. An electronic apparatus comprising the organic light-emitting device of claim 1.

20. The electronic apparatus of claim 19, wherein the electronic apparatus further comprises quantum dots.
